(19) United States
(12) Patent Application Publication
(10) Pub. No.: US 2014/0008716 A1
(43) Pub. Date: Jan. 9, 2014

(54) SEMICONDUCTOR DEVICE AND MANUFACTURING METHOD THEREOF

(71) Applicant: Renesas Electronics Corporation, Kawasaki-shi (JP)

(72) Inventors: Tsuyoshi Arigane, Akishima (JP); Digh Hisamoto, Kokubunji (JP); Yutaka Okuyama, Kokubunji (JP); Takashi Hashimoto, Kanagawa (JP); Daisuke Okada, Kanagawa (JP)

(73) Assignee: RENESAS ELECTRONICS CORPORATION

(21) Appl. No.: 13/931,874

(22) Filed: Jun. 29, 2013

(30) Foreign Application Priority Data
Jul. 9, 2012 (JP) 2012-153212

(51) Int. Cl. H01L 29/792; H01L 29/66

(52) U.S. Cl. CPC H01L 29/792; H01L 29/66833
USPC 257/326; 257/314; 438/287

(57) ABSTRACT

When the width of an isolation region is reduced through the scaling of a memory cell to reduce the distance between the memory cell and an adjacent memory cell, the electrons or holes injected into the charge storage film of the memory cell are diffused into the portion of the charge storage film located over the isolation region to interfere with each other and possibly impair the reliability of the memory cell. In a semiconductor device, the charge storage film of the memory cell extends to the isolation region located between the adjacent memory cells. The effective length of the charge storage film in the isolation region is larger than the width of the isolation region. Here, the effective length indicates the length of the region of the charge storage film which is located over the isolation region and in which charges are not stored.

### CROSS-REFERENCE TO RELATED APPLICATIONS

The disclosure of Japanese Patent Application No. 2012-153212 filed on Jul. 9, 2012 including the specification, drawings and abstract is incorporated herein by reference in its entirety.

### BACKGROUND

The present invention relates to a semiconductor device, and is a technique applicable to a semiconductor device having, e.g., a nonvolatile memory and a manufacturing method thereof.

In Japanese Unexamined Patent Publication No. 2006-41354 (Patent Document 1), a technique is disclosed in which, in a nonvolatile semiconductor memory device having a split-gate structure, a memory gate is formed over a projecting-type substrate and a side surface thereof is used as a channel to ensure a read current drive force. The height of the insulating film of an isolation region present between memory cells is set lower than the height of an active region to form the memory gate over the projecting-type substrate.

In Japanese Unexamined Patent Publication No. 2008-153355 (Patent Document 2), to improve the resistance of a split-gate MONOS memory cell to erroneous writing thereto and cause the memory cell to operate at a high speed, the following technique is disclosed. A charge storage layer in each of an isolation region and the insulating regions between memory transistors and selection transistors is eliminated to prevent charges from being injected or stored therein. In addition, over the isolation region, the gate electrodes of the memory transistors are couplel together at a position from a surface of a silicon substrate which is higher in level than that of the gate electrode of each of the selection transistors to reduce the capacitance between each of the memory transistors and the selection transistor.

### RELATED ART DOCUMENTS

### Patent Documents

### [Patent Document 1]

Japanese Unexamined Patent Publication No. 2006-41354

### [Patent Document 2]

Japanese Unexamined Patent Publication No. 2008-153355

### SUMMARY

In Patent Document 1, when the width of the isolation region is reduced through the scaling of the memory cell to reduce the distance between the memory cell and an adjacent memory cell, the electrons or holes injected into the silicon nitride film (charge storage film) of the memory cell are diffused into the portion of the charge storage film located over the isolation region to interfere with each other. This may impair the reliability of the memory cell.

Other problems and novel features of the present invention will become apparent from a statement in the present specification and the accompanying drawings.

In a semiconductor device according to an embodiment, the charge storage film of a memory cell extends to an isolation region located between the memory cell and an adjacent memory cell. The effective length of the charge storage film, which is the length of the region of the charge storage film in the isolation region in which charges are not stored, is larger than the width of the isolation region.

According to the foregoing embodiment, it is possible to reduce the diffusion of the charges between the adjacent memory cells through the charge storage film.

### BRIEF DESCRIPTION OF THE DRAWINGS

FIG. 1 is a plan view of a memory cell array in a semiconductor device according to Embodiment 1;

FIGS. 2A and 2B are partial cross-sectional views of the memory cell array along the line A-A′ in FIG. 1;

FIG. 3 is a partial cross-sectional view of the memory cell array along the line B-B′ in FIG. 1;

FIGS. 4A and 4B are partial cross-sectional views of the memory cell array along the line C-C′ in FIG. 1;

FIGS. 5A and 5B are partial cross-sectional views of the memory cell array along the line D-D′ in FIG. 1;

FIG. 6 is an equivalent circuit diagram of the memory cell array of the semiconductor device according to Embodiment 1;

FIG. 7 is a flow chart showing an example of an erase operation to a memory cell according to Embodiment 1;

FIG. 8 is a view showing an example of an erase pulse voltage for the memory cell according to Embodiment 1;

FIG. 9 is a flow chart showing an example of a write operation to the memory cell according to Embodiment 1;

FIG. 10 is a view showing an example of a write pulse voltage for the memory cell according to Embodiment 1;

FIG. 11 is a view showing an effect on a read operation to the memory cell according to Embodiment 1;

FIG. 12 is a view showing an effect on the reliability (charge retention property) of the memory cell according to Embodiment 1;

FIG. 13 is a view showing an effect on the reliability (charge retention property) of the memory cell according to Embodiment 1;

FIG. 14 is a schematic illustrative view for illustrating the effect of Embodiment 1;

FIG. 15 is a block diagram of a large-scale integrated circuit device to which the memory cell array according to Embodiment 1 is applied;

FIG. 16 is a flow chart of a manufacturing method of the semiconductor device according to Embodiment 1;

FIG. 17 is a process cross-sectional view illustrating the manufacturing method of the semiconductor device according to Embodiment 1;

FIG. 18 is a process cross-sectional view illustrating the manufacturing method of the semiconductor device according to Embodiment 1, which is subsequent to FIG. 17;

FIG. 19 is a process cross-sectional view illustrating the manufacturing method of the semiconductor device according to Embodiment 1, which is subsequent to FIG. 18;

FIG. 20 is a process cross-sectional view illustrating the manufacturing method of the semiconductor device according to Embodiment 1, which is subsequent to FIG. 19;

FIG. 21 is a process cross-sectional view illustrating the manufacturing method of the semiconductor device according to Embodiment 1, which is subsequent to FIG. 20;

FIG. 22 is a process cross-sectional view illustrating the manufacturing method of the semiconductor device according to Embodiment 1, which is subsequent to FIG. 21;

FIG. 23 is a process cross-sectional view illustrating the manufacturing method of the semiconductor device according to Embodiment 1, which is subsequent to FIG. 22;

FIG. 24 is a process cross-sectional view illustrating the manufacturing method of the semiconductor device according to Embodiment 1, which is subsequent to FIG. 23;

FIG. 25 is a process cross-sectional view illustrating the manufacturing method of the semiconductor device according to Embodiment 1, which is subsequent to FIG. 24;

FIG. 26 is a process cross-sectional view illustrating the manufacturing method of the semiconductor device according to Embodiment 1, which is subsequent to FIG. 25;

FIG. 27 is a plan view of a memory cell array in a semiconductor device according to Embodiment 2;

FIG. 28 is a partial cross-sectional view of the memory cell array along the line A-A′ in FIG. 27;

FIG. 29 is a partial cross-sectional view of the memory cell array along the line B-B′ in FIG. 27;

FIG. 30 is a partial cross-sectional view of the memory cell array along the line C-C′ in FIG. 27;

FIG. 31 is a partial cross-sectional view of the memory dell array along the line D-D′ in FIG. 27;

FIG. 32 is a plan view of a memory cell array in a semiconductor device according to Embodiment 3;

FIG. 33 is a partial cross-sectional view of the memory cell array along the line A-A′ in FIG. 32;

FIG. 34 is a partial cross-sectional view of the memory cell array along the line B-B′ in FIG. 32;

FIG. 35 is a partial cross-sectional view of the memory cell array along the line C-C′ in FIG. 32;

FIG. 36 is a partial cross-sectional view of the memory cell array along the line D-D′ in FIG. 32;

FIG. 37 is a view showing the resistance of a memory cell according to Embodiment 3 to erroneous writing to an adjacent cell;

FIG. 38 is a plan view of a memory cell array in a semiconductor device according to Embodiment 4;

FIG. 39 is a partial cross-sectional view of the memory cell array along the line A-A′ in FIG. 38;

FIG. 40 is a partial cross-sectional view of the memory cell array along the line B-B′ in FIG. 38;

FIG. 41 is a partial cross-sectional view of the memory cell array along the line C-C′ in FIG. 38;

FIG. 42 is a partial cross-sectional view of the memory cell array along the line D-D′ in FIG. 38;

FIG. 43 is a schematic illustrative view for illustrating the effect of Embodiment 4;

FIG. 44 is a plan view of a memory cell array in a semiconductor device according to Embodiment 5;

FIG. 45 is a partial cross-sectional view of the memory cell array along the line A-A′ in FIG. 44;

FIG. 46 is a partial cross-sectional view of the memory cell array along the line B-B′ in FIG. 44;

FIG. 47 is a partial cross-sectional view of the memory cell array along the line C-C′ in FIG. 44;

FIG. 48 is a partial cross-sectional view of the memory cell array along the line D-D′ in FIG. 44;

FIG. 49 is a plan view of a memory cell array in a semiconductor device according to Embodiment 6;

FIGS. 50A and 50B are partial cross-sectional views of the memory cell array along the line A-A′ in FIG. 49;

FIG. 51 is a partial cross-sectional view of the memory cell array along the line B-B′ in FIG. 49;

FIG. 52 is a partial cross-sectional view of the memory cell array along the line C-C′ in FIG. 49;

FIGS. 53A and 53B are partial cross-sectional views of the memory cell array along the line D-D′ in FIG. 49;

FIG. 54 is a plan view of a memory cell array in a semiconductor device according to Embodiment 7;

FIGS. 55A and 55B are partial cross-sectional views of the memory cell array along the line A-A′ in FIG. 54;

FIG. 56 is a partial cross-sectional view of the memory cell array along the line B-B′ in FIG. 54;

FIG. 57 is a partial cross-sectional view of the memory cell array along the line C-C′ in FIG. 54;

FIGS. 58A and 58B are partial cross-sectional views of the memory cell array along the line D-D′ in FIG. 54;

FIG. 59 is a view showing an example of an erase pulse voltage for a memory cell according to Embodiment 7;

FIG. 60 is a view showing an example of a write pulse voltage for the memory cell according to Embodiment 7;

FIG. 61 is a plan view of a memory cell array in a semiconductor device according to Embodiment 8;

FIGS. 62A and 62B are partial cross-sectional views of the memory cell array along the line A-A′ in FIG. 61;

FIG. 63 is a partial cross-sectional view of the memory cell array along the line B-B′ in FIG. 61;

FIG. 64 is a partial cross-sectional view of the memory cell array along the line C-C′ in FIG. 61;

FIG. 65 is a view showing an example of an erase pulse voltage for a memory cell according to Embodiment 8;

FIG. 66 is a view showing an example of a write pulse voltage for the memory cell according to Embodiment 8;

FIG. 67 is a flow chart of a manufacturing method of the semiconductor device according to Embodiment 8;

FIG. 68 is a process cross-sectional view illustrating the manufacturing method of the semiconductor device according to Embodiment 8;

FIG. 69 is a process cross-sectional view illustrating the manufacturing method of the semiconductor device according to Embodiment 8, which is subsequent to FIG. 68;

FIG. 70 is a process cross-sectional view illustrating the manufacturing method of the semiconductor device according to Embodiment 8, which is subsequent to FIG. 69;

FIG. 71 is a process cross-sectional view illustrating the manufacturing method of the semiconductor device according to Embodiment 8, which is subsequent to FIG. 70;

FIG. 72 is a process cross-sectional view illustrating the manufacturing method of the semiconductor device according to Embodiment 8, which is subsequent to FIG. 71;

FIG. 73 is a process cross-sectional view illustrating the manufacturing method of the semiconductor device according to Embodiment 8, which is subsequent to FIG. 72;

FIG. 74 is a process cross-sectional view illustrating the manufacturing method of the semiconductor device according to Embodiment 8, which is subsequent to FIG. 73;

FIG. 75 is a process cross-sectional view illustrating the manufacturing method of the semiconductor device according to Embodiment 8, which is subsequent to FIG. 74;

FIG. 76 is a process cross-sectional view illustrating the manufacturing method of the semiconductor device according to Embodiment 8, which is subsequent to FIG. 75;

FIG. 77 is a process cross-sectional view illustrating the manufacturing method of the semiconductor device according to Embodiment 8, which is subsequent to FIG. 76;

FIG. 78 is a plan view of a memory cell array in a semiconductor device according to Embodiment 9;

FIG. 79 is a partial cross-sectional view of the memory cell array along the line A-A′ in FIG. 78;

FIG. 80 is a partial cross-sectional view of the memory cell array along the line B-B′ in FIG. 78;

FIG. 81 is a partial cross-sectional view of the memory cell array along the line C-C′ in FIG. 78;

FIG. 82 is a partial cross-sectional view of the memory cell array along the line D-D′ in FIG. 79;

FIG. 83 is a flow chart of a manufacturing method of the semiconductor device according to Embodiment 9;

FIG. 84 is a process cross-sectional view illustrating the manufacturing method of the semiconductor device according to Embodiment 9;

FIG. 85 is a process cross-sectional view illustrating the manufacturing method of the semiconductor device according to Embodiment 9, which is subsequent to FIG. 84;

FIG. 86 is a process cross-sectional view illustrating the manufacturing method of the semiconductor device according to Embodiment 9, which is subsequent to FIG. 85;

FIG. 87 is a process cross-sectional view illustrating the manufacturing method of the semiconductor device according to Embodiment 9, which is subsequent to FIG. 86;

FIG. 88 is a process cross-sectional view illustrating the manufacturing method of the semiconductor device according to Embodiment 9, which is subsequent to FIG. 87;

FIG. 89 is a process cross-sectional view illustrating the manufacturing method of the semiconductor device according to Embodiment 9, which is subsequent to FIG. 88;

FIG. 90A is a plan view of a semiconductor according to an embodiment, and FIGS. 90B and 90C are cross-sectional views thereof;

FIG. 91 is a flow chart showing a manufacturing method of a semiconductor device associated with the structure of FIG. 90A to 90C; and

FIG. 92 is a view summarizing each of the embodiments.

### DETAILED DESCRIPTION

### Outline of Embodiments

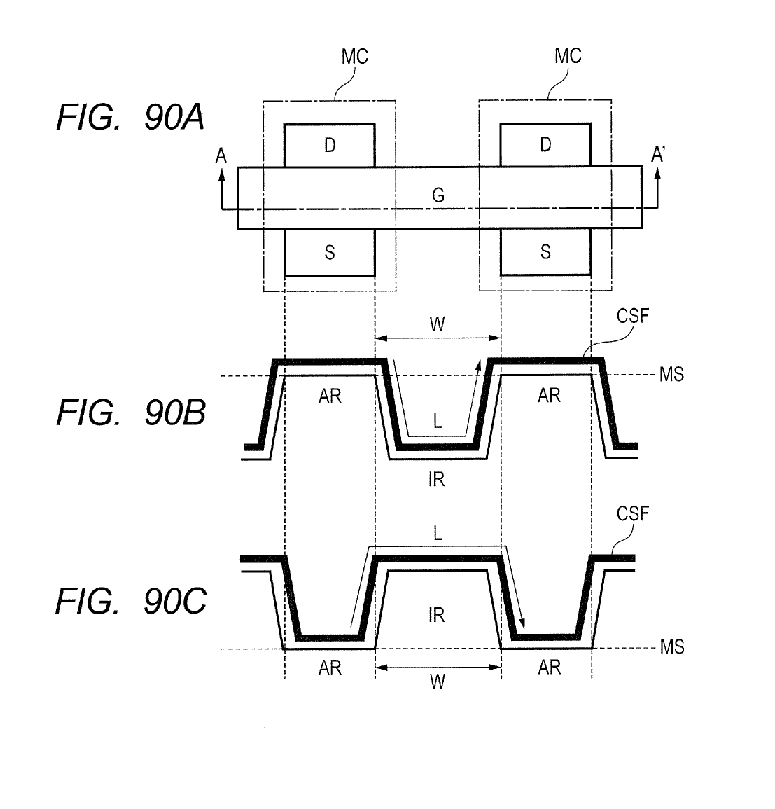

FIGS. 90A to 90C are a plan view and cross-sectional views of a semiconductor device showing an embodiment, of which FIG. 90A is the plan view showing parts of two memory cells MC, FIG. 90B is the view showing a part of a cross section along the line A-A′ in FIG. 90A, and FIG. 90C is the view showing a part of a cross section of a modification along the line A-A′ in FIG. 90A.

Each of the memory cells MC has a memory gate G, a source S, and a drain D. The memory gate G extends commonly to the two memory cells MC. A charge storage film CSF located under the memory gate G extends to an isolation region IR located between the adjacent memory cells. In FIG. 90B, the isolation region IR is downwardly recessed from a main surface MS of a semiconductor substrate. That is, the upper surface of the isolation region IF is at a position lower in level than the upper surfaces of active regions AR. On the other hand, in FIG. 90C, the isolation region IR upwardly protrudes from the main surface MS of the semiconductor substrate. That is, the upper surface of the isolation region IR is at a position higher in level than the upper surfaces of the active regions AR. In either of the cases of FIGS. 90B and 90C, the effective length L of the charge storage film CSF in the isolation region IR is larger than the width W of the isolation region. Here, the effective length L indicates the length of the region of the charge storage film CSF which is located over the isolation region IR and in which charges are not stored.

When the width of the isolation region IR is reduced through the scaling of the memory cells, electrons or holes injected into the charge storage film CSF of each of the memory cells are diffused into the portion of the charge storage film CSF located over the isolation region IR to interfere with each other and possibly impair the reliability of the memory cells. However, according to the embodiment, the effective length L of the charge storage film CSF in the isolation region IR can be set larger than the width W of the isolation region IR. This allows a reduction in the diffusion of the charges between the adjacent memory cells via the charge storage film.

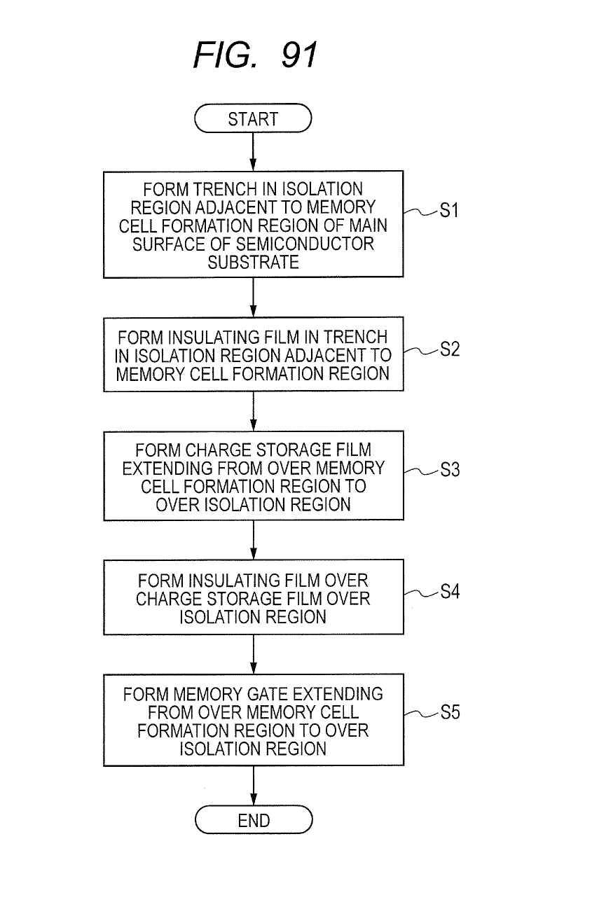

FIG. 91 is a flow chart showing a manufacturing method of a semiconductor device associated with the structure of FIG. 90. First, the isolation region IR adjacent to the memory cell formation region of the main surface MS of the semiconductor substrate is formed with a trench (Step S1). Then, in the trench of the isolation region IR, an insulating film is formed (Step S2). Then, the charge storage film CSF is formed to extend from over the memory cell formation region to over the isolation region IR (Step S3). Thereafter, an insulating film is formed over the portion of the charge storage film CSF located over the isolation region IR (Step S4). Finally, the memory gate G is formed to extend from over the memory cell formation region to over the isolation region IR (Step S5). In Step S2, depending on the thickness of the insulating film formed in the trench of the isolation region IR, the structure of FIG. 90B and the structure of FIG. 90C are formed.

A means for increasing the effective length L of the charge storage film CSF in the isolation region IR and the like are described in each of the embodiments described later.

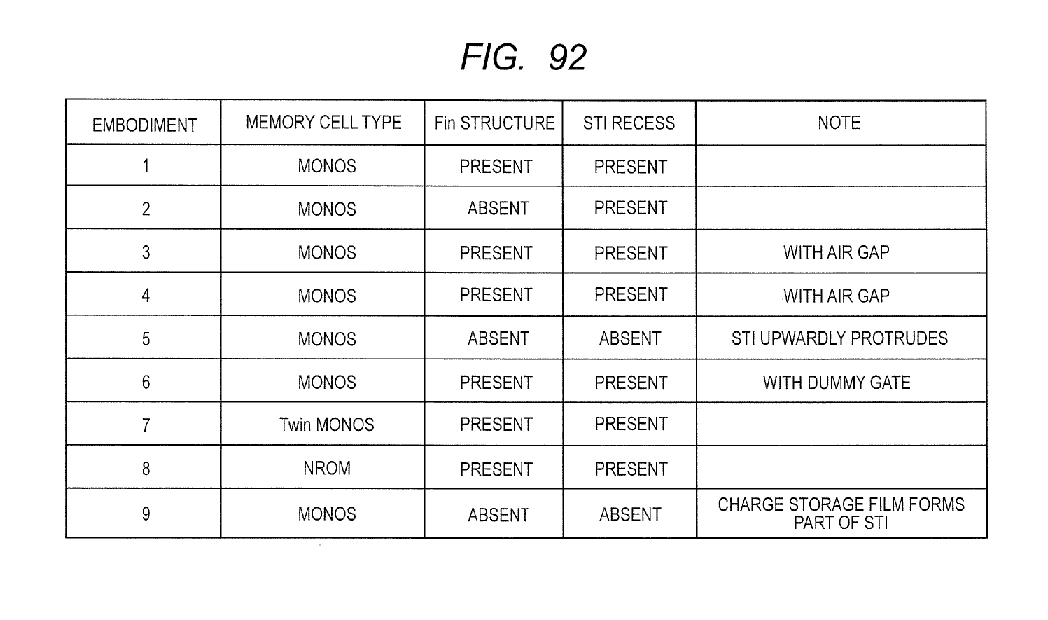

FIG. 92 is a view summarizing each of the embodiments described later. A “Fin structure” refers to a structure in which a memory gate (MG) protrudes toward the recess in an isolation region (STI). A “STI recess” refers to a structure in which the upper surface of the insulating film forming the STI is located below the main surface of the semiconductor substrate. A “MONOS” refers to a MONOS (Metal Oxide Nitride Oxide Semiconductor) memory cell type having a split-gate structure. A “Twin MONOS” refers to a memory cell type having a twin MONOS structure in which memory gates are present on both sides of a selection gate interposed therebetween. An “NROM” refers to a memory cell type having a MONOS structure in which no selection gate exists.

### DETAILED DESCRIPTION OF EMBODIMENTS

Referring to the drawings, a detailed description will be given below of the embodiments.

In the following embodiments, if necessary for the sake of convenience, the embodiments will be each described by being divided into a plurality of sections or embodiments. However, they are by no means irrelevant to each other unless particularly explicitly described otherwise, and one of the sections or embodiments is modifications, applications detailed explanation, supplementary explanation, and so forth of part or the whole of the others. Also in the following embodiments, when the number and the like (including the number, numerical value, amount, range, and the like) of elements are referred to in the following embodiments, they are not limited to specific numbers. The number and the like of the elements may be not less than or not more than specific numbers unless particularly explicitly described otherwise or unless they are obviously limited to specific numbers in principle.

Also in the following embodiments, the components thereof (including also elements, steps, and the like) are not necessarily indispensable unless particularly explicitly described otherwise or unless the components are considered to be obviously indispensable in principle. Likewise, if the shapes, positional relationships, and the like of the components and the like are referred to in the following embodiments, the shapes, positional relationships, and the like are assumed to include those substantially proximate or similar thereto and the like unless particularly explicitly described otherwise or unless it can be considered that they obviously do not in principle. The same shall apply in regard to the foregoing number and the like (including the number, numerical value, amount, range, and the like).

Note that, throughout all the drawings for illustrating the embodiments, members having the same functions are denoted by the same or associated reference numerals, and a repeated description thereof is omitted. In the following embodiments, a description of the same or like parts will not be repeated in principle unless particularly necessary.

### Embodiment 1

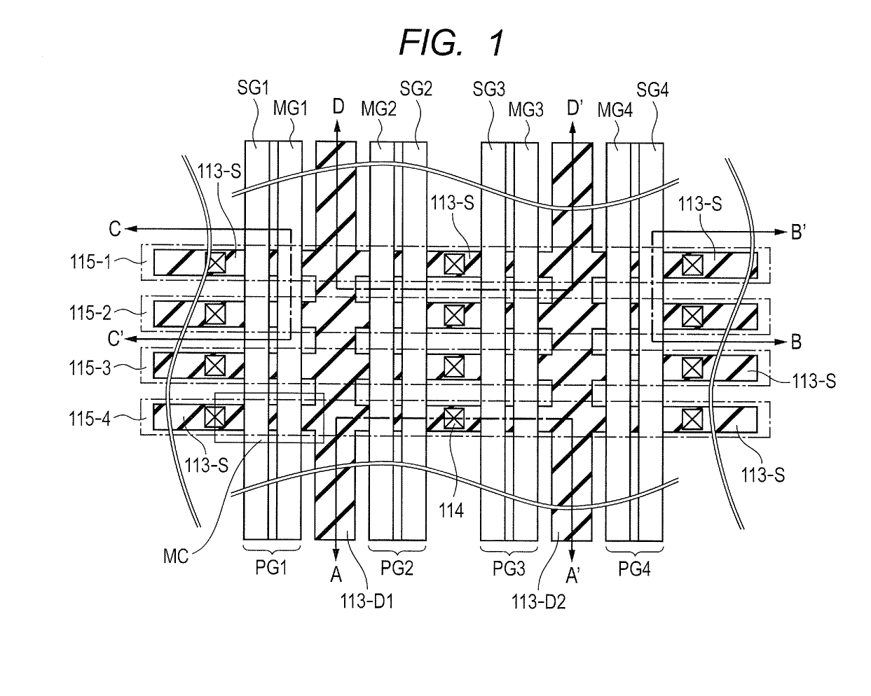

FIG. 1 is a plan view of a memory cell array in a semiconductor device according to Embodiment 1. In the memory cell array in the semiconductor device of the present embodiment, as can be seen from FIG. 1, a memory gate MG1 and a selection gate SG1 form a first gate pair PG1 and a memory gate MG2 and a selection gate SG2 form a second gate pair PG2. Each of the first and second gate pairs PG1 and PG2 extends in the same direction (first direction). Likewise, a memory gate MG3 and a selection gate SG3 form a third gate pair PG3 and a memory gate MG4 and a selection gate SG4 form a fourth gate pair PG4. Each of the third and fourth gate pairs PG3 and PG4 extends in the first direction, similarly to the first and second gate pairs PG1 and PG2. A total of N such gate pairs form the memory cell array, and only some of them are shown in FIG. 1.

The memory cell array also has diffusion regions 113 traversing (or orthogonal to) these plurality of gate pairs PG1, PG2, PG3, and PG4 and extending in another direction (second direction) different from the first direction, while extending in the first direction between the gate pairs. The diffusion regions 113 include source (Source) regions 113-S extending in the second direction and (Drain) drain regions 113-D extending in the first direction. The source regions 113-S are coupled to metal wires 115 in layers located over a plurality of contact portions 114 to extend in the second direction as a first source line 115-1, a second source line 115-2, a third source line 115-3, and a fourth source line 115-4.

The drain regions 113-D are formed respectively between the first and second gate pairs PG1 and PG2 and between the third and fourth gate pairs PG3 and PG4 to extend in the first direction, similarly to the first to fourth gate pairs PG1, PG2, PG3, and PG4, and form a first drain line 113-D1 and a second drain line 113-D2.

The square region enclosed in the solid line (the region with the reference mark MC) corresponds to one memory cell. In the memory cell array, a plurality of the memory cells MC are arranged in rows and columns (as a matrix). The memory cell array also has an isolation region adjacent to and located between the memory cells. The memory cell MC of Embodiment 1 is a MONOS nonvolatile memory having a split-gate structure.

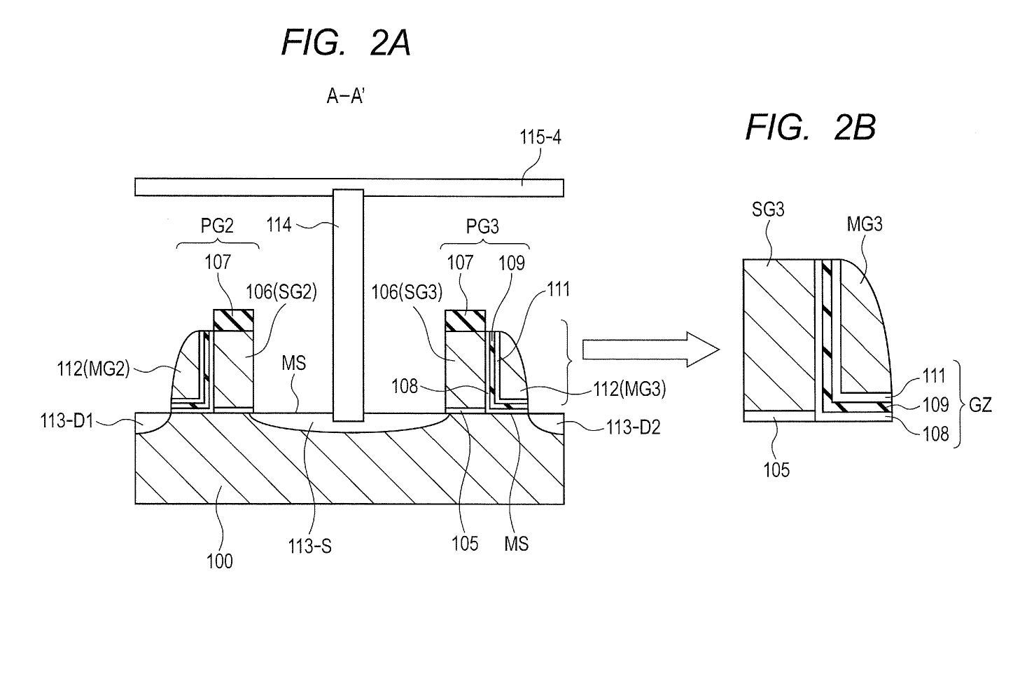

FIGS. 2A and 2B show cross-sectional structures along the line A-A′ in FIG. 1. FIG. 2A is a cross-sectional view transversely extending through two memory cells. FIG. 2B is a partially enlarged view of FIG. 2A. Over the main surface MS of a semiconductor substrate 100 made of silicon or the like and formed with P-type and N-type wells (not shown), the memory gates MG2 and MG3 each formed of a polysilicon (polycrystalline silicon) film 112 as a conductor film are present. In addition, the selection gates SG2 and SG3 each formed of a polysilicon film 106 as a conductor film and respectively facing the memory gates MG2 and MG3 are located over the main surface MS of the semiconductor substrate 100.

The second gate pair SG2 formed of the memory gate MG2 and the selection gate SG2 and the third gate pair SG3 formed of the memory gate MG3 and the selection gate SG3 each mentioned in the description of FIG. 1 are shown in the cross section. In the portion of the semiconductor substrate 100 located between the second and third gate pairs PG2 and PG3, the source region 113-S is formed. In addition, in the portions of the semiconductor substrate 100 located outside the second and third gate pairs PG2 and PG3, the drain regions 113-D each formed of the diffusion layer are formed such that these gate pairs are interposed therebetween.

The source region 113-S is coupled to the fourth source line 115-4 formed of a metal wiring layer via the contact portion 114. The fourth source line 115-4 extends over the memory gate MG2 and the selection gate SG2 and over the memory gate MG3 and the selection gate SG3 with an interlayer insulating film (not shown) interposed therebetween.

As shown in FIG. 2B, between the memory gates MG2 and MG3 and the main surface MS of the semiconductor substrate 100, a gate insulating film GZ having a laminated structure is located. The gate insulating film GZ having the laminated structure has an insulating film 108, an insulating film 109 serving as a charge storage film 109, and an insulating film 111 in order of increasing distance from the main surface MS side of the semiconductor substrate 100. Preferably, the insulating film 108 is formed of a silicon oxide film, the insulating film 109 is formed of a silicon nitride film, and the insulating film 111 is formed of a silicon oxide film. The gate insulating film GZ having the laminated structure is also present between the memory gate MG2 and the selection gate SG2 and between the memory gate MG3 and the selection gate SG3.

Each of the memory gates MG2 and MG3 has been processed into a sidewall shape.

The gate insulating film GZ also has a gate insulating film 105 between each of the selection gates SG2 and SG3 and the main surface MS of the semiconductor substrate 100. The gate insulating film GZ also has an insulating film 107 over the polysilicon film 106 of each of the selection gates SG2 and SG3. The insulating film 105 is formed of a silicon oxide film. The insulating film 107 is formed of a silicon nitride film.

The selection gates SG2 and SG3 are respectively arranged side by side with the memory gates MG2 and MG3 each with the layered gate insulating film GZ interposed therebetween.

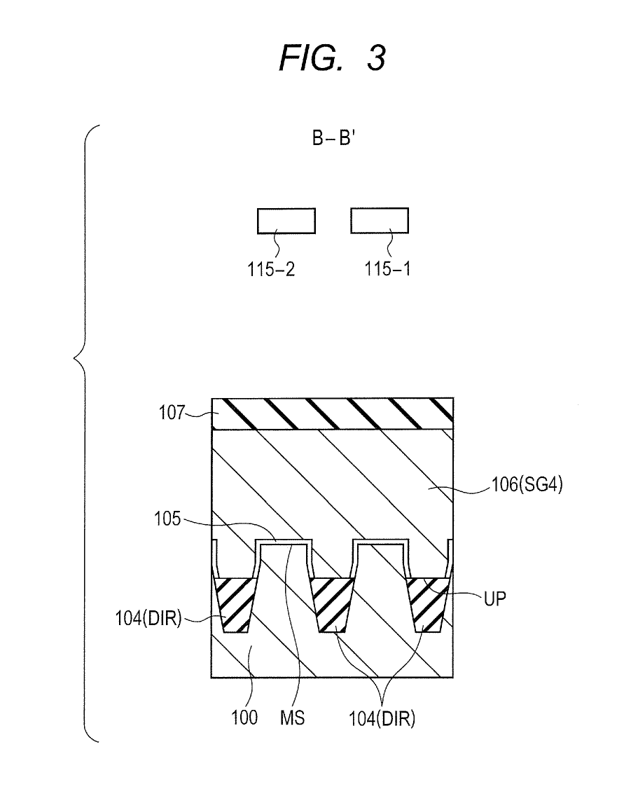

FIG. 3 is a partial cross-sectional view of the memory cell array along the line B-B′ in FIG. 1. FIG. 3 is a cross section vertically extending through the two memory cells and along the selection gate SG4. The insulating films between the first and second source lines 115-1 and 115-2 extending over the two memory cells and the insulating film 107 are omitted without being illustrated.

As can be seen from the drawing, an upper surface UP of each of isolation regions (isolation regions) DIR each formed of an insulating film 104 is located below the main surface MS of the semiconductor substrate 100 and has a shape recessed from the main surface MS of the semiconductor substrate 100.

Over the main surface MS of the semiconductor substrate 100 and over the upper surfaces UP of the isolation regions DIR, the selection gate SG4 and the gate insulating film 105 extend. The selection gate SG4 has a shape protruding toward the upper surface UP of each of the isolation regions DIR.

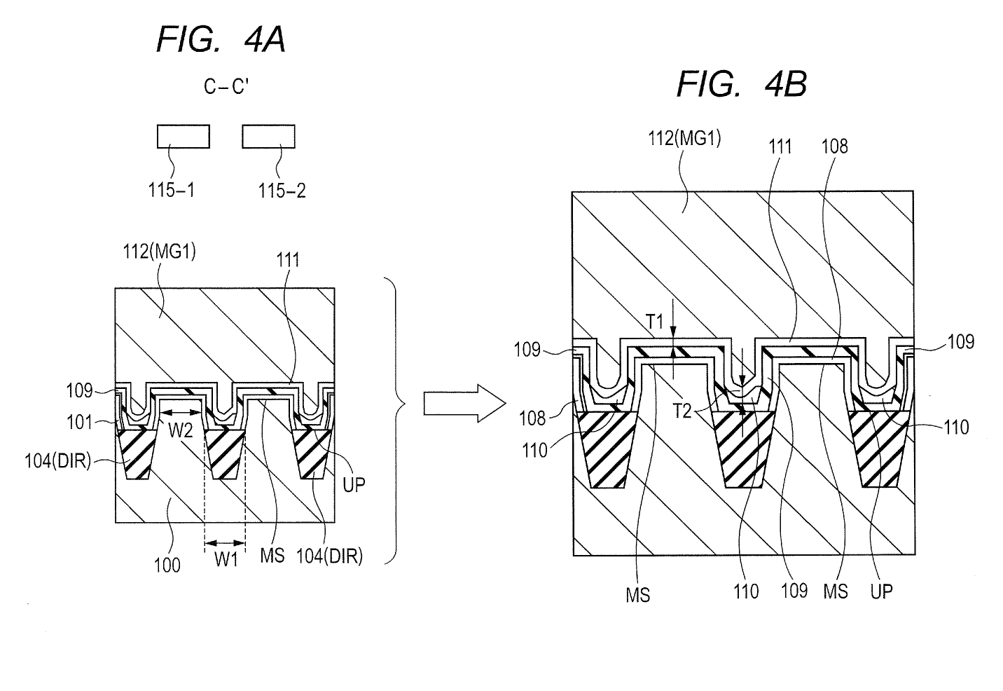

FIGS. 4A and 4B are partial cross-sectional views of the memory cell array along the line C-C′ in FIG. 1. FIG. 4B is a partially enlarged view of FIG. 4A. FIGS. 4A and 4B are also cross sections vertically extending through the two memory cells but along the memory gate MG1. The insulating films between the first and second source lines 115-1 and 115-2 and the memory gate MG1 located therebelow are omitted without being illustrated.

As can be seen from the drawing, the upper surface UP of each of the isolation regions DIR is present at the position different from that of the main surface MS of the semiconductor substrate 100. That is, the upper surface UP is located below the main surface MS. Accordingly, the upper surface UP of each of the isolation regions DIR has a shape recessed from the main surface MS of the semiconductor substrate 100.

Over the semiconductor substrate 100 and over the isolation regions DIR, the memory gate MG1 and the gate insulating film GZ having the laminated structure and located thereunder extend.

The memory gate MG1 has a shape selectively protruding toward the upper surface UP of each of the isolation regions DIR.

The gate insulating film GZ having the laminated structure has the insulating film 108, the insulating film 109 as the charge storage film, and the insulating film 111 each described with reference to FIG. 2 over the main surface MS of the portion of the semiconductor substrate which is not formed with the isolation regions DIR.

On the other hand, the portion of the gate insulating film GZ having the laminated structure which is located over each of the isolation regions DIR further has an insulating film 110 besides the insulating film 108, the insulating film 109 as the charge storage film, and the insulating film 111 each described with reference to FIG. 2. The insulating film 110 is formed of a silicon oxide film.

As a result, the insulating film present between the memory gate MG1 and the insulating film 109 as the charge storage film located thereunder has the difference between the thicknesses thereof over the isolation regions DIR and over the region of the semiconductor substrate 100 other than the isolation regions.

That is, the thickness of the insulating film present between the memory gate MG1 and the insulating film 109 as the charge storage film located thereunder is the total thickness T2 of the insulating film 110 and the insulating film 111 over each of the isolation regions DIR, as also shown in FIG. 4B. By contrast, the thickness of the insulating film present between the memory gate MG1 and the insulating film 109 is the thickness T1 of the insulating film 111 over the portion of the semiconductor substrate 100 without the isolation regions DIR. Here, of the insulating film present between the memory gate MG1 and the insulating film 109 as the charge storage film located thereunder, the portion located over the portion of the semiconductor substrate 100 without the isolation regions DIR and the portion located over each of the isolation regions DIR are respectively referred to also as a first insulating film and a second insulating film.

Accordingly, due to the presence of the insulating film 110, the thickness T2 of the second insulating film is larger than the thickness T1 of the first insulating film. In other words, the thickness of the first insulating film is smaller than the thickness of the second insulating film.

Here, the dimensions of the memory cell related to the present invention are such that the width W1 of each of the isolation regions in the cross section along the line C-C′ is about 60 nm and the width W2 of the active region in the memory cell region interposed between the isolation regions is about 100 nm.

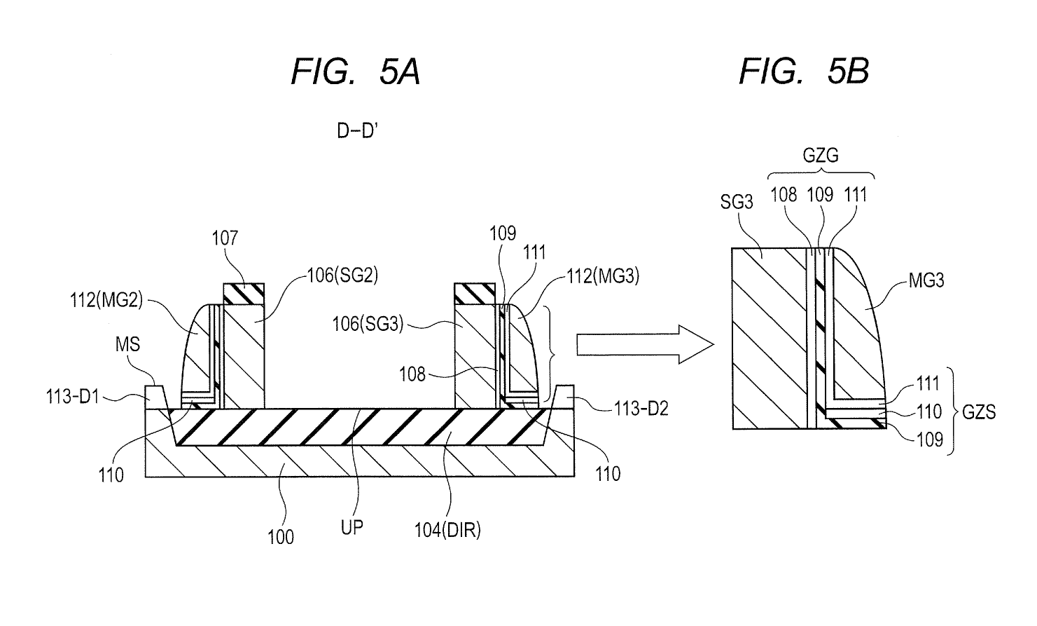

FIGS. 5A and 5B are partial cross-sectional views of the memory cell array along the line D-D′ in FIG. 1. FIG. 5A is a cross section along the isolation region 104 between the plurality of memory cells. FIG. 5B is a partially enlarged view of FIG. 5A.

As can be seen from the drawing, the upper surface UP of the isolation region DIR is located at a position recessed from the position of the main surface MS of the semiconductor substrate 100 having the drain region 113-D and, over the isolation region DIR104, the memory gates MG2 and MG3 shown in FIG. 1 are present.

In addition, the selection gates SG2 and SG3 respectively facing the memory gates MG2 and MG3 are located over the isolation region 104.

Under the memory gates MG2 and MG3, there is a gate insulating film GZS having the laminated structure. As shown in FIG. 5B, the gate insulating film GZS having the laminated structure and located over the isolation region DIR has the insulating film 109 serving as the charge storage film, the insulating film 110, and the insulating film 111 in order of increasing distance from the isolation region DIR side. Each of the memory gates MG2 and MG3 has been processed into a sidewall shapes

On the other hand, a gate insulating film GZG having the laminated structure and located between each of the memory gates MG2 and MG3 and each of the selection gates SG2 and SG3 respectively facing the memory gates MG2 and MG3 has the insulating films 111, 109, and 108.

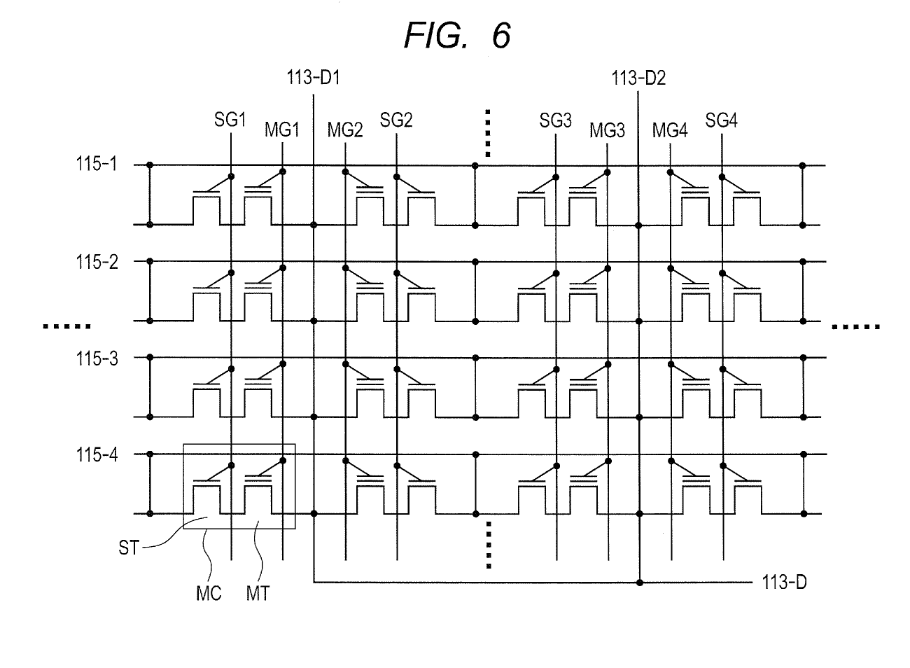

FIG. 6 is an equivalent circuit diagram of the memory cell array of the semiconductor device according to Embodiment 1. In the drawing, a circuit (including transistors and wiring) is shown correspondingly to the plan view of the memory cell array of FIG. 1. However, the drain line 113-D coupling the first and second drain lines 113-D1 and 113-D2 to each other is not shown in FIG. 1. The equivalent circuit shows a part of the memory cell array.

The rectangular region enclosed in the solid line (region with the reference numeral MC) corresponds to one memory cell. A plurality of the memory cells are arranged in rows and columns (as a matrix) to form the memory cell array. The memory cell MC has a memory transistor MT and a selection transistor ST. The drain of the memory transistor MT is coupled to the drain line 113-D. The source of the selection transistor is coupled to any of the source lines 115-1, 115-2, 115-3, and 115-4.

Next, the three basic operations of the memory cell according to Embodiment 1 which are: (1) read operation; (2) erase operation; and (3) write operation will be each described. However, the names of these three operations used here are typical ones. In particular, the erase operation and the write operation can also be called by the switched names. Here, for the sake of illustration, the description will be given of the memory cell formed as an n-MOS type. However, in principle, even a p-MOS-type memory cell can be similarly formed.

(1) Read Operation

By giving 0 V to the diffusion layer (Drain) on the memory gate (MG) side, giving a positive potential of about 1.0 V to the diffusion layer (Source) on the selection gate (SG) side, and giving a positive potential of about 1.3 V to the selection gate (SG), the channel under the selection gate (SG) is turned ON. Here, by giving a proper potential (i.e., middle potential between a threshold value in a write state and a threshold value in an erase state) which allows the difference between the threshold values of the memory gate (MG) given by the write state and the erase state to be recognized to the memory gate (MG), charge information held in the memory cell MC can be read as a current. Here, if settings are made such that the middle potential between the threshold value in the write state and the threshold value in the erase state is 0 V, the voltage applied to the memory gate (MG) need not be boosted in a power source circuit desirably for high-speed reading.

(2) Erase Operation

A voltage of, e.g., −6 V is applied to the memory gate (MG) and a voltage of, e.g., 0 V is applied to the selection gate (SG). On the other hand, 6 V is applied to the diffusion layer (Drain) on the memory gate (MG) side and 1.5 V is applied to the diffusion layer (Source) on the selection gate (SG) side. However, the diffusion layer on the selection gate SG side may also be brought into an electrically floating (open) state. As a result, holes are generated in the semiconductor substrate 100 and injected into the change storage film 109.

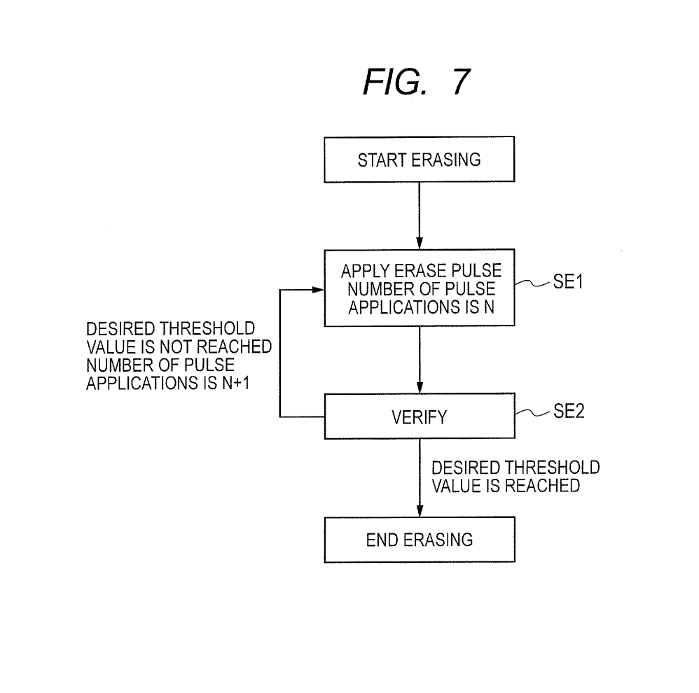

FIG. 7 is a flow chart showing an example of the erase operation to the memory cell MC. When the erase operation is actually performed to the memory cell MC, as shown in FIG. 7, an erase pulse is applied to inject holes into the charge storage film 109 and thereby effect the erase operation (Step SE1). Then, by a verify operation, it is verified whether or not the memory cell MC has reached a desired threshold value (Step SE2). A sequence is repeated in which, when the memory cell MC has not reached the desired threshold value, the erase pulse is applied again.

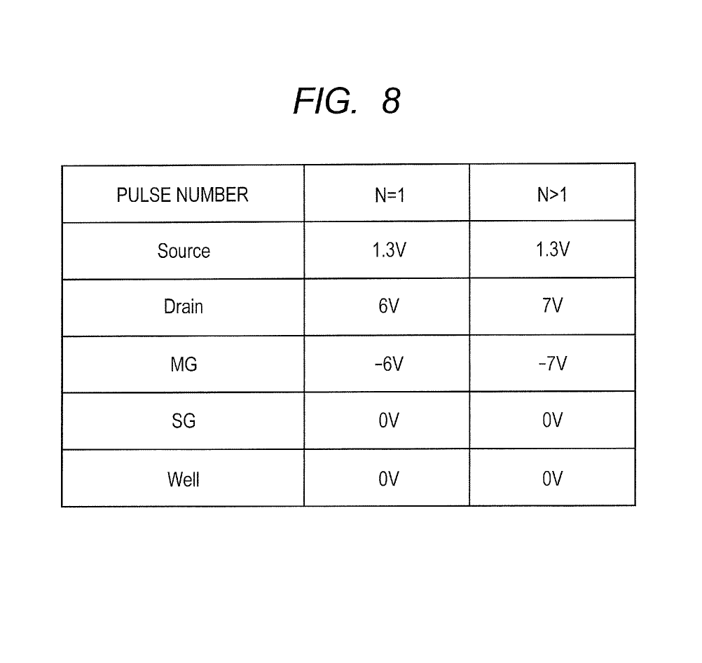

Typical applied voltages are as shown above. However, erase conditions after the verification need not necessarily be the same as the conditions for the first application of the erase pulse. FIG. 8 shows an example of the erase pulse in that case. In FIG. 8, N=1 shows the first application of the erase pulse, and N>1 shows the second or subsequent application of the erase pulse. Here, the “Well” shown in the drawing indicates the region of the semiconductor substrate 100 which supplies a substrate potential to the memory transistor MT and the selection transistor ST.

(3) Write Operation

To the memory cell MC of Embodiment 1, writing is performed by injecting electrons therein from the semiconductor substrate 100 side. As a method for injecting electrons from the semiconductor substrate 100 side, a voltage of, e.g., 0.9 V is applied to the selection gate (SG), a voltage of, e.g., 4.5 V is applied to the drain region (Drain) on the memory gate (MG) side, and a voltage lower than the voltage applied to the drain region (Drain), e.g., 0.3 V is applied to the source region (Source) on the selection gate (SG) side. In this manner, the injection of charges (electrons) is performed locally into the end portion of the memory gate (MG) located on the selection gate (SG) side. The injection method is known as a SSI (Source Side Hot Electron) injection method.

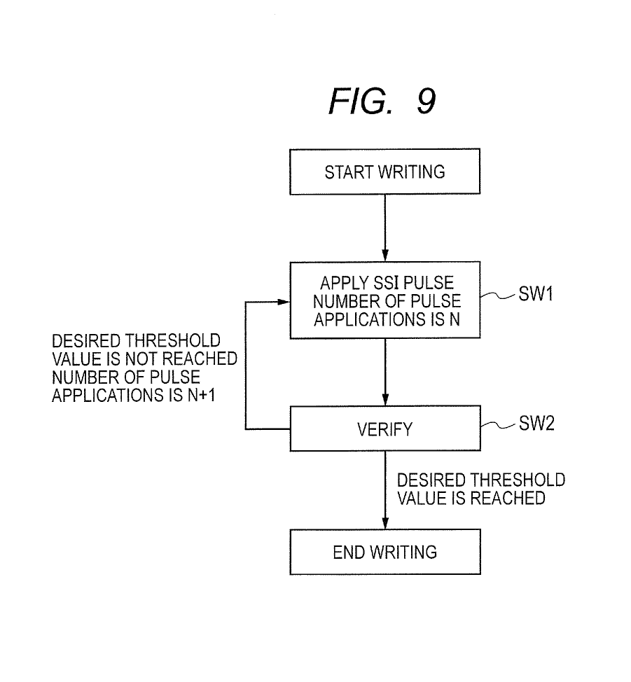

FIG. 9 is a flow chart showing an example of a write operation to the memory cell. As shown in FIG. 9, when the erase operation is actually performed to the memory cell, a SSI pulse is applied to inject electrons into the charge storage film 109 and thereby effect the write operation (Step SW1). Then, by a verify operation, it is verified whether or not the memory cell MC has reached a desired threshold value (Step SW2). A sequence is repeated in which, when the memory cell MC has not reached the desired threshold value, the SSI pulse is applied again.

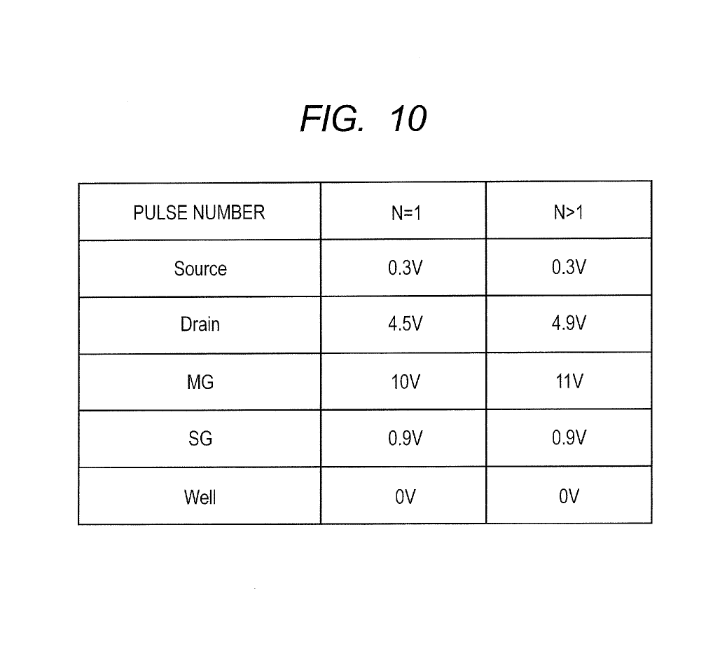

Typical applied voltages are as shown above. However, in the same manner as in erasing after the verification, write conditions after the verification need not necessarily be the same as the conditions for the first application of the SSI pulse. FIG. 10 shows an example in that case. FIG. 10 is a view showing an example of a write pulse voltage to the memory cell. In FIG. 10, N=1 shows the first application of the SSI pulse, and N>1 shows the second or subsequent application of the SSI pulse.

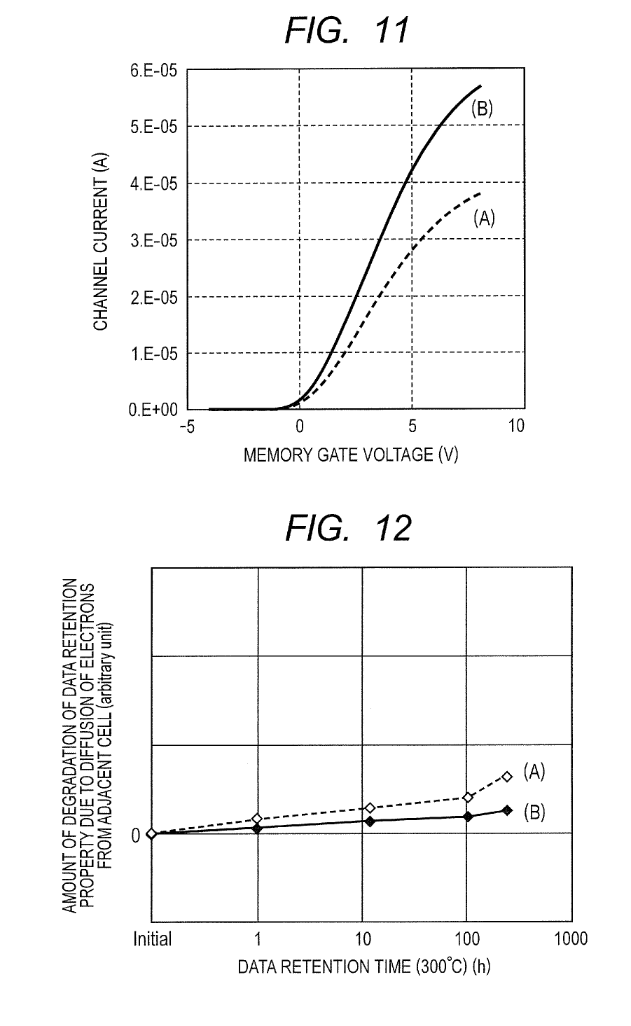

FIG. 11 is a view showing, for the sake of comparison, the respective current-voltage characteristics of the memory gate transistors in a comparative example (A) and Embodiment 1 (B) under conditions for reading to the memory cells. The abscissa axis shows a memory gate voltage, while the ordinate axis shows a channel current. FIG. 12 is a view showing, for the sake of comparison, the degradation of a data retention property due to the diffusion of electrons from an adjacent cell in each of the comparative example (A) and Embodiment 1 (B). Note that, to accelerate the degradation due to the diffusion of electrons, the memory cells were allowed to stand at 300° C. Here, the planar structure of the memory cell array of a semiconductor device according to the comparative example is the same as in FIG. 1. However, the cross-sectional structure of the memory cell array of the semiconductor device according to the comparative example is different from that of Embodiment 1. For example, the cross section of the comparative example corresponding to the cross-sectional view (FIG. 4A) along the line C-C′ in FIG. 1 is different. That is, in the comparative example of the semiconductor device according to Embodiment 1, the upper surface of each of the isolation regions is present at substantially the same position as that of the main surface of the semiconductor substrate. In other words, the upper surface of each of isolation regions as shown in FIGS. 4A and 4B does not have a shape recessed from the main surface of the semiconductor substrate. In addition, over the semiconductor substrate and the isolation regions, an insulating film (silicon oxide film), a charge storage film (silicon nitride film), an insulating film (silicon oxide film), and a memory gate extend. Briefly, in the comparative example, the length of the charge storage film over each of the isolation regions is approximately the same as the width of the isolation region and is shorter than the length of the charge storage film 109 over the isolation region DIR in Embodiment 1.

As can be seen from FIG. 11, Embodiment 1 (B) allows a channel current, i.e., a read current to be increased to be larger than that in the comparative example (A). Therefore, Embodiment 1 is advantageous for high-speed reading. As is obvious from FIG. 12, it can be seen that the amount of degradation of the memory cell of Embodiment 1 (B) has decreased and the reliability thereof has improved compared to those of the memory cell of the comparative example (A).

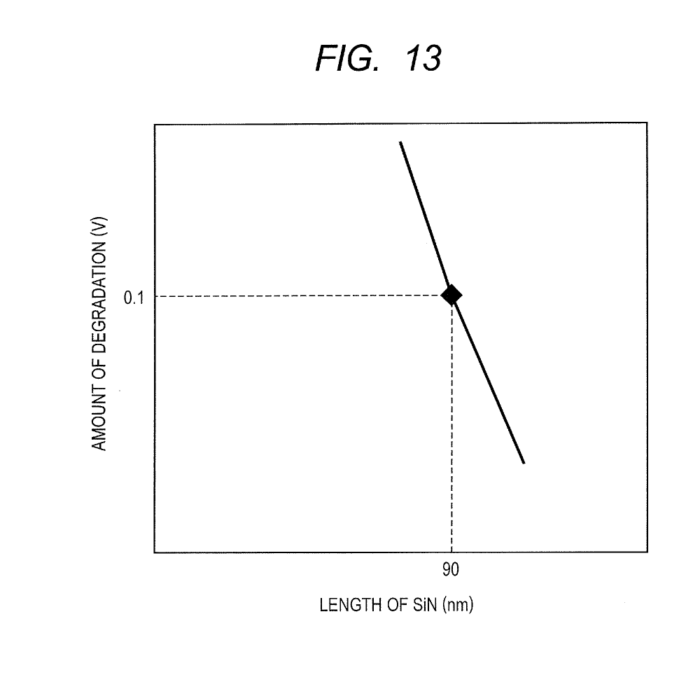

FIG. 13 is a view in which the amount of degradation of the reliability of the memory cell due to the diffusion of charges from an adjacent cell is plotted against the length of the silicon nitride film (charge storage film) to the adjacent cell. In the same manner as in FIG. 12, as the length of the silicon nitride film to the adjacent cell increases, the time required for the diffusion of charges increases so that the amount of the degradation decreases. As shown in FIG. 13, it has become clear that, as long as a length of approximately 90 nm can be ensured as the length of the silicon nitride film to the adjacent cell, the amount of the degradation can be suppressed to about 0.1 V. That is, when the width of the isolation region in the structure of the comparative example is smaller than 90 nm, the application of the structure of Embodiment 1 is more effective.

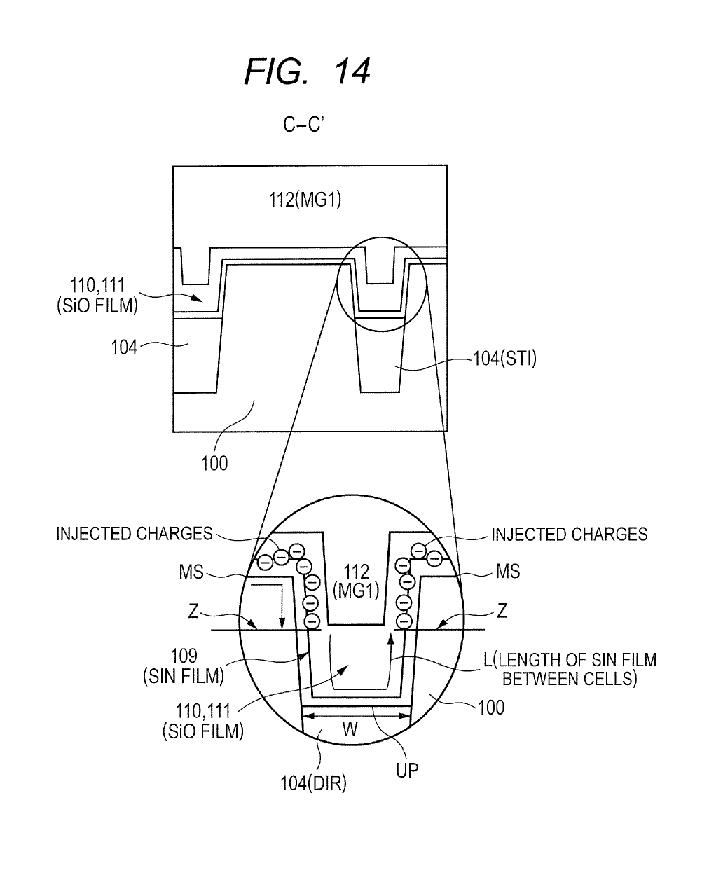

The reason why the various effects described above can be obtained will be described based on FIGS. 4A and 4B and FIG. 14 which is a schematic illustrative view.

As shown in FIGS. 4A and 4B and 14, the upper surface UP of the isolation region DIR is located below the main surface MS of the semiconductor substrate 100 and has the shape recessed from the main surface MS of the semiconductor substrate 100.

By providing a structure (so-called Fin structure) in which a part of the memory gate MG1 and the charge storage film 109 located thereunder protrude toward the recess, charges are injected extensively to portions (portions Z) of the charge storage film 109 present in the foregoing recessed portion and the gate width (channel width) of the memory gate MG1 extends to over the isolation region DIR, as shown in the schematic view of FIG. 14. This allows the active region of the memory cell to be larger in area than in the comparative example. As a result, the read current can be increased to be larger than in the comparative example (A).

In addition, as shown in FIG. 4, not only the part of the memory gate MG1 and the charge storage film 109 located thereunder protrude toward the upper surface UP of the isolation region DIR, but also the insulating films 110 and 111 are provided between the portion of the charge storage film 109 located over the upper surface UP of the isolation region DIR and the memory gate MG1. Accordingly, the insulating film between the portion of the charge storage film 109 located over the upper surface UP of the isolation region DIR and the memory gate MG1 is configured to be thicker than the insulating film between the portion of the charge storage film 109 located over the main surface MS of the semiconductor substrate 100 and the memory gate MG1. Therefore, as shown in FIG. 14, it is possible to limit the region (data retention region) of the charge storage film 109 which is located over the isolation region DIR and in which charges are stored. As a result, the length L of the region of the charge storage film 109 which is located between the adjacent cells and in which charges are not stored (region which does not retain data) is larger than the width W of the isolation region DIR. Here, the width W is assumed to be the width of the isolation trench in the main surface MS. Consequently, the diffusion of charges is not easily performed between the adjacent cells to improve the data retention property (reduce the amount of the degradation). Note that the region of the charge storage film in which charges are stored is the region of the charge storage film interposed between the memory gate and the active region. On the other hand, the region of the charge storage film in which charges are not stored is the region other than the region in which charges are stored.

A multi-value memory for storing 1 bit or more of data in each of the memory cells implements a multi-value configuration by adjusting the threshold value thereof using the number of electrons injected into the silicon nitride film, though not described in Embodiment 1. Accordingly, of the multi-value memory, higher-accuracy control of the threshold value of the memory cell is required so that the present embodiment is used preferably therefor.

In the semiconductor device of Embodiment 1, even when the width of the isolation region is reduced through the scaling of the memory cells to reduce the distance between the adjacent memory cells, the effective length of the charge storage film over each of the isolation regions can be increased. Therefore, it is possible to reduce mutual interference between the electrons or holes injected into the charge storage film of the memory cell and diffused into the portions of the charge storage film located over the isolation regions.

Also, in the semiconductor device of Embodiment 1, even when the gate width in planar view is reduced through the scaling of the memory cells, the effective channel width (gate width) can be increased. Therefore, it is possible to ensure a read current corresponding to a high-speed operation.

Further, in the semiconductor device of Embodiment 1, even under circumstances where an external environment is severe, such as when the semiconductor device is used as an in-vehicle product, it is possible to ensure high quality and reliability.

In addition, through the scaling of a product chip size, it is possible to improve the number of products obtained from a single wafer and thereby achieve a cost reduction.

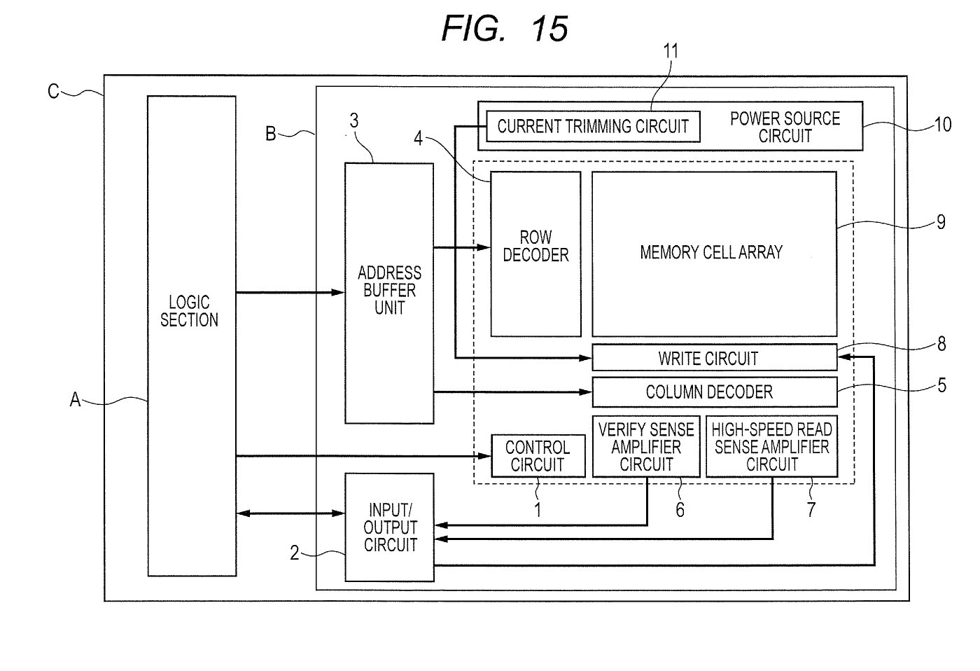

Next, an example when the memory cell array according to Embodiment 1 is applied to a semiconductor device with a large scale integrated circuit will be described based on FIG. 15. A semiconductor device C shown in FIG. 5 has a logic section A and a memory section B. The memory section B has a control circuit 1, an input/output circuit 2, an address buffer 3, a row decoder 4, a column decoder 5, a verify sense amplifier circuit 6, a high-speed read sense amplifier circuit 7, a write circuit 8, a memory cell array 9, and a power source circuit 10.

The control circuit 1 temporarily stores a control signal input from the logic section A to control the memory section B. The control circuit 1 also controls a potential at the gate electrode of each of the memory cells in the memory cell array 9. To the input/output circuit 2, various data including data to be read from or written to the memory cell array 9 and program data is input/output. The address buffer 3 temporarily stores an address input from the logic section A. To the address buffer 3, the row decoder 4 and the column decoder 5 are each coupled. The row decoder 4 performs decoding based on the row address output from the address buffer 3. The column decoder 5 performs decoding based on the column address output from the address buffer 3.

The verify sense amplifier circuit 6 is a sense amplifier for erase/write verification. The high-speed read sense amplifier circuit 7 is a read sense amplifier used during data reading. The write circuit 8 latches data to be written which is input via the input/output circuit 2 to control data writing. In the memory cell array 9, the memory cells MC as minimum storage units are arranged as an array.

The power source circuit 10 includes a voltage generation circuit for generating various voltages used during data writing, erasing, verification, and the like, a current trimming circuit 11 for generating an arbitrary voltage value and supplying the generated voltage value to the write circuit, and the like.

The logic section A is, e.g., a central processing unit (CPU). Accordingly, the semiconductor device C is, e.g., a microcontroller with an embedded nonvolatile memory. The rate of the area occupied by the nonvolatile memory in the semiconductor chip of the microcontroller with the embedded nonvolatile memory is extremely high. Through the scaling of the memory cells, the area of the nonvolatile memory can be reduced, and consequently the area of the microcontroller with the embedded nonvolatile memory can be reduced.

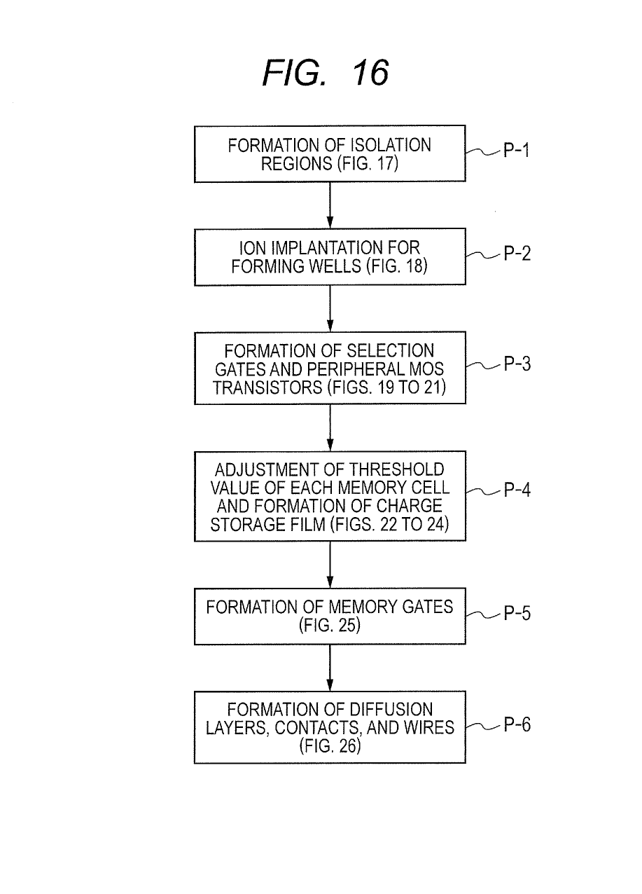

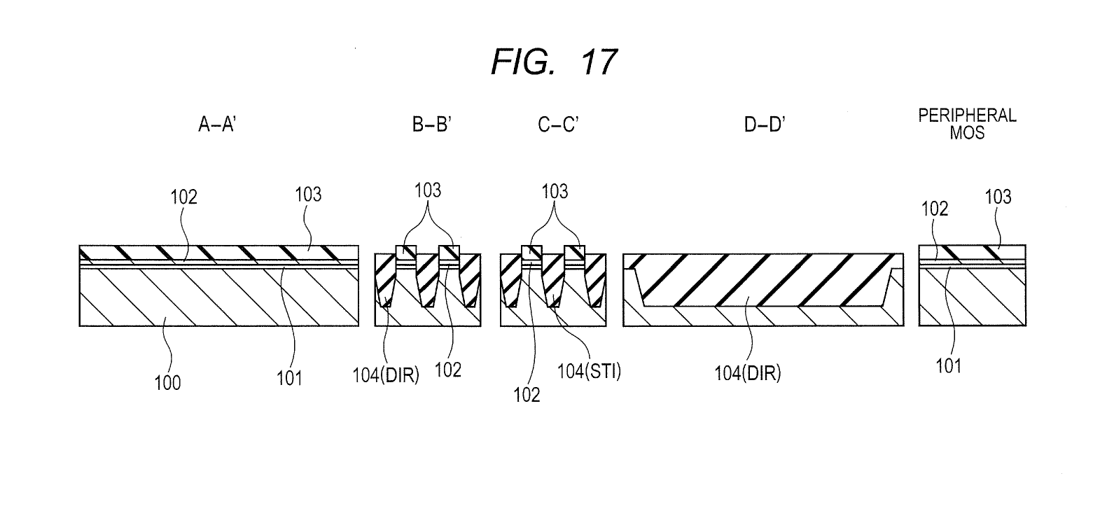

Next, using FIGS. 16 to 26, a description will be given of a manufacturing method of the semiconductor device according to Embodiment 1. FIG. 16 is a flow chart showing the outline of the manufacturing method having steps P-1 to P-6. FIGS. 17 to 26 are cross-sectional views in each of process steps corresponding to the steps P-1 to P-6 shown in the flow chart. Note that each of the cross-sectional views separately shows the cross sections of a nonvolatile memory cell array region along the lines A-A′, B-B′, C-C′, and D-D′ of FIG. 1 and a cross section corresponding to a peripheral MOS region not shown in FIG. 1. The peripheral MOS region is a region outside the memory cell array region where MOS (Metal Oxide Semiconductor) transistors (peripheral MOS transistors) exist. For example, the peripheral MOS transistors include the control circuit 1 and the input/output circuit 2 each shown in FIG. 15. In FIGS. 1 to 6, the elements denoted by the reference numerals mostly have functional names while, in FIGS. 17 to 26, the elements denoted by the reference numerals have names represented by material names. In FIGS. 1 to 6 and 17 to 26, the elements denoted by the same reference numerals are identical.

(a) Process Step P-1

The semiconductor substrate 100 made of silicon is provided and thermally oxidized to form a silicon oxide film 101 of about 10 nm over the main surface of the semiconductor substrate 100. Thereafter, a polysilicon film 102 of about 10 nm and a silicon nitride film 103 of about 50 nm are deposited in this order over the silicon oxide film 101.

Using lithographic and etching techniques, trenches for STI (Shallow Trench Isolation) regions are each formed at a depth of about 150 nm from the main surface of the semiconductor substrate 100. The silicon oxide film (insulating film) 104 is deposited and polished by a CMP (Chemical Mechanical Polishing) method using the silicon nitride film 103 as a stopper to be left in the trenches and thereover. This allows the silicon oxide film 104 to be formed to a position higher in level than that of the main surface of the semiconductor substrate 100 (FIG. 17).

(b) Step P-2

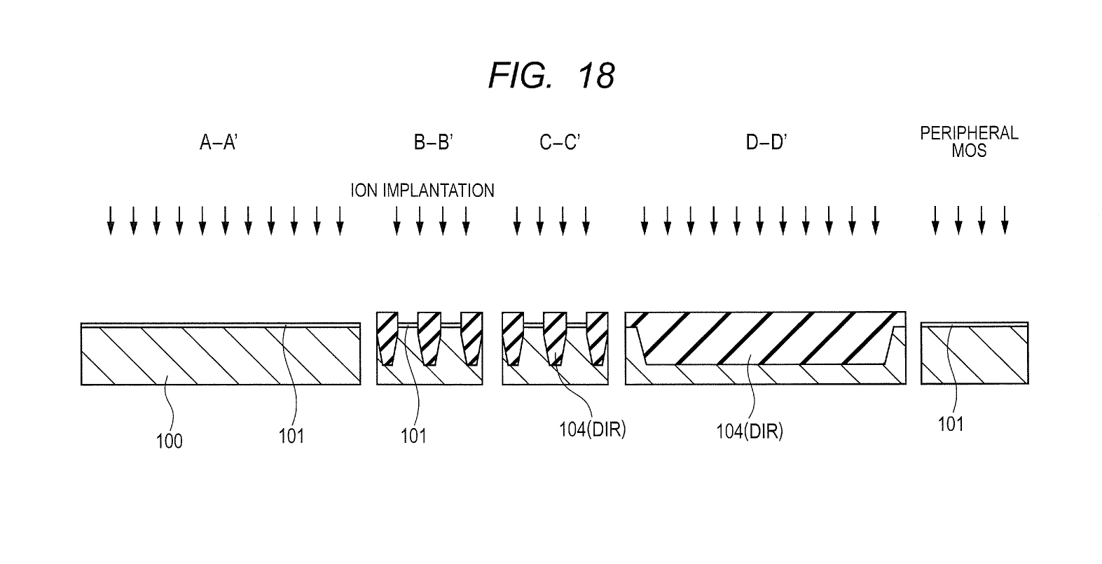

The silicon nitride film 103 and the polysilicon film 102 located thereunder are removed by wet etching and dry etching. Using the remaining silicon oxide film 101 as a through film for ion implantation, the semiconductor substrate 100 is subjected to the ion implantation. That is, via the silicon oxide film 101 thinner than the silicon oxide film 104, P-type and N-type impurities are selectively ion-implanted into the semiconductor substrate 100 to form P-type and N-type wells (not shown) (FIG. 18).

(c) Step P-3

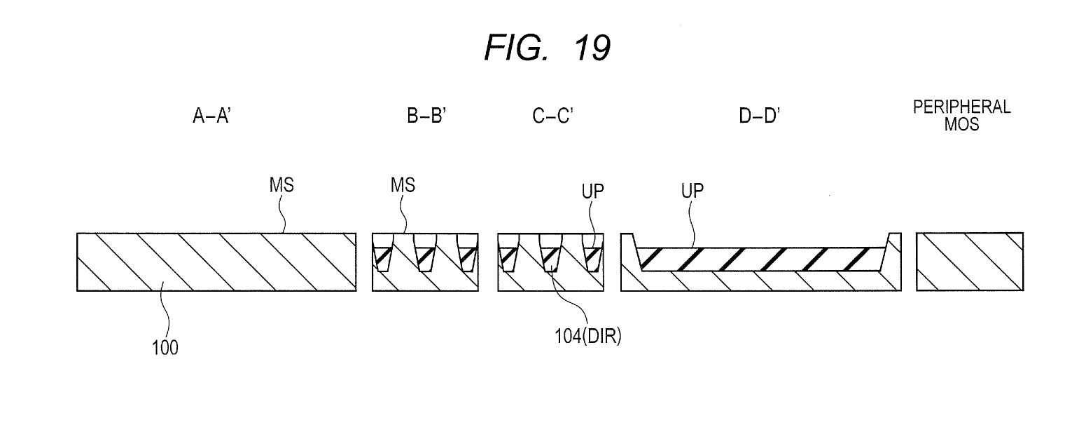

By dry etching or wet etching, the silicon oxide film 101 is removed. In addition, the silicon oxide film 104 in each of the isolation regions DIR is partly removed to have a depth of, e.g., about 50 nm from the main surface of the semiconductor substrate 100. As a result, the main surface of the semiconductor substrate 100 is newly exposed to form the main surface MS. On the other hand, the upper surface UP of the silicon oxide film 104 in the isolation region DIR is at a depth of about 50 nm from the main surface MS of the semiconductor substrate 100 to be recessed from the main surface MS of the semiconductor substrate 100 (FIG. 19).

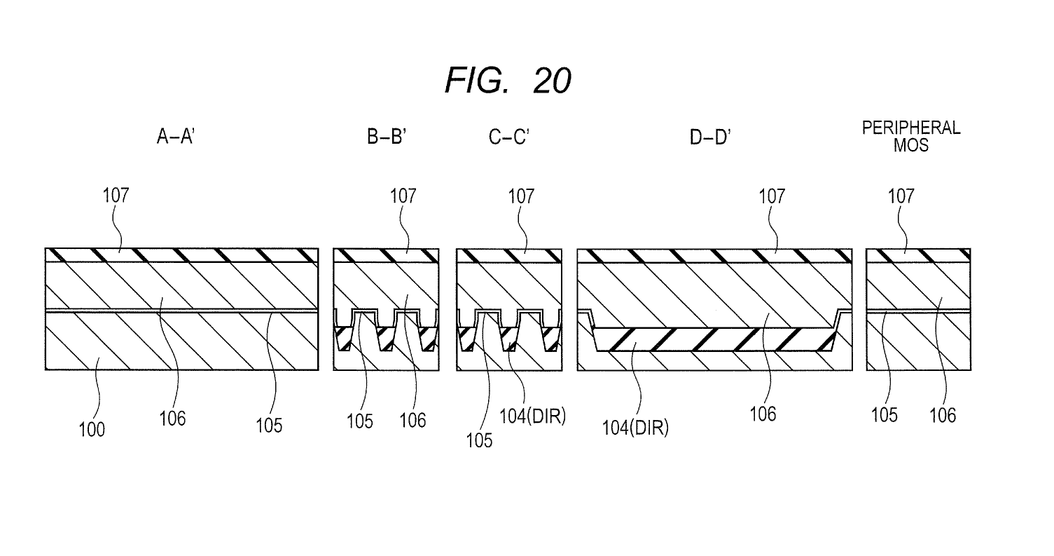

Subsequently, the silicon oxide film (insulating film) 105 of about 1.4 nm serving as the gate insulating film of each of the peripheral MOS transistors and the selection transistors is formed over the main surface MS of the semiconductor substrate 100 by a thermal oxidation method, and the polysilicon film (conductor film) 106 having a thickness of about 80 nm and serving as the gate electrode of each of the peripheral MOS transistors and the selection transistors and the silicon nitride film (insulating film) 107 having a thickness of about 20 nm are deposited (FIG. 20). Here, using lithographic and dry etching techniques, the silicon oxide film 105 may also be formed to have a plurality of levels of thicknesses.

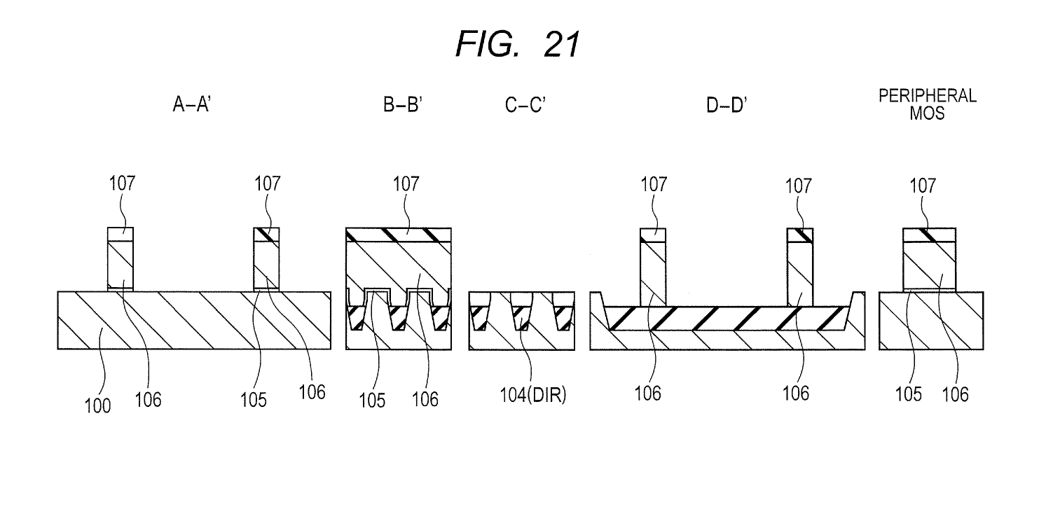

Next, using lithographic and etching techniques, the gates of the peripheral MOS transistors and the gates of the selection transistors each formed of the polysilicon film 106 are formed (FIG. 21).

(d) Step P-4

Using lithographic and ion implantation techniques, ion implantation for adjusting the threshold of each of the memory cells is performed (not shown).

Next, the silicon oxide film (insulating film) 108 having a thickness of about 4 nm is formed by a thermal oxidation method. Then, the silicon nitride film (charge storage film) 109 having a thickness of about 9 nm is deposited. Subsequently, the silicon oxide film (insulating film) 110 having a thickness of about 20 nm is deposited. In this manner, the recess in the upper surface of the isolation region DIR is filled with the insulating films.

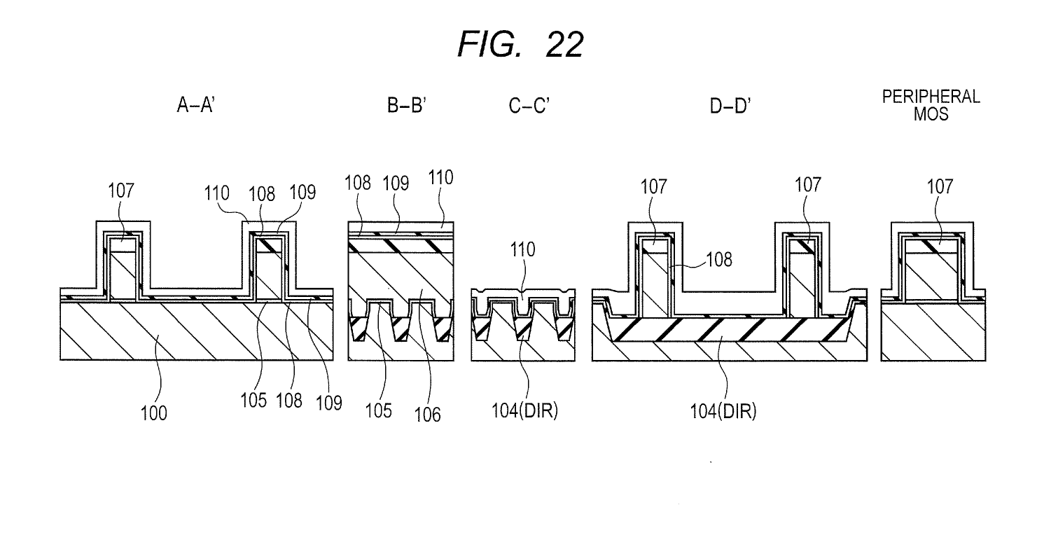

At this time, the silicon oxide film 108, the silicon nitride film 109, and the silicon oxide film 110 are deposited such that the total of the physical thicknesses thereof is larger than the width of the upper surface UP of the isolation region DIR shown in the cross section along the line C-C′ to allow the recess in the isolation region DIR to be filled with the insulating films. At this time, over the gate of each of the peripheral MOS transistors also, the silicon oxide film 108, the silicon nitride film 109, and the silicon oxide film 110 are formed by, e.g., a CVD method (FIG. 22).

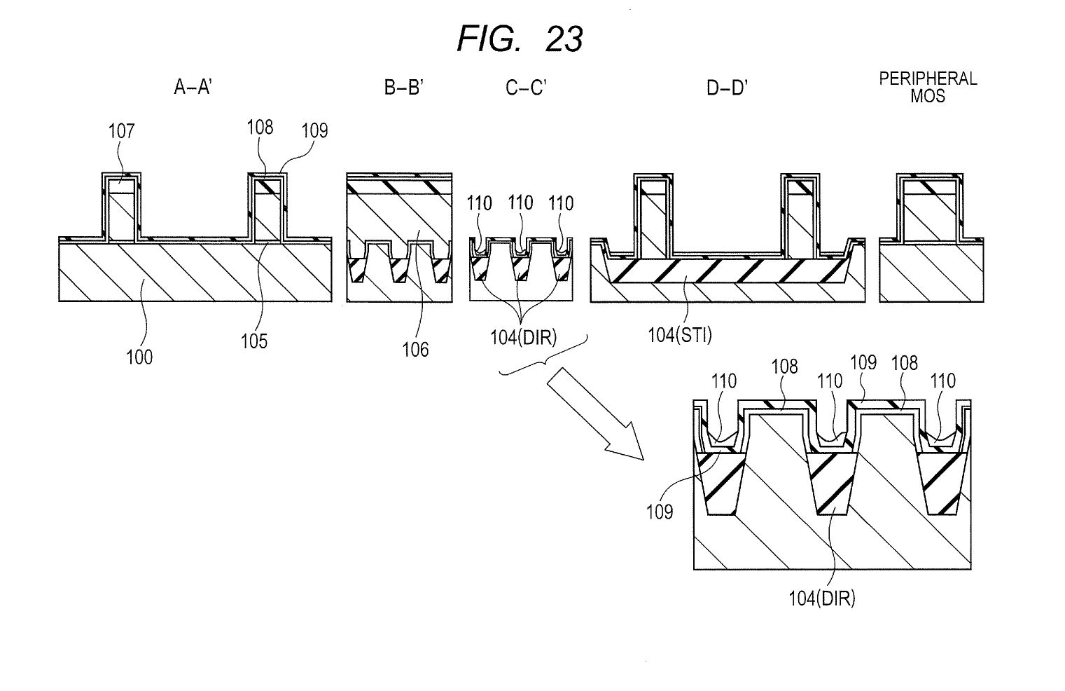

Next, the silicon oxide film 110 is selectively removed by wet etching such that the portion thereof corresponding to about 25 nm is left only over the silicon nitride film 109 over each of the isolation regions DIR over which the memory gates extend, as shown in the C-C′ cross section and the enlarged cross section thereof. That is, the silicon oxide films 110 in the A-A′ cross section, in the B-B′ cross section, in the D-D′ cross section, and of the peripheral MOS transistors are removed (FIG. 23).

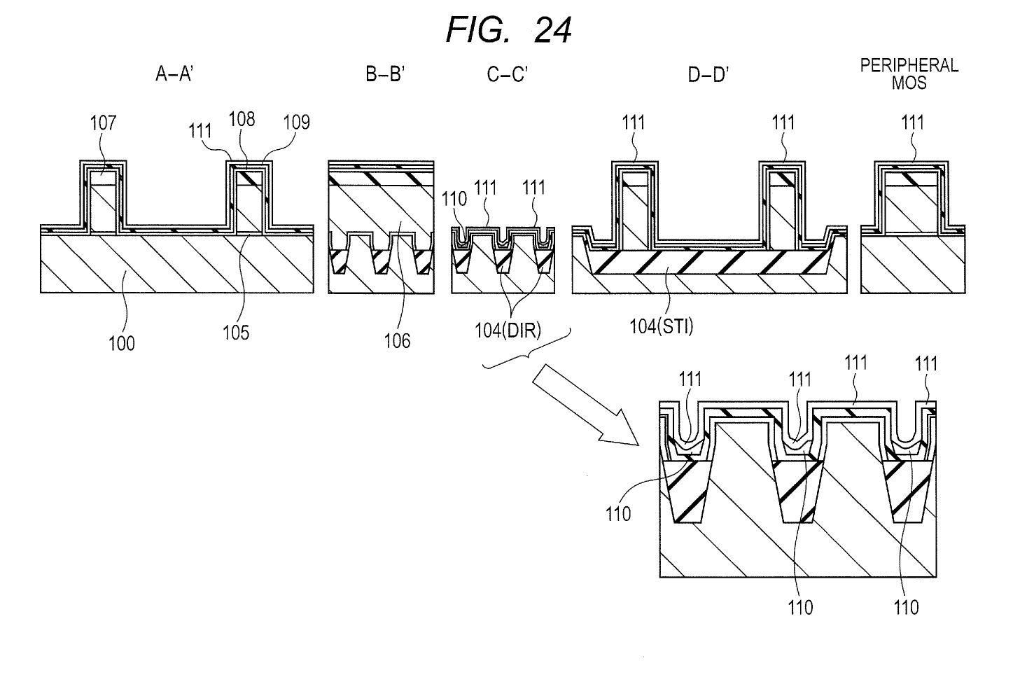

Thereafter, over the gates in the memory cell array region and the peripheral MOS region, the silicon oxide film 111 of about 7 nm is newly deposited. By the process, as can be seen from the C-C′ cross section and the enlarged cross section thereof, under each of the memory gates, the thickness of the oxide film over the silicon nitride film in each of the isolation regions can be increased to be larger than the thickness of the oxide film over the silicon nitride film 109 in the active region of the memory cell region (FIG. 24).

(e) Step P-5

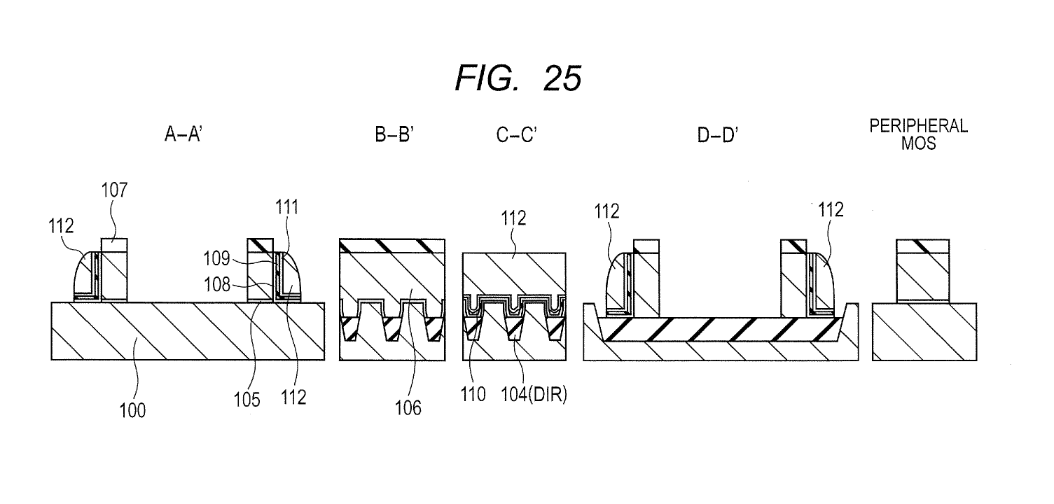

Next, the polysilicon film (conductor film) 112 serving as the gate electrodes of the memory gates is deposited to, e.g., 40 nm and etched back to form the memory gates each having a sidewall shape in the memory cell array region. At this time, sidewall electrodes are formed on both sides of each of the selection transistors which is interposed therebetween. However, using lithographic and etching techniques, the unneeded one of the sidewall gates located on one side of each of the memory gates is removed so that the sidewall gate is formed only on the other side of the memory gate. Also, the sidewall gates on both sides of each of the peripheral MOS gates are similarly removed (FIG. 25).

(f) Step P-6

Thereafter, ion implantation for the diffusion layers of each of the p-MOS and n-MOS transistors is performed to form the diffusion layers 113 in the memory cell array region and the peripheral MOS region. At this time, the gate electrodes of the selection transistors and/or the peripheral MOS transistors and the diffusion layers thereof may also be silicidized for lower resistances. In that case, after the silicon nitride films 107 over the gate electrodes of the selection transistors and/or the peripheral MOS transistors are removed, the silicidation is performed.

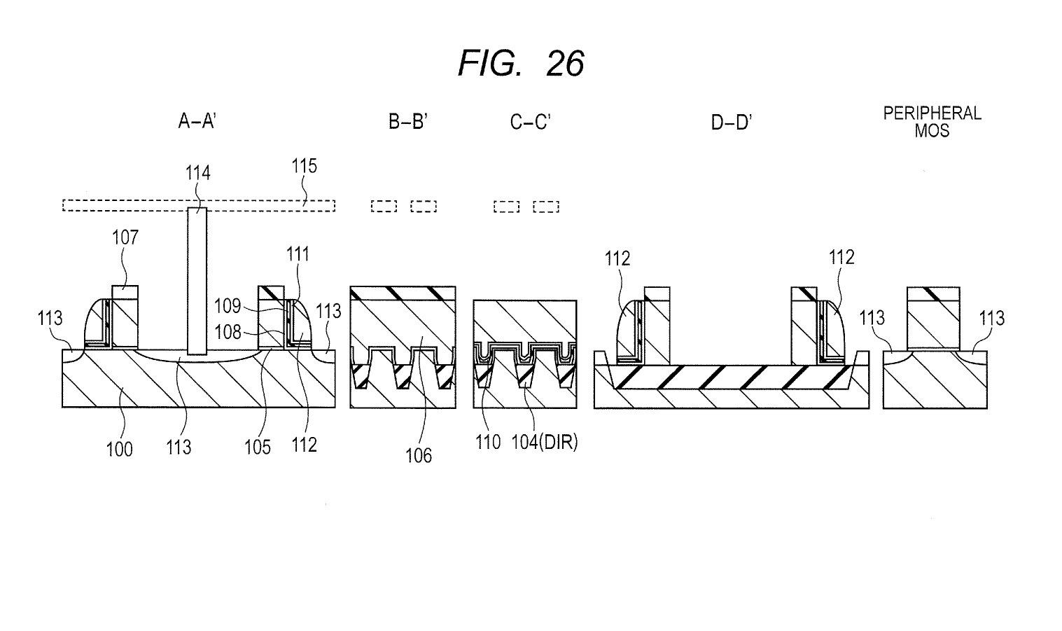

Thereafter, a wiring interlayer film is deposited, and then contact holes for providing conduction between the memory transistors, the selection transistors, the peripheral MOS transistors, and the diffusion layers are formed. In the contact holes, a metal film is deposited to form contact portions 114. Subsequently, over the interlayer insulating film, a metal film is deposited and patterned to form wires 115 (FIG. 26).

It may also be considered to remove the silicon nitride film over the isolation region and thereby prevent injected charges from being diffused into the regions between the adjacent cells. However, it is difficult to remove the portion (corresponding to L in FIG. 14) of the silicon nitride film located over the recessed and extremely narrow isolation region which does not form the gate insulating films of the memory gates, while leaving the portion (corresponding to Z in FIG. 14) of the silicon nitride film which forms the gate insulating films of the memory gates.

Leaving the silicon nitride film located over the isolation region as performed in Embodiment 1 allows the manufacturing process to be further simplified.

### Embodiment 2

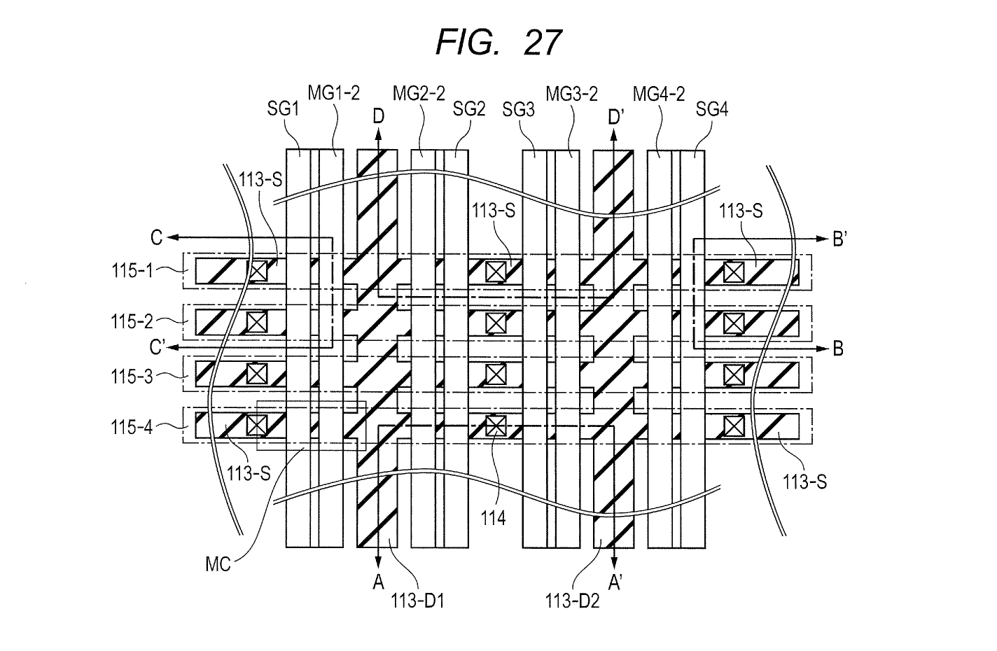

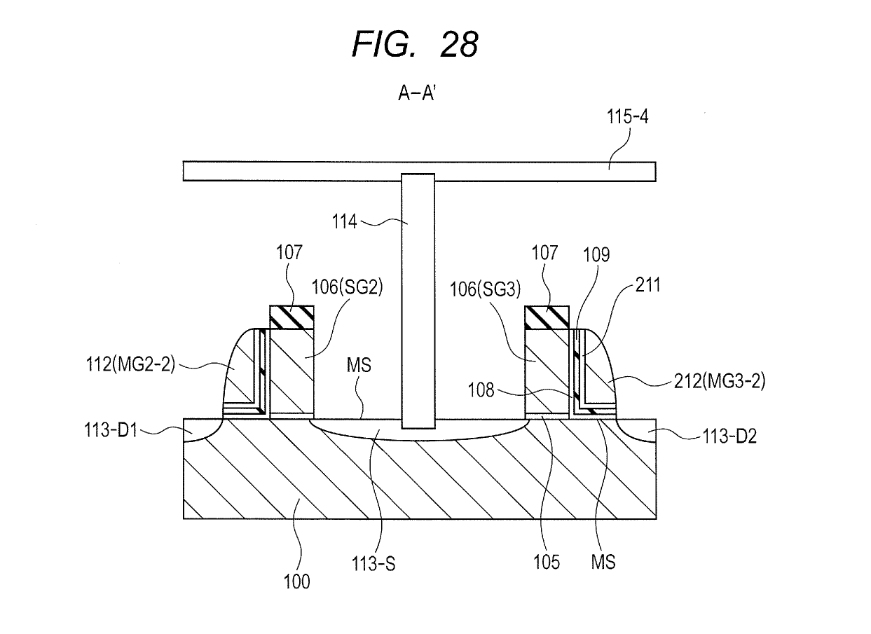

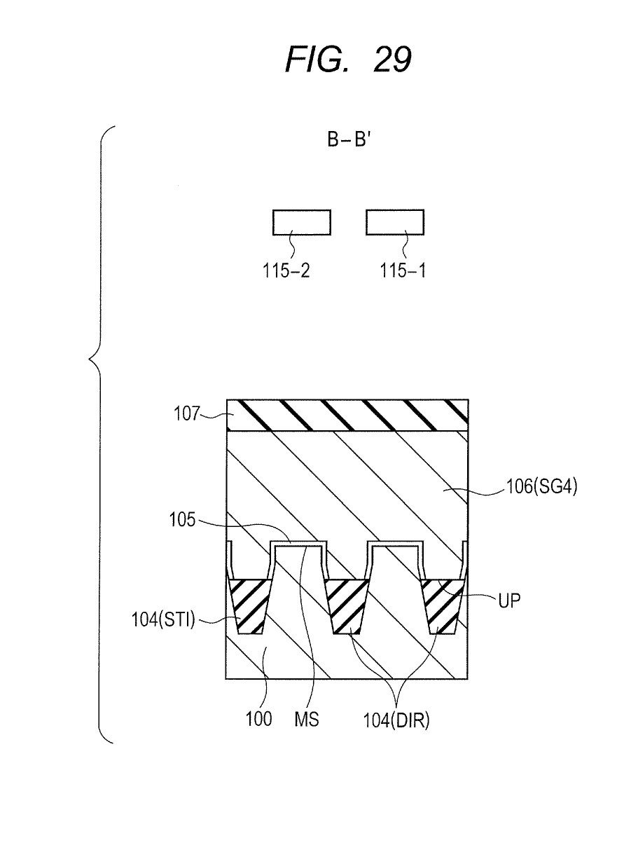

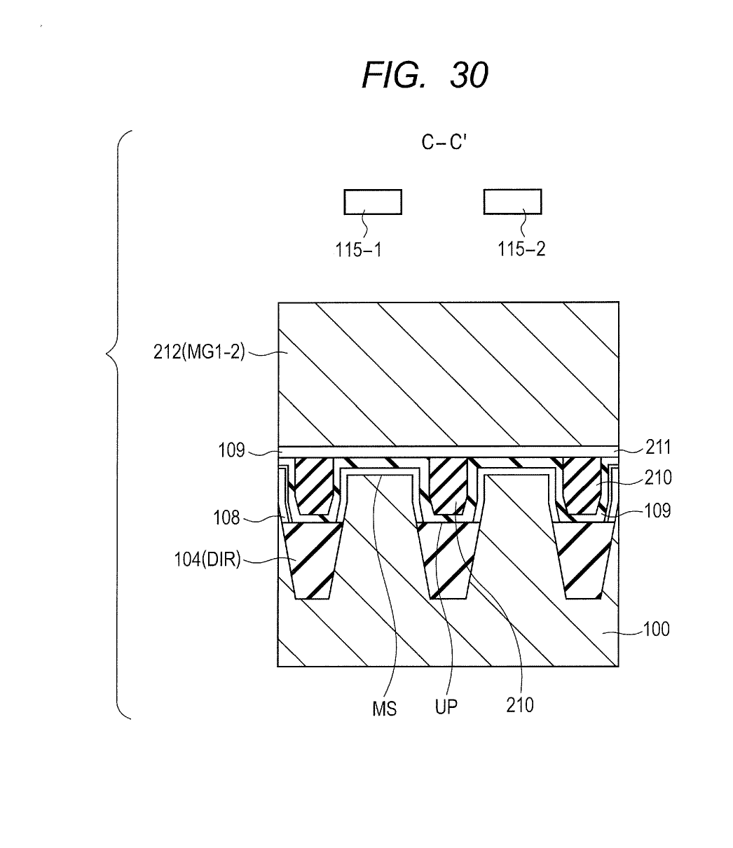

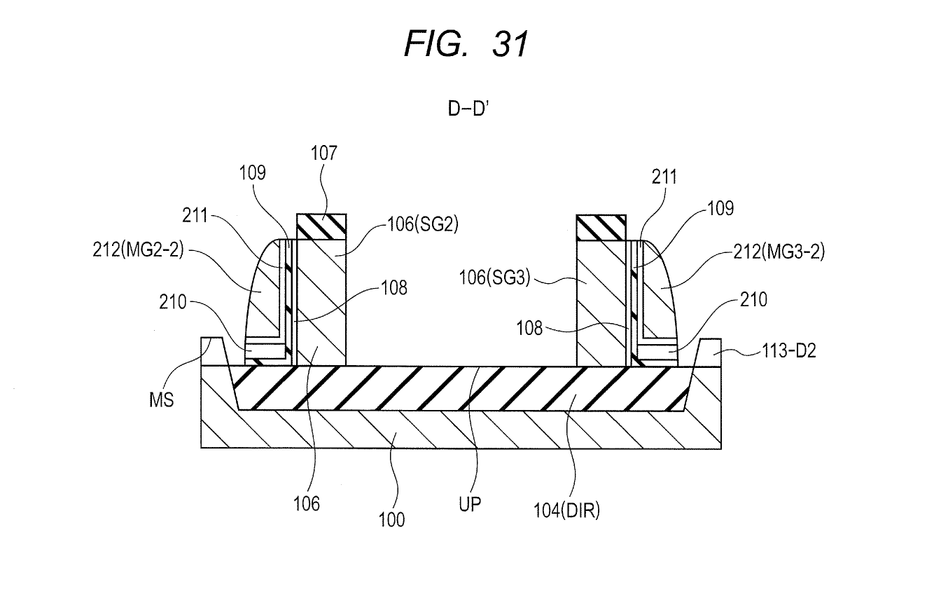

FIG. 27 is a plan view of a memory cell array in a semiconductor device according to Embodiment 2. FIG. 28 is a partial cross-sectional view of the memory cell array along the line A-A′ in FIG. 27. FIG. 29 is a partial cross-sectional view of the memory cell array along the line B-B′ in FIG. 27. FIG. 30 is a partial cross-sectional view of the memory cell array along the line C-C′ in FIG. 27. FIG. 31 is a partial cross-sectional view of the memory cell array along the line D-D′ in FIG. 27.

The memory cell array of Embodiment 2 is the same as in Embodiment 1. Since FIG. 27, FIG. 28, and FIG. 29 are respectively the same as FIG. 1, FIGS. 2A and 2B (partial cross-sectional views of the memory cell array along the line A-A′ in FIG. 1), and FIG. 3 (partial cross-sectional view of the memory cell array along the line B-B′ in FIG. 1) of Embodiment 1, the description thereof is omitted here. On the other hand, the portions denoted by reference numerals MG1-2, MG2-2, MG3-2, MG4-2, and 211 which are different from those used in Embodiment 1 are different from the equivalent portions of Embodiment 1. However, the memory gates MG1-2, MG2-2, MG3-2, and MG4-2 respectively have the same shapes as those of the memory gates MG1, MG2, MG3, and MG4 of Embodiment 1 in the plan view of FIG. 27 and the cross-sectional view of FIG. 28. In addition, an insulating film 211 has the same shape as that of the insulating film 111 of Embodiment 1 in the cross-sectional view of FIG. 28.

Embodiment 2 is substantially different from Embodiment 1 in FIG. 30 which is the partial cross-sectional view of the memory cell array along the line C-C′ in FIG. 27 and in FIG. 31 which is the partial cross-sectional view of the memory cell array along the line D-D′ in FIG. 27. In each of FIGS. 30 and 31, the portions denoted by reference numerals 210, 211, and 212 which are different from those used in Embodiment 1 are different from the equivalent portions of Embodiment 1.

As can be seen from FIGS. 4A and 4B (cross-sectional views along the line C-C′ in FIG. 1), Embodiment 1 has a structure (so-ca-led “Fin Structure”) in which the memory gate MG1 (polysilicon film 112) protrudes along the side surfaces of the memory cell active region, i.e., over the isolation region DIR (into the recessed portion). By contrast, in Embodiment 2, as shown in FIG. 30 (cross-sectional view along the line C-C′ in FIG. 27), the memory gate MG1-2 (polysilicon film 212) and the insulating film (silicon oxide film) 211 located thereunder do not protrude along the side surfaces of the active region, i.e., into the recessed portion above the upper surface UP of the isolation region DIR. That is, as shown in FIG. 30, in the recessed portion above the upper surface UP of the isolation region DIR, the insulating film (silicon oxide film) 108 and the charge storage film (silicon nitride film) 109 extend along the recess as in Embodiment 1. However, the foregoing recessed portion is filled with the insulating film (silicon oxide film) 210 and the upper surface thereof is located above the main surface MS of the semiconductor substrate 100. Over the upper surface of the insulating film 210, the insulating film 211 extends and, over the insulating film 211, the memory gate MG1-2 extends. Here, of the insulating film present between the memory gate MG1-2 and the insulating film 109 as the charge storage film located thereunder, the portion located over the portion of the semiconductor substrate 100 without the isolation regions DIR is referred to also as a first insulating film and the portion located over the isolation region 104 is referred to also as a second insulating film. Accordingly, due to the presence of the insulating film 210, the thickness of the second insulating film is larger than the thickness of the first insulating film. In other words, the thickness of the first insulating film is smaller than the thickness of the second insulating film.

Due to the presence of the insulating film 210 filling the foregoing recessed portion, FIG. 31 also shows a structure different from that of Embodiment 1. The thickness of the insulating film 210 shown in FIG. 31 is different from that of the insulating film (silicon oxide film) of Embodiment 1. The thickness of the insulating film 210 is larger than the thickness of the insulating film 110 of Embodiment 1.

Note that the respective cross-sectional shapes of the insulating silicon oxide film denoted by the reference numeral 211 of FIG. 28 (cross-sectional view along the line A-A′ in FIG. 27) and the polysilicon film denoted by the reference numeral 212 and forming the memory gates MG2-2 and MG3-2 are the same as in FIG. 2 which is the cross-sectional view along the line A-A′ of Embodiment 1.

Methods for the read, erase, and write operations to the memory cell described in Embodiment 2 are the same as in Embodiment 1 so that the description thereof is omitted here.

The manufacturing method is also generally the same as in the manufacturing process of Embodiment 1. That is, processing is performed by the same steps as the steps P-1 to P-3 (FIGS. 17 to 21) of Embodiment 1. Then, during the wet etching process performed on the silicon oxide film 110 in the step P-4 shown in FIGS. 22 and 23, the amount of the etching is adjusted to form the silicon oxide film 210 having a desired thickness as shown in FIG. 30. Thereafter, the remaining step P-4 (FIG. 24) is performed, and the processing in the steps P-5 (FIG. 25) and P-6 (FIG. 26) is performed.

In each of the memory cells described in Embodiment 2, the charge storage film 109 extends between the adjacent cells along the recess above the isolation region DIR, in the same manner as in Embodiment 1. Therefore, it is possible to increase the length of the portion of the charge storage film which is located over the isolation region DIR and in which charges are not injected during writing.

In other words, the length of the region (region which does not retain data) of the charge storage film 109 which is located between the adjacent cells and in which charges are not stored is increased.

As a result, the charges are not easily diffused between the adjacent cells and the amount of degradation of the data retention property is reduced to be able to suppress the degradation of reliability.

Since the memory gate of Embodiment 2 does not have a Fin structure, a read current is smaller than in Embodiment 1. However, the length of the portion of the charge storage film which is located over the isolation region and in which charges are not injected can be increased to be larger than in Embodiment 1. Therefore, Embodiment 2 is preferred in the case where high-speed reading is less required than in Embodiment 1. That is, even when the width of the isolation region is reduced through the scaling of the memory cells to reduce the distance between the adjacent memory cells, the effective length of the charge storage film over the isolation region can be increased to be larger than in Embodiment 1. This allows a further reduction in mutual interference between the electrons or holes injected into the charge storage film of the memory cell and diffused into the portion of the charge storage film located over the isolation region. In other words, if the length of the portion of the charge storage film which is located over the isolation region and in which the charges are not injected is controlled to be the same as in Embodiment 1, the width of the isolation region can be reduced to be smaller than in Embodiment 1.

Further, in the semiconductor device according to Embodiment 2, even under circumstances where an external environment is severe, such as when the semiconductor device is used as an in-vehicle product, high quality and reliability can be ensured.

In addition, through the scaling of a product chip size, it is possible to improve the number of products obtained from a single wafer and thereby achieve a cost reduction.

### Embodiment 3

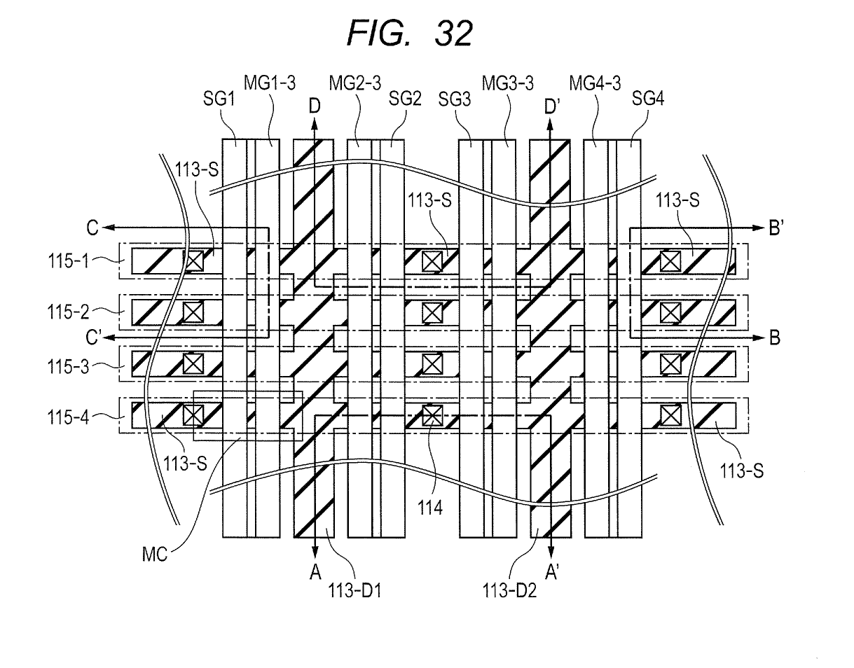

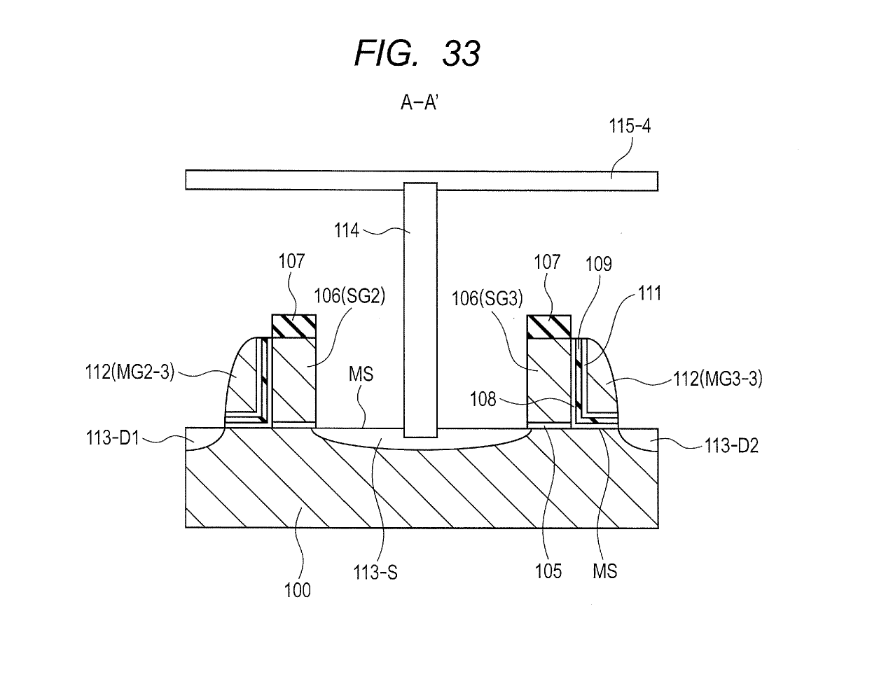

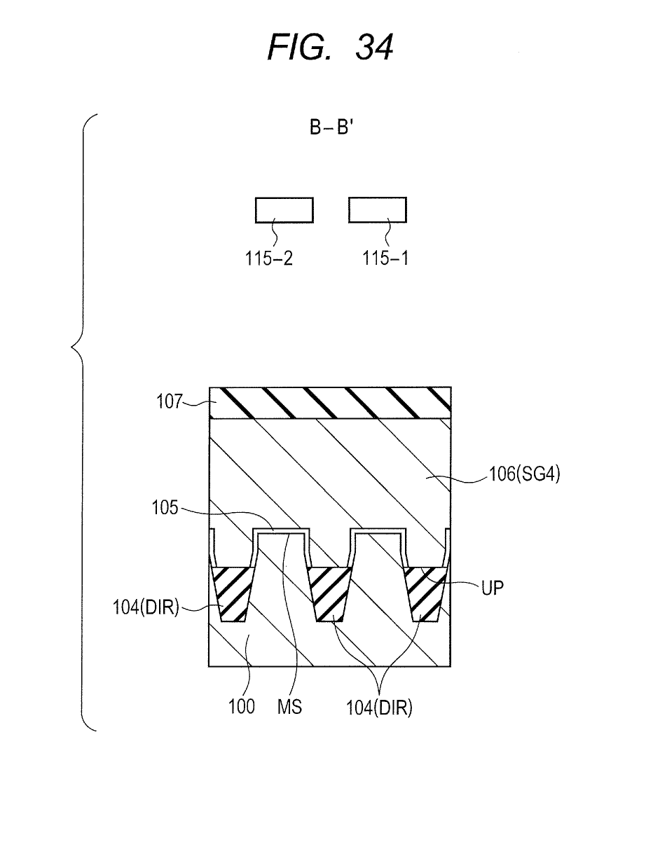

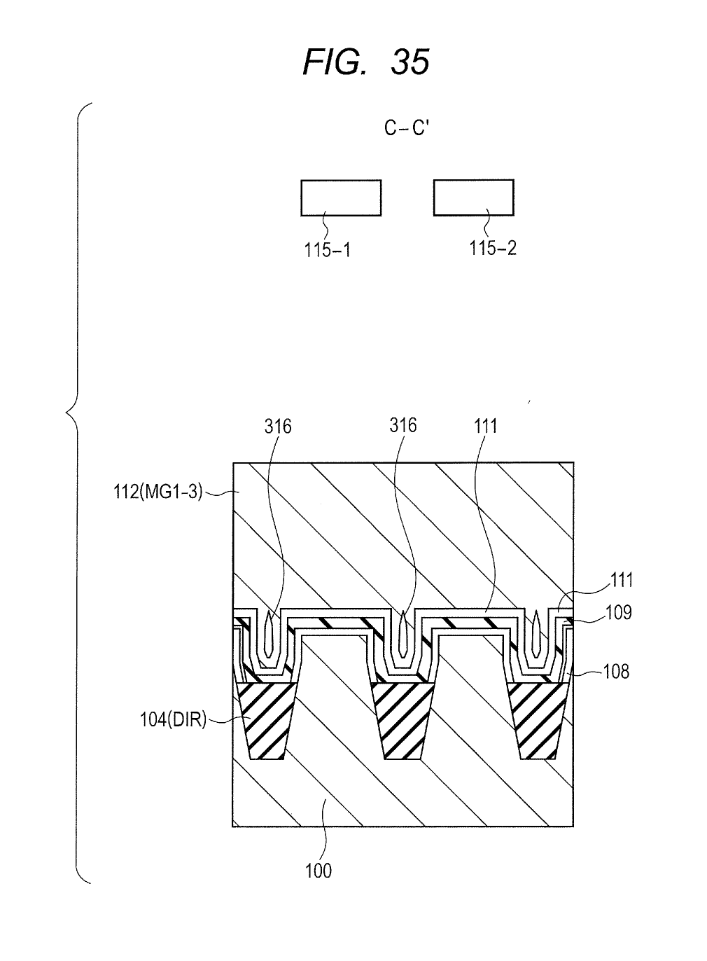

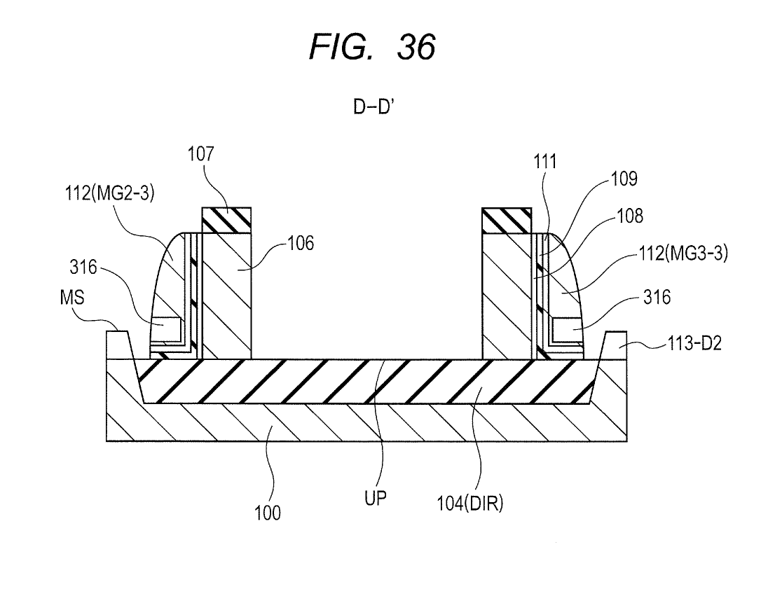

FIG. 32 is a plan view of a memory cell array in a semiconductor device according to Embodiment 3. FIG. 33 is a partial cross-sectional view of the memory cell array along the line A-A′ in FIG. 32. FIG. 34 is a partial cross-sectional view of the memory cell array along the line B-B′ in FIG. 32. FIG. 35 is a partial cross-sectional view of the memory cell array along the line C-C′ in FIG. 32. FIG. 36 is a partial cross-sectional view of the memory cell array along the line D-D′ in FIG. 32. The memory cell array of Embodiment 3 is the same as in Embodiment 1. Since FIG. 32, FIG. 33, and FIG. 34 are respectively the same as FIG. 1, FIGS. 2A and 2B, and FIG. 3 of Embodiment 1, the description thereof is omitted here. On the other hand, the portions denoted by reference numerals MG1-3, MG2-3, MG3-3, and MG4-3 which are different from those used in Embodiment 1 are different from the equivalent portions of Embodiment 1. However, the memory gates MG1-3, MG2-3, MG3-3, and MG4-3 respectively have the same shapes as those of the memory gates MG1, MG2, MG3, and MG4 of Embodiment 1 in the plan view of FIG. 32 and the cross-sectional view of FIG. 33.

The difference between Embodiments 3 and 1 is the structure of each of the memory gates. In particular, the portion thereof extending over the isolation region DIR providing isolation between the memory cells is different. Embodiment 3 is different from Embodiment 1 in FIG. 35 which is the partial cross-sectional view of the memory cell array along the line C-C′ in FIG. 32 and in FIG. 36 which is the partial cross-sectional view of the memory cell array along the line D-D′ in FIG. 32. In each of FIGS. 35 and 36, the portions denoted by the reference numeral 316 different from the reference numerals used in Embodiment 1 are different from the portions of Embodiment 1. There are two differences between Embodiments 3 and 1.

One of the differences is the shape of each of the memory gates. In Embodiment 3, a part of the memory gate protrudes into the recessed portion above the isolation region DIR providing isolation between the memory cells, and the presence of voids (air gaps) 316 in the memory gate (protruding portion) present in the recessed portion is one of the differences.

The other difference is the absence of the insulating film (silicon oxide film) 110 between the charge storage film (silicon nitride film) 109 in the recessed portion above the isolation region DIR and the memory gate MG1-3. Accordingly, the thickness of the insulating film (silicon oxide film) 111 between the charge storage film 109 over the main surface MS of the semiconductor substrate 100 and the memory gate MG1-3 is substantially equal to the thickness of the insulating film 111 between the charge storage film 109 present in the recessed portion above the isolation region DIR and the memory gate MG-3.

Methods for the read, erase, and write operations to the memory cell described in Embodiment 3 are the same as in Embodiment 1 so that the description thereof is omitted here.

The manufacturing method is also generally the same as in the manufacturing process of Embodiment 1. That is, the same steps as the steps P-1 to P-3 (process shown in FIGS. 17 to 21) of Embodiment 1 are performed and, in the step P-4 of Embodiment 1 (process shown in FIGS. 22, 23, and 24), the silicon oxide film 110 is not formed, but the silicon oxide film 108, the silicon nitride film 109, and the silicon oxide film 111 are formed (CVD films are deposited).

Then, as in the step P-5 (FIG. 25) of Embodiment 1, the polysilicon film 112 serving as the memory gates are formed. At this time, the deposition is performed under conditions resulting in poor coverage to form the air gaps 316 in the portion of the polysilicon film 112 formed over the isolation region DIR.

Thereafter, the same manufacturing process as in the step P-6 (FIG. 26) of Embodiment 1 is performed.

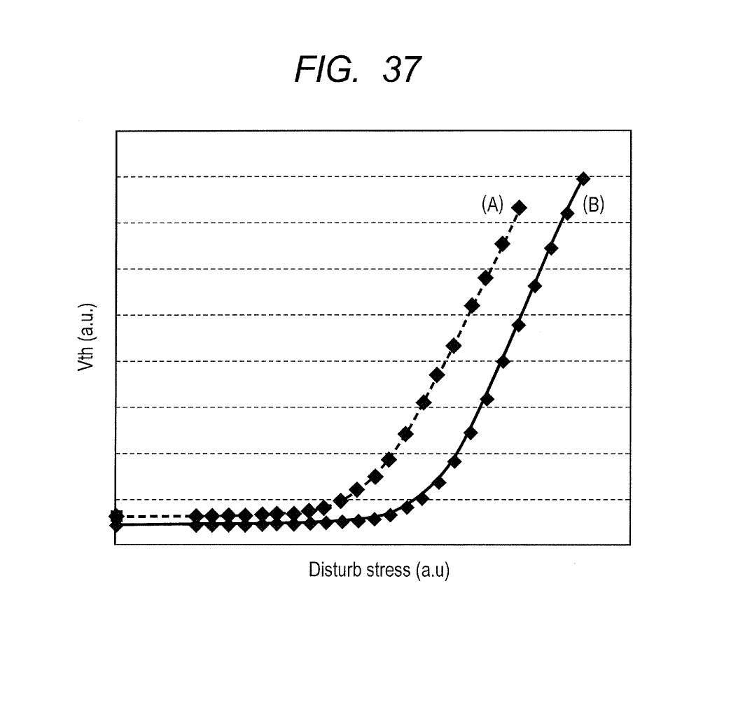

FIG. 37 is a view showing the resistance of a memory cell according to Embodiment 3 to erroneous writing to an adjacent cell.

In the drawing, (A) shows the resistance to erroneous writing when no air gap is formed in the memory gate and (B) shows the resistance to erroneous writing when the air gaps are formed in the memory gate. In the drawing, the ordinate axis shows fluctuations in the threshold value (Vth) of the memory cell adjacent to the given memory cell to which writing has been performed. By repeating the writing, erroneous writing stress (disturb stress) is given. In the drawing, the abscissa axis shows the disturb stress. From the drawing, it can be seen that, when the air gap regions are formed in the memory gate, even when the erroneous writing stress is applied for a longer period, the fluctuations in the threshold value of the memory cell are reduced.

Moreover, in each of the memory cells described in Embodiment 3, a part of the memory gate protrudes into the recessed portion located over the isolation region DIR so that the gate width (channel width) of the memory gate extends to over the isolation region DIR. This allows the active region of the memory cell to be further extended than in the comparative example of Embodiment 1 in addition, the absence of the insulating film 110 allows the amount of protrusion of the protruding portion of the memory gate to be further increased than in Embodiment 1 and allows the charge storage region, i.e., the active region to be significantly extended. As a result, it is easier to ensure the read current than in Embodiment 1.

Furthermore, by providing the air gaps 316 in the protruding portion of the memory gate, it is possible to reduce the occurrence of erroneous operations such as erroneous writing and erroneous erasing to the adjacent cell. As the erroneous operation, an erroneous operation caused by charges (hot carriers) which have penetrated the memory gate and reached the adjacent cell during writing or erasing may be considered. According to Embodiment 3, due to the air gaps 316, it is possible to reduce the penetration by the charges and reduce the erroneous operations.

### Embodiment 4

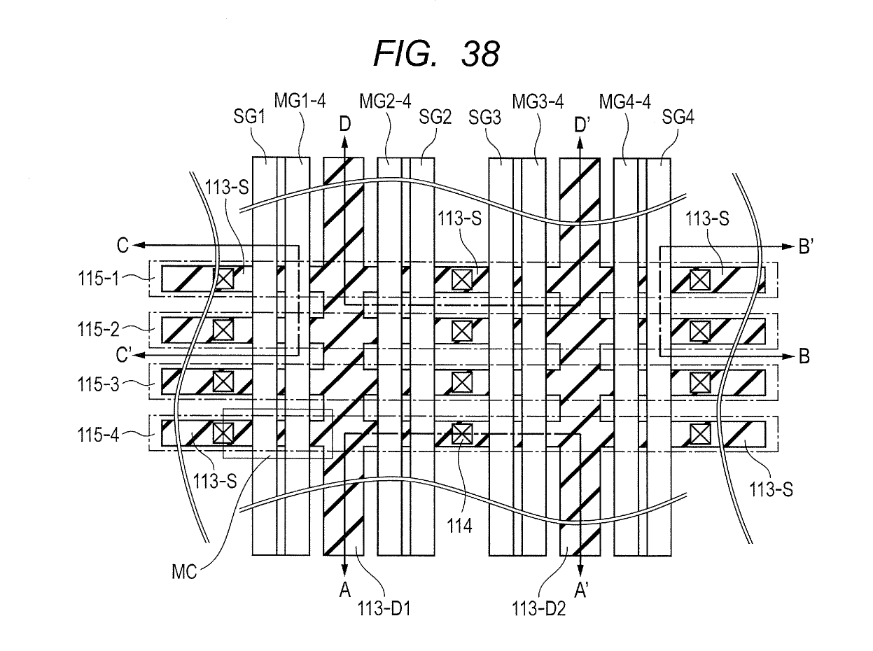

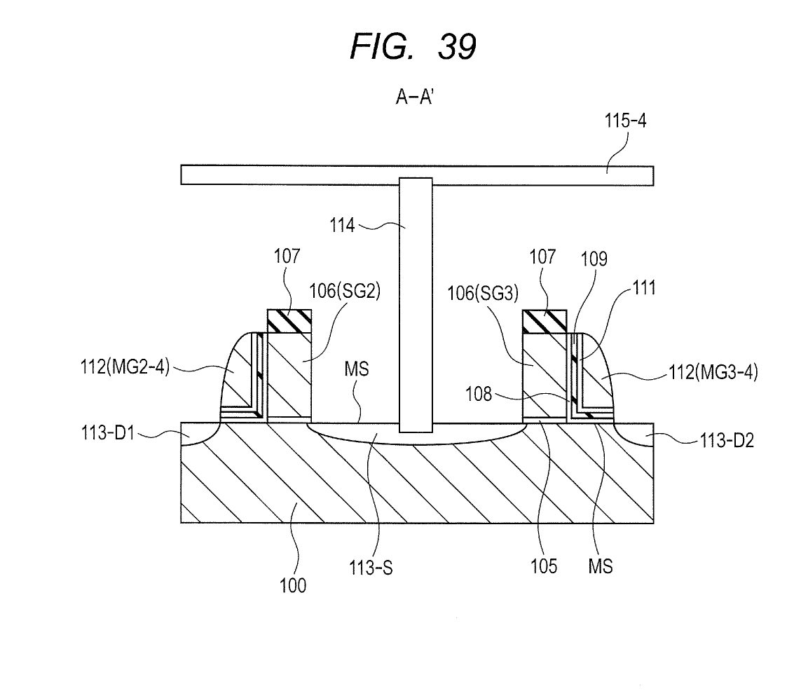

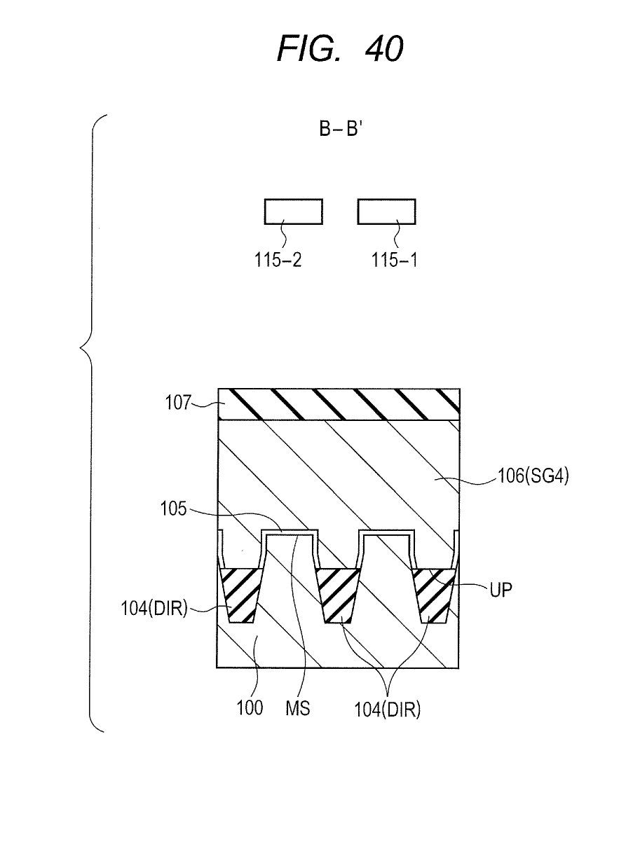

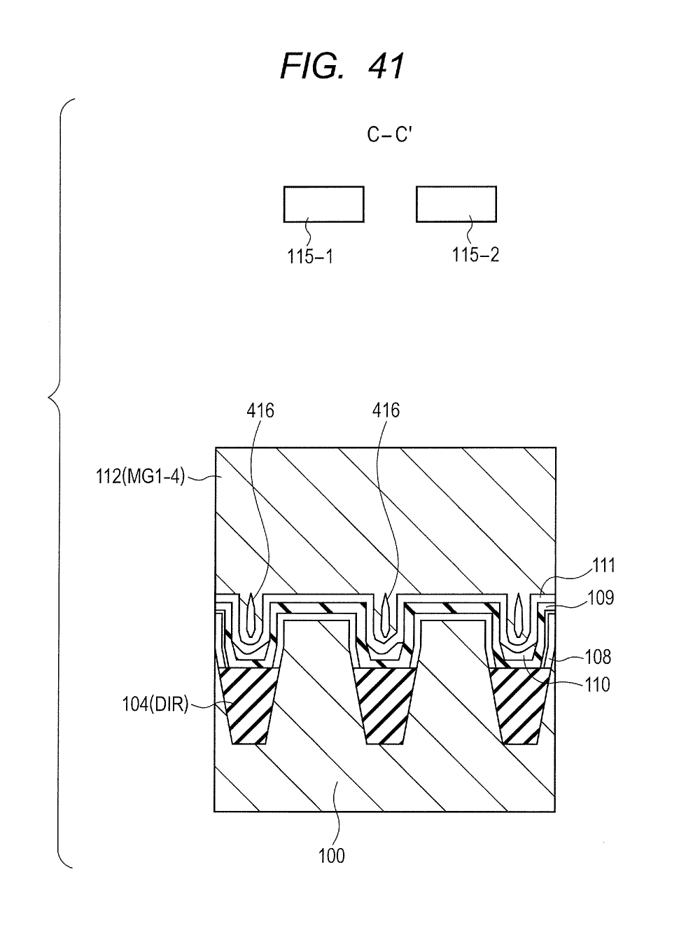

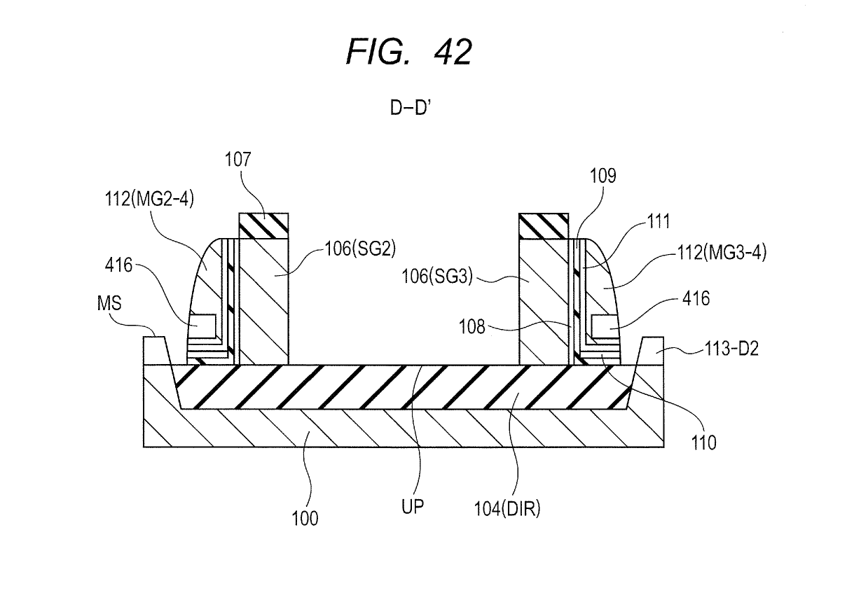

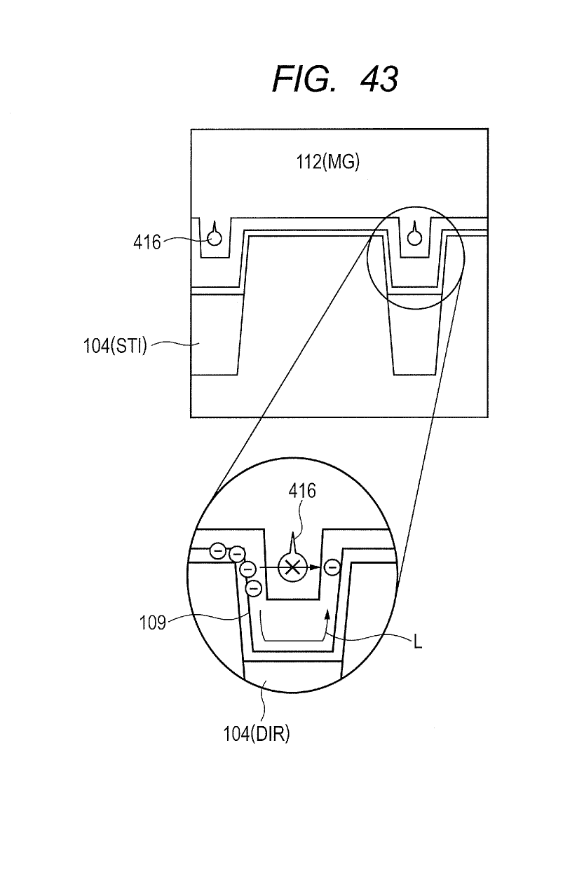

FIG. 38 is a plan view of a memory cell array in a semiconductor device according to Embodiment 4. FIG. 39 is a partial cross-sectional view of the memory cell array along the line A-A′ in FIG. 38. FIG. 40 is a partial cross-sectional view of the memory cell array along the line B-B′ in FIG. 38. FIG. 41 is a partial cross-sectional view of the memory cell array along the line C-C′ in FIG. 38. FIG. 42 is a partial cross-sectional view of the memory cell array along the line D-D′ in FIG. 38. FIG. 43 is a schematic cross-sectional view for illustrating the effect of Embodiment 4, which corresponds to FIG. 41.

The memory cell array of Embodiment 4 is the same as in Embodiment 1. Since FIG. 38, FIG. 39, and FIG. 40 are respectively the same as FIG. 1, FIGS. 2A and 2B, and FIG. 3, the description thereof is omitted here. On the other hand, the portions denoted by reference numerals MG1-4, MG2-4, MG3-4, and MG4-3 which are different from those used in Embodiment 1 are different from the equivalent portions of Embodiment 1. However, the memory gates MG1-4, MG2-4, MG3-4, and MG4-4 respectively have the same shapes as those of the memory gates MG1, MG2, MG3, and MG4 of Embodiment 1 in the plan view of FIG. 38 and the cross-sectional view of FIG. 39.

The difference between Embodiments 4 and 1 is the structure of each of the memory gates. In particular, the portion extending over the isolation region DIR providing isolation between the memory cells is different. Embodiment 4 is different from Embodiment 1 in the cross-sectional views of FIGS. 41 and 42. In each of FIGS. 41 and 42, the portions denoted by the reference numeral 416 different from the reference numerals used in Embodiment 1 are different from the portions of Embodiment 1. The reference numeral 416 denotes an air gap which is present in the memory gate protruding into the recessed portion above the isolation region DIR providing isolation between memory cell elements.

Methods for the read, erase, and write operations to the memory cell described in Embodiment 4 are the same as in Embodiment 1 so that the description thereof is omitted here.

The manufacturing method is generally the same as in the manufacturing process of Embodiment 1. That is, the same steps as the steps P-1 to P-4 (FIGS. 17 to 24) of Embodiment 1 are performed. Then, in the step P-5 (FIG. 25), the polysilicon film 112 serving as the memory gates is deposited under conditions resulting in poor coverage to form the air gaps 416 shown in FIGS. 41 and 42 in the portion of the polysilicon film 112 located above the isolation region DIR. Thereafter, the same manufacturing process as in the step P-6 (FIG. 26) is performed. According to Embodiment 4 described above, as shown in FIGS. 41 and 42, the memory gate has the air gap regions therein in the same manner as in Embodiment 43. Therefore, even when the erroneous writing stress is applied for a longer period, the fluctuations in the threshold value of the memory cell are reduced.

In addition, it is possible to reduce the occurrence of erroneous operations such as erroneous writing and erroneous erasing to the adjacent cell. As the erroneous operation, an erroneous operation caused by charges which have penetrated the memory gate MG and reached the adjacent cell during writing or erasing may be considered. However, as shown in FIG. 43, the charges are trapped by the air gaps 416 to allow a reduction in the penetration of the memory gate by the charges. Accordingly, the erroneous operation can be reduced.

Moreover, as shown in FIGS. 41 and 42, due to the structure in which a part of the memory gate protrudes into the recessed portion above the isolation region DIR, the gate width (channel width) of the memory gate extends to over the isolation region DIR. This allows the active region of the memory cell to be further extended than conventionally and allows the read current to be easily ensured. In particular, it is easier to ensure the read current corresponding to a high-speed operation.

Also as shown in FIGS. 41 and 42, the insulating film (silicon oxide film) 110 is interposed between a part of the memory gate protruding into the recessed portion above the isolation region DIR and the insulating film (silicon nitride film) 109 located thereunder to limit the protrusion of the memory gate. Also as shown in FIG. 41, the insulating film present between the conductor film (polysilicon film) 112, which is the memory gate MG1-4, and the insulating film 109 as the charge storage film located thereunder has the difference between the thicknesses thereof over the isolation region DIR and over the semiconductor substrate 100 (over the memory element) other than the isolation regions. Here, of the insulating film present between the memory gate MG1-4 and the insulating film 109 as the charge storage film located thereunder, the portion located over the semiconductor substrate 100 without the isolation regions DIR and the portion located over each of the isolation regions DIR are respectively referred to also as a first insulating film and a second insulating film.

Accordingly, due to the presence of the insulating film 110, the thickness of the second insulating film is larger than the thickness of the first insulating film. In other words, the thickness of the first insulating film is smaller than the thickness of the second insulating film. This increases the length L of the region (region which does not retain data) of the charge storage film 109 which is located between the adjacent cells and in which charges are not stored (FIG. 43). Consequently, the diffusion of charges is not easily performed between the adjacent cells to improve the data retention property.

According to Embodiment 4, even when the width of the isolation region is reduced through the scaling of the memory cells to reduce the distance between the adjacent memory cells, the effective length of the charge storage film over each of the isolation regions can be increased. Therefore, it is possible to reduce mutual interference between the electrons or holes injected into the charge storage film of the memory cell and diffused into the portions of the charge storage film located over the isolation regions.

Also according to Embodiment 4, even when the gate width in planar view is reduced through the scaling of the memory cells, the effective channel width (gate width) can be increased. Therefore, it is possible to ensure the read current corresponding to the high-speed operation.

Also according to Embodiment 4, the fin structure is used in which the height of the isolation region providing isolation between memory cell regions is adjusted to be lower than the height of the active region of each of the memory cells to increase the channel width. As a result, hot carriers generated in the write operation (or erase operation) may reach the adjacent memory cell via the memory gate present over the isolation region to cause the erroneous operation of the memory cell. However, by providing the air gaps in the memory gate located over the isolation region, the erroneous operation can be reduced.

Therefore, the reliability of the memory cell is unlikely to be impaired through the scaling thereof. In particular, even when the semiconductor device is exposed to a high temperature, such as when the semiconductor device is used as an in-vehicle product, the reliability is less likely to be degraded.

In addition, through the scaling of a product chip size, it is possible to improve the number of products obtained from a single wafer and thereby achieve a cost reduction.

### Embodiment 5

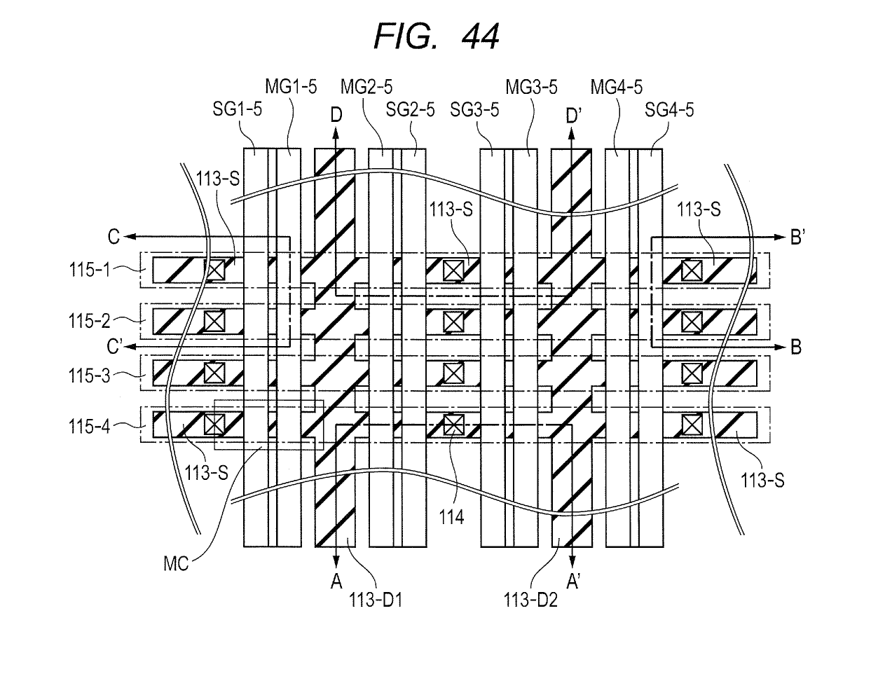

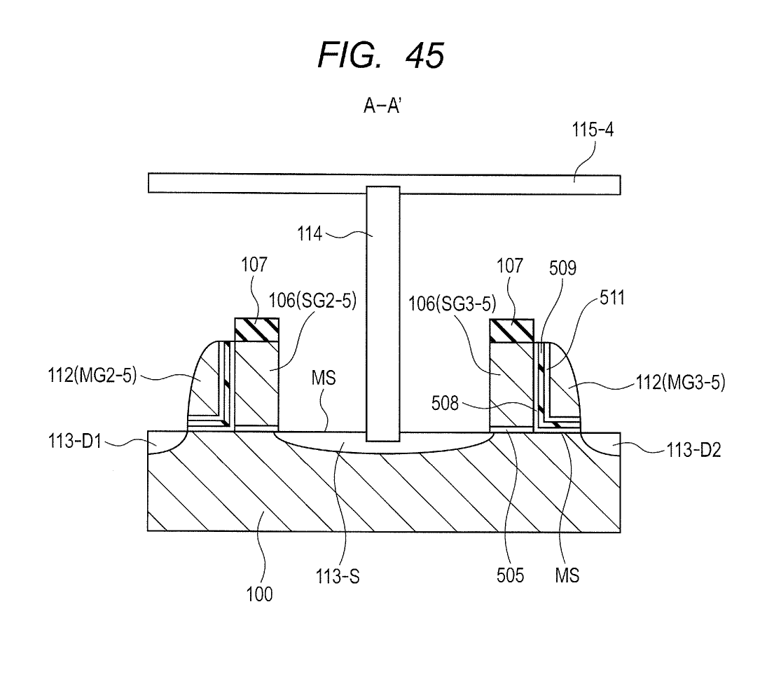

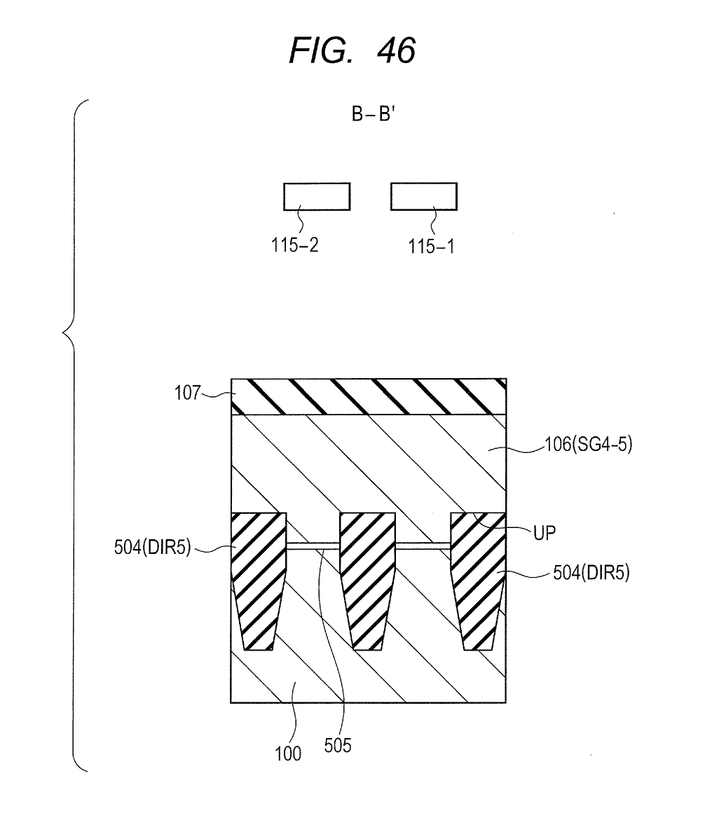

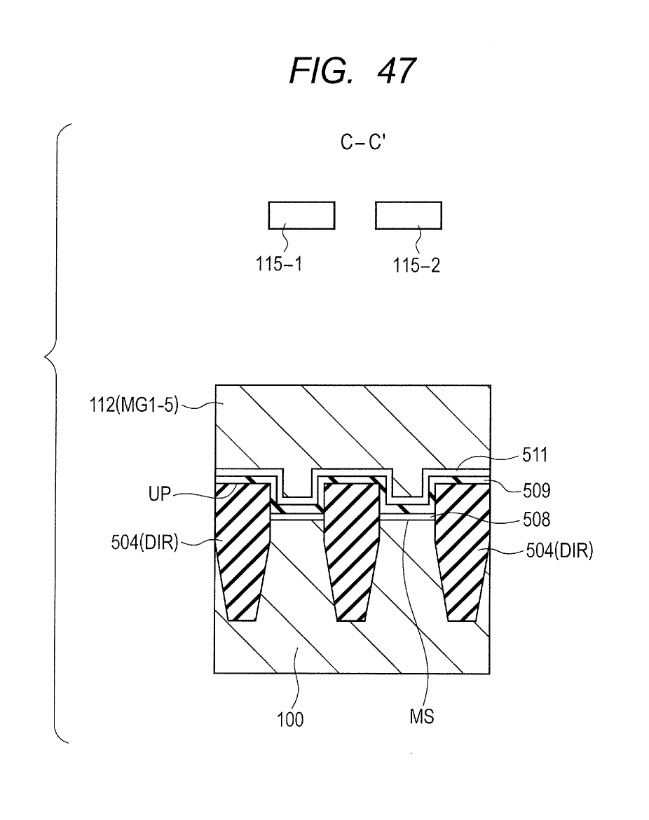

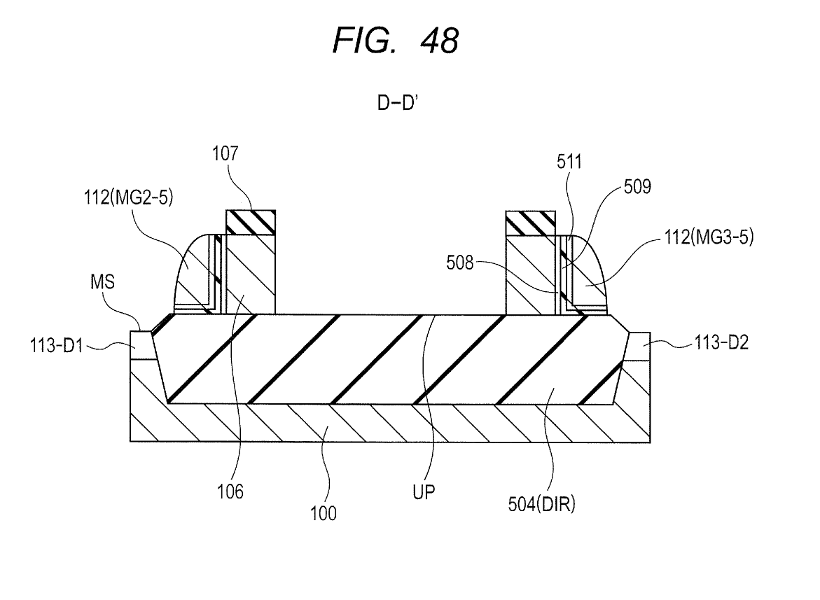

FIG. 44 is a plan view of a memory cell array in a semiconductor device according to Embodiment 5. FIG. 45 is a partial cross-sectional view of the memory cell array along the line A-A′ in FIG. 44. FIG. 46 is a partial cross-sectional view of the memory cell array along the line B-B′ in FIG. 44. FIG. 47 is a partial cross-sectional view of the memory cell array along the line C-C′ in FIG. 44. FIG. 48 is a partial cross-sectional view of the memory cell array along the line D-D′ in FIG. 44.

The memory cell array of Embodiment 5 is the same as in Embodiment 1. Since FIG. 44 and FIG. 45 are respectively the same as FIG. 1 and FIGS. 2A and 2B, the description thereof is omitted here. On the other hand, the portions denoted by reference numerals MG1-5, MG2-5, MG3-5, MG4-5, SG1-5, SG2-5, SG3-5, SG4-5, 505, 508, 509, and 511 which are different from those used in Embodiment 1 are different from the equivalent portions of Embodiment 1. However, the memory gates MG1-5, MG2-5, MG3-5, and MG4-5 respectively have the same shapes as those of the memory gates MG1, MG2, MG3, and MG4 of Embodiment 1 in the plan view of FIG. 27 and the cross-sectional view of FIG. 28. Also, the selection gates SG1-5, SG2-5, and SG3-5 respectively have the same shapes as those of the selection gates SG1, SG2, SG3, and SG4 in Embodiment 1 in the plan view of FIG. 27 and the cross-sectional view of FIG. 28. Also, the insulating films 505, 508, 509, and 511 respectively have the same shapes as those of the insulating films 105, 108, 109, and 111 in Embodiment 1 in the cross-sectional view of FIG. 28.

Embodiment 5 is different from Embodiment 1 in FIGS. 46, 47, and 48. In each of these cross-sectional views, the portions denoted by the reference numerals different from those used in Embodiment 1 are different from the equivalent portions of Embodiment 1. That is, the different portions are the silicon oxide film denoted by the reference numeral 504, the isolation regions each denoted by the reference numeral DIR5, the silicon oxide film under the selection gate denoted by the reference numeral 505, the silicon oxide film under the memory gate denoted by the reference numeral 508, the charge storage film denoted by the reference numeral 509, and the silicon oxide film denoted by the reference numeral 511. These different portions will be described next.

(1) Isolation Region DIR5

Among them, the isolation regions DIR5 are one of the large differences between Embodiments 5 and 1. In Embodiment 1, the upper surface UP of each of the isolation regions DIR is lower in level than the main surface MS of the semiconductor substrate 100. However, in Embodiment 5, as shown in FIGS. 46, 47, and 48, the upper surface UP of each of the isolation regions DIR5 (silicon oxide film 504) is higher in level than the main surface MS of the semiconductor substrate 100.

(2) Charge Storage Film 509

The second large difference between Embodiments 5 and 1 is the charge storage film 509 located under the memory gate and extending from over the main surface MS of the semiconductor substrate 100 to over the upper surface UP of the isolation region 504 (FIGS. 47 and 48).

(3) Silicon Oxide Film 511

The silicon oxide film 511 between the memory gate and the charge storage film 509 also extends from over the main surface MS of the semiconductor substrate 100 to over the upper surface UP of the isolation region 504 (FIGS. 47 and 48).

(4) Others

The silicon oxide film 508 present under the memory gate and under the charge storage film 509 is present over the main surface MS of the portion of the semiconductor substrate 100 located between the isolation regions DIR5, but is not present over the upper surfaces UP of the isolation region DIR5 (FIG. 47). Also, the silicon oxide film 505 under the polysilicon film 106 forming the selection gate is present over the main surface MS of the semiconductor substrate 100, but is not present over the upper surfaces UP of the isolation regions DIR5 (FIG. 46).

FIG. 45 also shows the reference numerals 505, 508, 509, and 511 but, in FIG. 45 (A-A′ cross section), the portions 505, 508, 509, and 511 have the same cross-sectional shapes as those of the portions denoted by the reference numerals 105, 108, 109, and 111 of FIG. 2 of Embodiment 1. That is, in Embodiment 5, the portions shown by the reference numerals 505, 508, 509, and 511 have the same cross-sectional shapes as those of the equivalent portions of Embodiment 1 in the cross section A-A′ (FIG. 45), but have cross-sectional shapes different from those of the equivalent portions of Embodiment 1 in the cross section B-B′ (FIG. 46) and the cross section C-C′ (FIG. 47).

Methods for the read, erase, and write operations to the memory cell described in Embodiment 5 are the same as in Embodiment 1 so that the description thereof is omitted.

The manufacturing method is also generally the same as in the manufacturing steps P-1 to P-6 of Embodiment 1 and can be achieved by partly modifying the process steps as follows. That is, when dry etching or wet etching is performed in the step of FIG. 19 which is a part of the step P-3 described in Embodiment 1, the amount of removal of the silicon oxide film serving as the isolation regions is adjusted such that the upper surface UP of the silicon oxide film is higher in level than the main surface MS of the silicon substrate 100. In this manner, the silicon oxide film 504 serving as the isolation regions having the upper surfaces UP thereof higher in level than the main surface MS of the silicon substrate 100 is formed. In the step P-4 (the steps shown in FIGS. 22, 23, and 24) of Embodiment 1, the silicon oxide film 110 is not formed, but the silicon oxide film 108, the silicon nitride film 109, and the silicon oxide film 111 are formed. Thereafter, the same manufacturing process as in Embodiment 1 is performed.

According to Embodiment 5, the upper surface UP of the silicon oxide film (STI oxide film) 504 of each of the isolation regions DIR5 of the memory cells is higher in level than the main surface MS of the silicon substrate 100, and the charge storage film 509 extends over the upper surface UP and along the direction in which the memory gate extends. Accordingly, the length of the silicon nitride film 509 to the adjacent cell can be increased to be larger than the width of the isolation region. This allows a reduction in the degradation resulting from the diffusion of injected charges between the adjacent cells.

It can be considered that, by removing the silicon oxide film 509 over each of the isolation regions DIR5 also, the diffusion of the injected charges between the adjacent cells can be prevented. However, Embodiment 5 in which at least the step of removing the silicon nitride film 509 is unnecessary can more simplify the manufacturing process.

### Embodiment 6

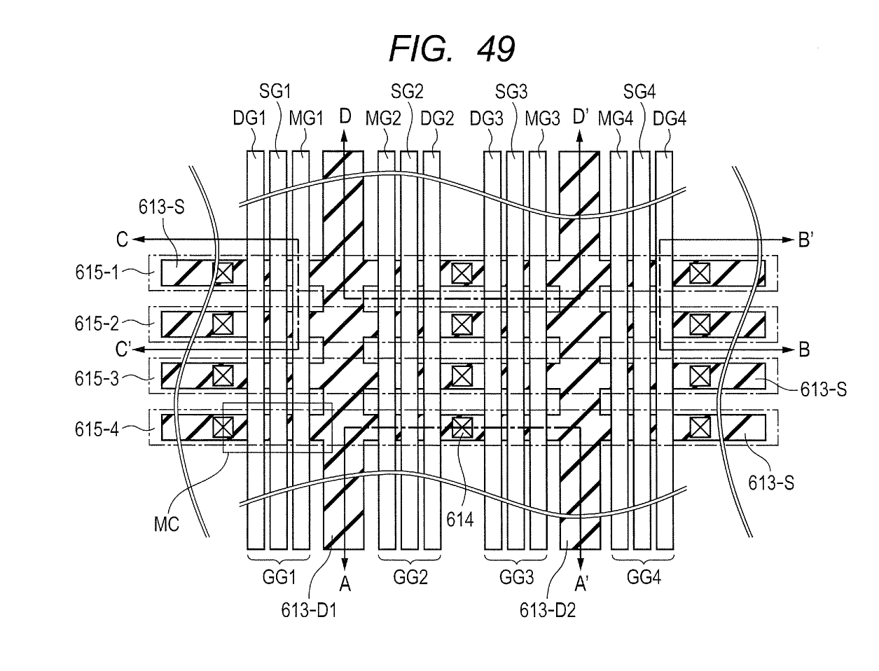

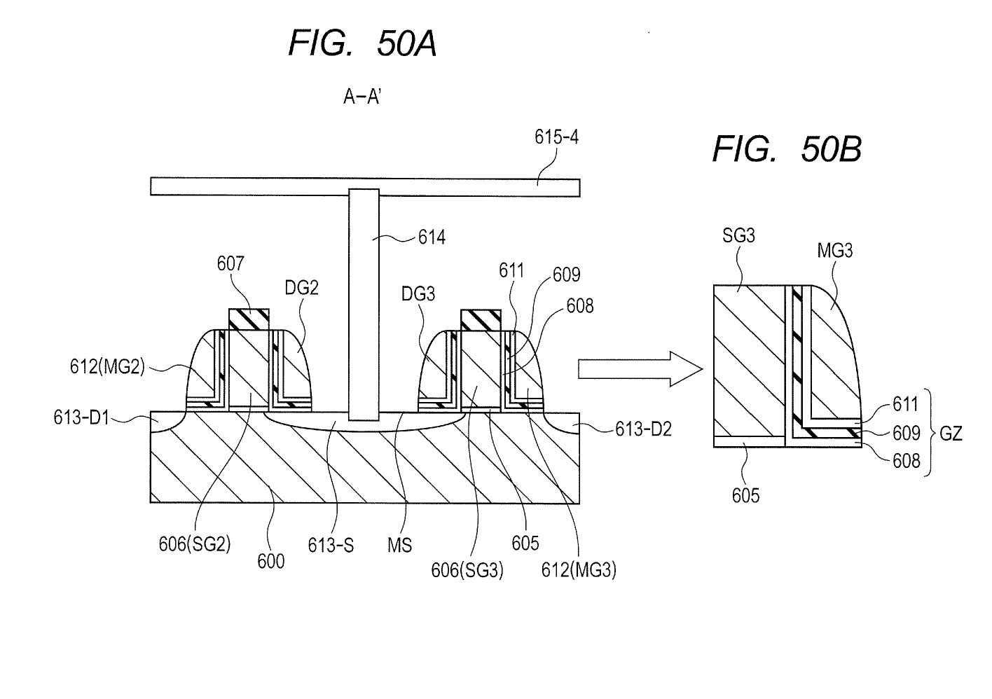

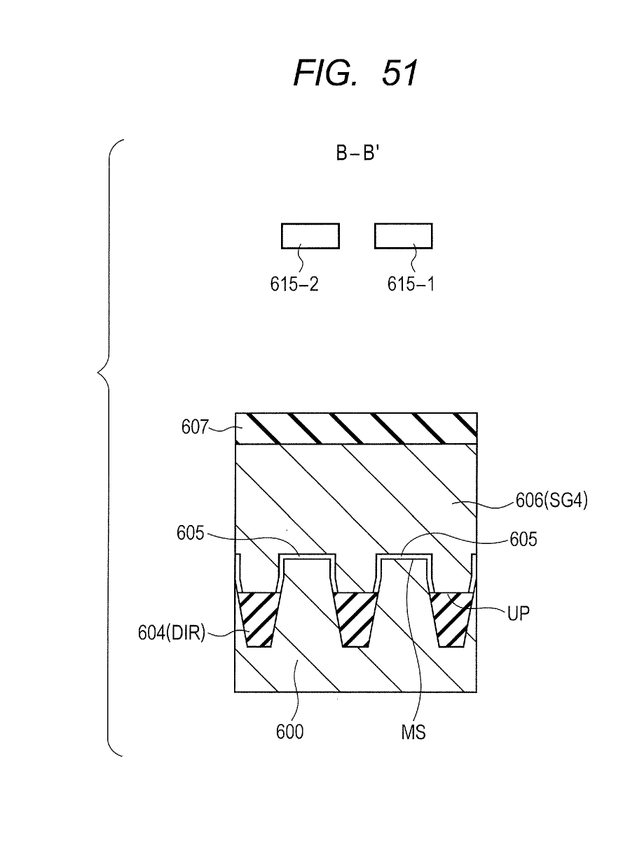

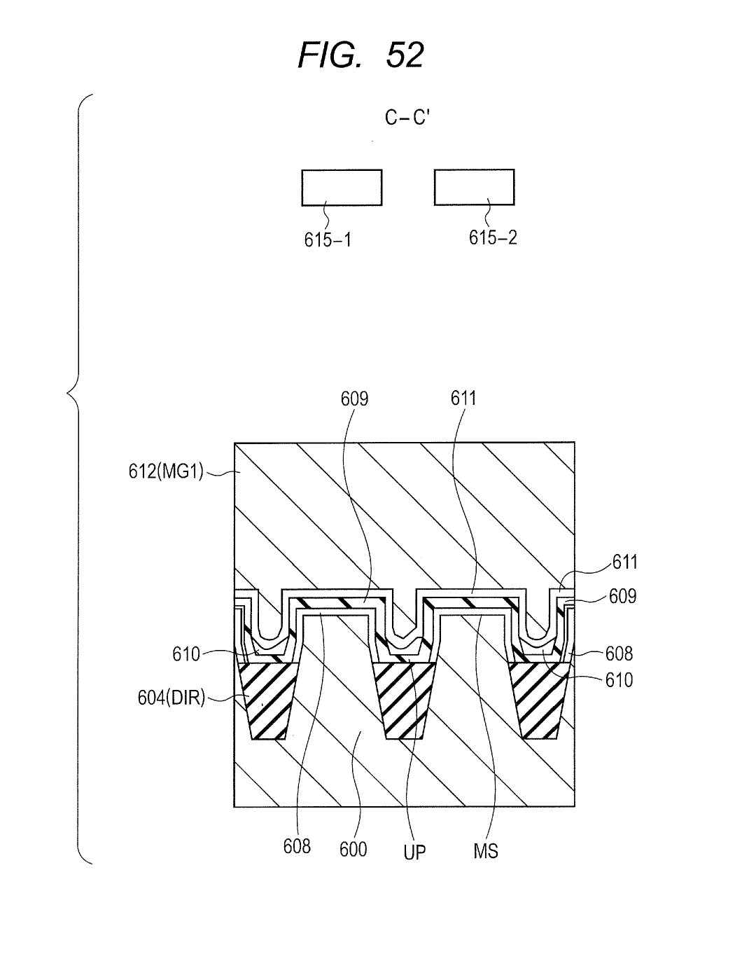

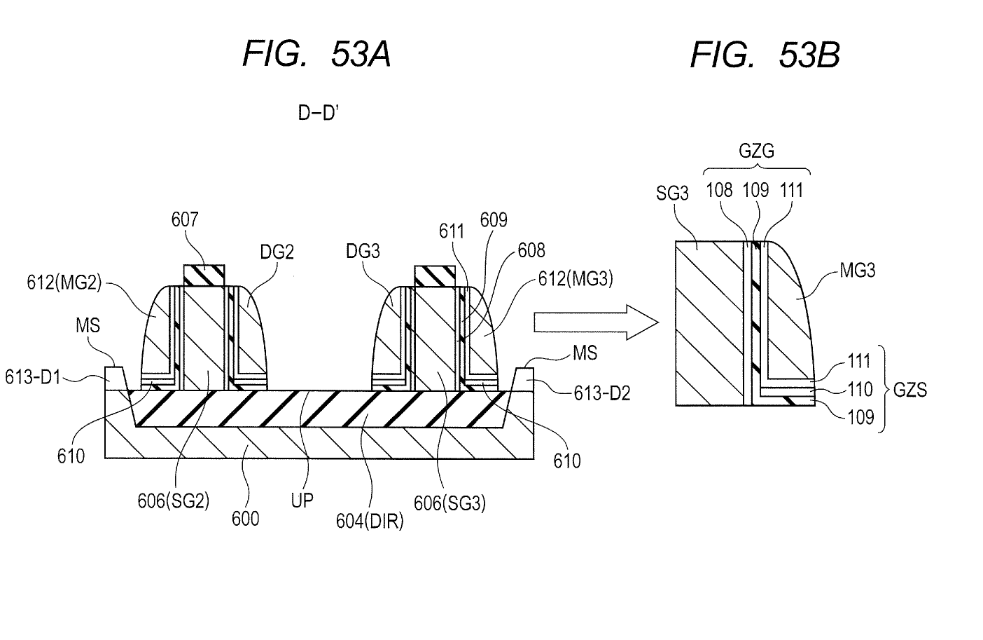

FIG. 49 is a plan view of a memory cell array in a semiconductor device according to Embodiment 6. FIGS. 50A and 50B are partial cross-sectional views of the memory cell array along the line A-A′ in FIG. 49. FIG. 51 is a partial cross-sectional view of the memory cell array along the line B-B′ in FIG. 49. FIG. 52 is a partial cross-sectional view of the memory cell array along the line C-C′ in FIG. 49. FIG. 53 is a partial cross-sectional view of the memory cell array along the line D-D′ in FIG. 49.

As shown in FIG. 49, the memory cell array of Embodiment 6 has a structure in which two polysilicon films each having a sidewall shape are present with the selection (control) gate interposed therebetween. Of the two sidewall gates, one functions as the memory gate in the same manner as in Embodiment 1. Into/from the silicon nitride film formed as the charge storage film under the memory gate, charges are injected/released to be used as data in the memory cell. The other sidewall gate has a diffusion layer formed under the gate and does not affect the memory operation. In addition, the sidewall gate is not electrically coupled to a circuit or the like and serves as a dummy gate in a floating state.

Thus, the memory cell configuration is provided which has the polysilicon films shaped as the sidewalls on both sides of the selection gate SG.

Embodiment 6 is the same as Embodiment 1 except for the dummy gates and the insulating films adjacent to the dummy gates. The reference numerals “6XX” and “6XX-X” in FIGS. 49 to 53 correspond to and are the same as the reference numerals “1XX” and “1XX-X” of Embodiment 1. For example, the reference numeral “615-1” of Embodiment 6 corresponds to and is the same as the reference numeral “115-1” of Embodiment 1. Therefore, the repeated description of the same parts as in Embodiment 1 except for the dummy gates and the insulating films adjacent to the dummy gates is omitted. However, in the context of description, the description in Embodiment 6 has a part overlapping the description in Embodiment 1. As shown in FIG. 49, the memory gate MG1, the selection gate SG1, and a dummy gate DG1 form a first gate group GG1, and the memory gate MG2, the selection gate SG2, and a dummy gate DG2 form a second gate group GG2. The first and second gate groups GG1 and GG2 extend in the same direction (first direction). Likewise, the memory gate MG3, the selection gate SG3, and a dummy gate DG3 form a third gate group GG3, and the memory gate MG4, the selection gate SG4, and a dummy gate DG4 form a fourth gate group GG4. The third and fourth gate groups GG3 and GG4 also extend in the first direction, similarly to the first and second gate groups GG1 and GG2.

Embodiment 6 also has diffusion regions 613 traversing (or orthogonal to) the plurality of gate groups GG1, GG2, GG3, and GG4 and extending in another direction (second direction) different from the first direction, while extending in the first direction between the gate groups. The drain regions 613-D are formed between the first and second gate groups GG1 and GG2 and between the third and fourth gate groups GG3 and GG4 to extend in the first direction similarly to the first to fourth gate groups GG1, GG2, GG3, and GG4 and form a first drain line 613-D-1 and a second drain line 613-D-2.

FIGS. 50A and 50B show cross-sectional structures along the line A-A′ in FIG. 49. FIG. 50A is a cross-sectional view transversely extending through two memory cells. FIG. 50B is a partially enlarged view of FIG. 50A. The second gate group GG2 formed of the memory gate MG2, the selection gate SG2, and the dummy gate DG2 and the third gate group GG3 formed of the memory gate MG3, the selection gate SG3, and the dummy gate DG3 are shown in the cross sections. In the portion of a semiconductor substrate 600 located between the second and third gate groups GG2 and GG3, a source region 613-S formed of the diffusion layer is formed. Additionally, in the portion of the semiconductor substrate 600 located outside the second and third gate groups GG2 and GG3, the drain regions 613-D formed of the diffusion regions are formed such that these gate groups GG2 and GG3 are interposed therebetween.

Between the memory gates MG2 and MG3 and the main surface MS of the semiconductor substrate 600, the gate insulating film GZ having a laminated structure is located. The gate insulating film GZ having the laminated structure has an insulating film 608, an insulating film 609 serving as a charge storage film, and an insulating film 611 in order of increasing distance from the main surface MS side of the semiconductor substrate 600. Preferably, the insulating film 608 is formed of a silicon oxide film, the insulating film 609 is formed of a silicon nitride film, and the insulating film 611 is formed of a silicon oxide film.

The gate insulating film GZ having the laminated structure is also present between the memory gate MG2 and the selection gate SG2 and between the selection gate Sg2 and the dummy gate DG2. The gate insulating film GZ is also present between the memory gate MG3 and the selection gate SG3 and between the selection gate SG3 and the dummy gate DG3.

Embodiment 6 also has a gate insulating film 605 between each of the selection gates SG2 and SG3 and the main surface MS of the semiconductor substrate 600. Further, Embodiment 6 has an insulating film 607 over a polysilicon film 606. The insulating film 605 is formed of a silicon oxide film, and the insulating film 607 is formed of the silicon nitride film 607.

The selection gates SG2 and SG3 are arranged side by side with the memory gates MG2 and MG3 with the laminated gate insulating film GZ interposed therebetween.

FIG. 51 is the partial cross-sectional view of the memory cell array along the line B-B′ in FIG. 49. FIG. 51 shows a cross section vertically extending through the two memory cells and along the selection gate SG4. Since FIG. 51 is the same as the equivalent drawing in Embodiment 1, the description thereof is omitted.

FIG. 52 is the partial cross-sectional view of the memory cell array along the line C-C′ in FIG. 49. FIG. 52 also shows a cross section which vertically extends through the two memory cells but along the memory gate MG1. As can be seen from the drawing, the upper surface UP of each of the isolation regions DIR is present at the position different from that of the main surface MS of the semiconductor substrate 600. That is, the upper surface UP is located below the main surface MS. As a result, the upper surface UP of the isolation region DIR has a shape recessed from the main surface MS of the semiconductor substrate 600.

The gate insulating film GZ having the laminated structure has the insulating film 608, the insulating film 609 as the charge storage film, and the insulating film 611 over the main surface MS of the portion of the semiconductor substrate which is not formed with the isolation regions DIR.

On the other hand, the portion of the gate insulating film GZ having the laminated structure which is located over each of the isolation regions DIR further has an insulating film 610 besides the insulating film 608, the insulating film 609 as the charge storage film, and the insulating film 611. The insulating film 610 is formed of a silicon oxide film.

As a result, the insulating film present between the memory gate 612 and the insulating film 609 as the charge storage film located thereunder has the difference between the thicknesses thereof over the isolation region DIR and over the region of the semiconductor substrate 600 other than the isolation regions.

That is, over the isolation region DIR, the thickness of the insulating film between the memory gate 612 and the insulating film 609 is the total thickness of the insulating films 610 and 611 while, over the portion of the semiconductor substrate 100 without the isolation regions, the thickness of the insulating film between the memory gate 612 and the insulating film 609 is the thickness of the insulating film 611. Consequently, the film thickness over the isolation region DIR is larger than that over the semiconductor substrate 100. Here, of the insulating film present between the memory gate MG1 and the insulating film 609 as the charge storage film located thereunder, the portion located over the portion of the semiconductor substrate 600 without the isolation regions and the portion located over each of the isolation regions DIR are respectively referred to also as a first insulating film and a second insulating film. Accordingly, due to the presence of the insulating film 610, the thickness of the second insulating film is larger than the thickness of the first insulating film. In other words, the thickness of the first insulating film is smaller than the thickness of the second insulating film.

FIGS. 53A and 53B are the partial cross-sectional views of the memory cell array along the line D-D′ in FIG. 49. FIG. 53A shows a cross section along an isolation region 604 between the plurality of memory cells. FIG. 53B is a partially enlarged view of FIG. 53A.

As can be seen from the drawings, the upper surface UP of each of the isolation region DIR is located at a position recessed from the position of the main surface MS of the semiconductor substrate 600 having the drain (Drain) regions 613-D and, over the isolation region DIR, the memory gates MG2 and MG3 and the dummy gates DG2 and DG3 which are shown in FIG. 49 are present.

Also, the selection gates SG2 and SG3 respectively facing the memory gates MG2 and MG3 are located over the isolation region DIR.

Embodiment 6 also has a gate insulating film GZ6 having a laminated structure under each of the memory gates MG2 and MG3. The gate insulating film GZ6 having the laminated structure over each of the isolation regions DIR has the insulating film 609 serving as the charge storage film, the insulating film 610, and the insulating film 611 in order of increasing distance from the isolation region DIR side.

The gate insulating film GZ having the laminated structure further extends to respective positions between the memory gates MG2 and MG3 and the selection gates SG2 and SG3 respectively facing the memory gates MG2 and MG3.

Methods for the read, erase, and write operations to the memory cell described in Embodiment 6 are the same as in Embodiment 1.

The manufacturing method is also generally the same as in the manufacturing process (FIGS. 16 to 26) of Embodiment 1. That is, the steps in the steps P-1 to P-4 shown in FIG. 16 of Embodiment 1 are performed and, in the step P-5, the polysilicon film 112 is subjected to sidewall processing to form the memory gate on one side of each of the selection gates. Then, the polysilicon film 112 on the other side of the selection gate is left without being removed to form the dummy gate DG.

Thereafter, the steps of forming the diffusion layers and forming the contacts and the wires in the step P-6 (FIG. 26) are performed. However, to form the diffusion layers under the sidewall gates (dummy gates) not to be removed, oblique implantation is performed as ion implantation for the diffusion layers. Embodiment 6 described above achieves the same function/effect as achieved by Embodiment 1.

### Embodiment 7

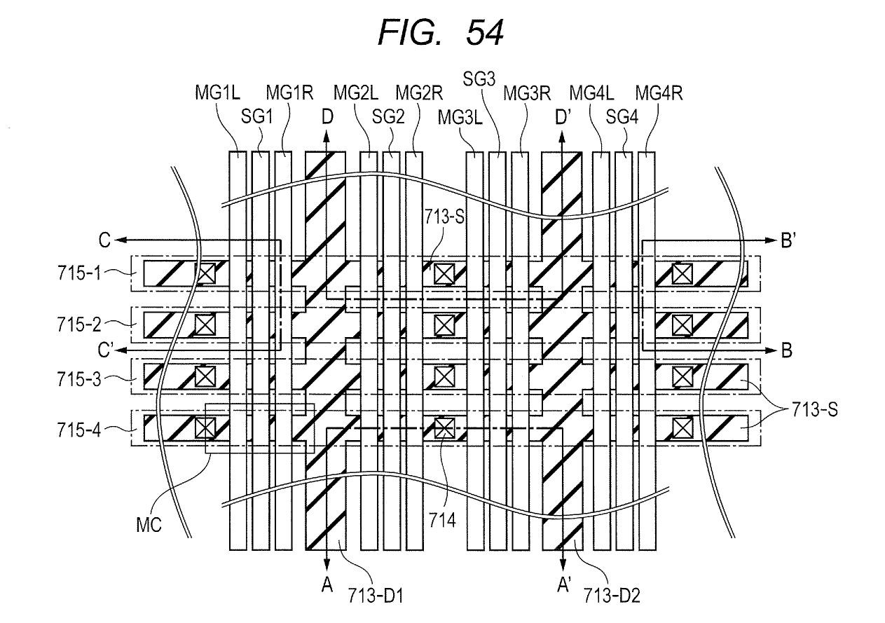

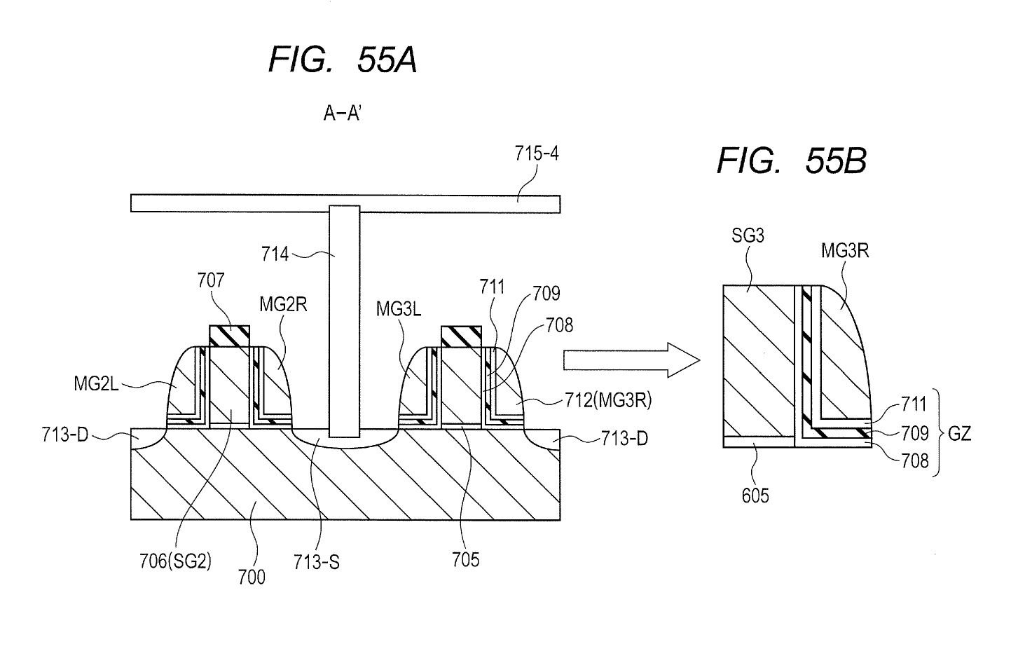

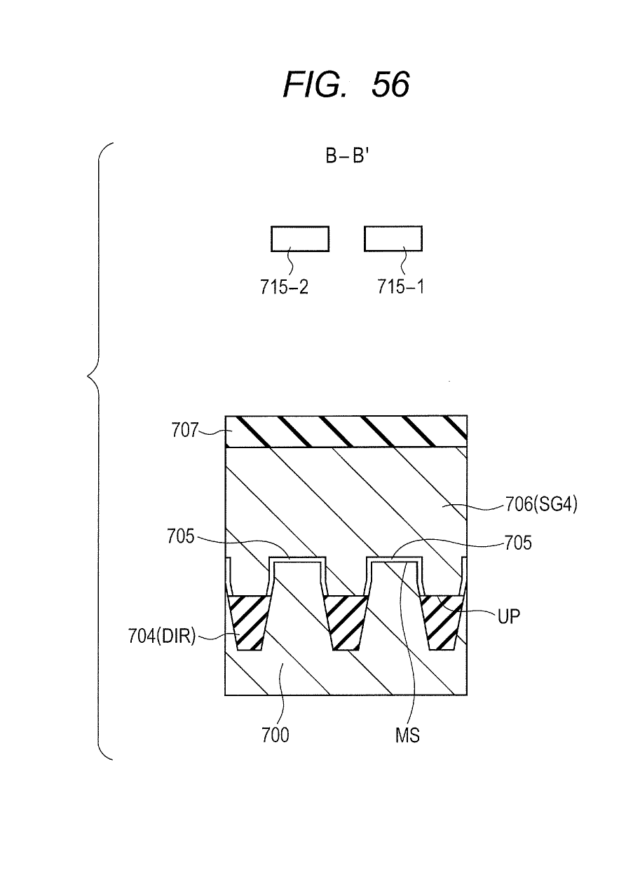

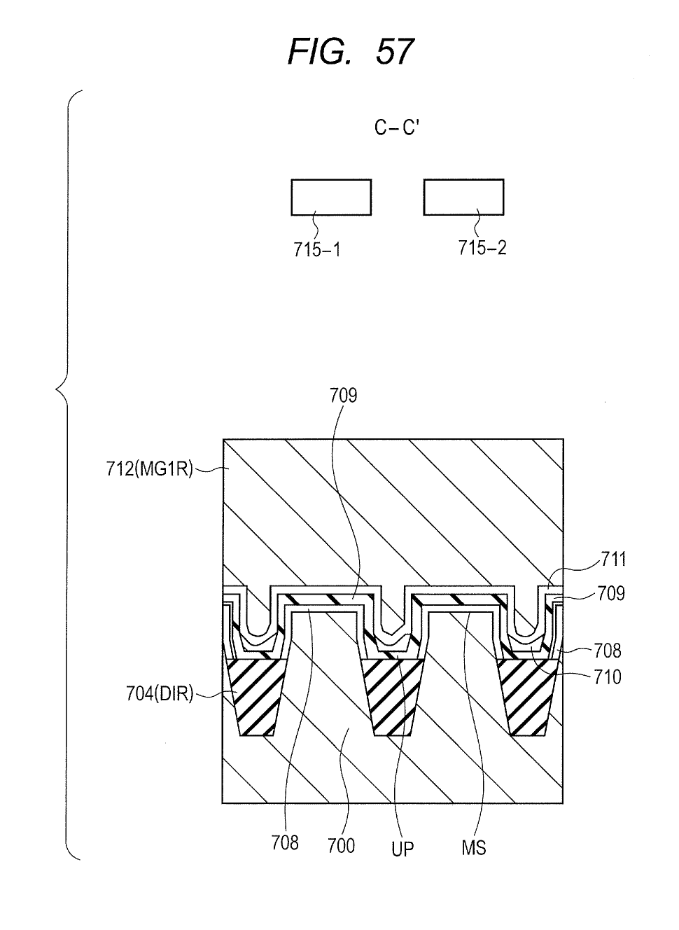

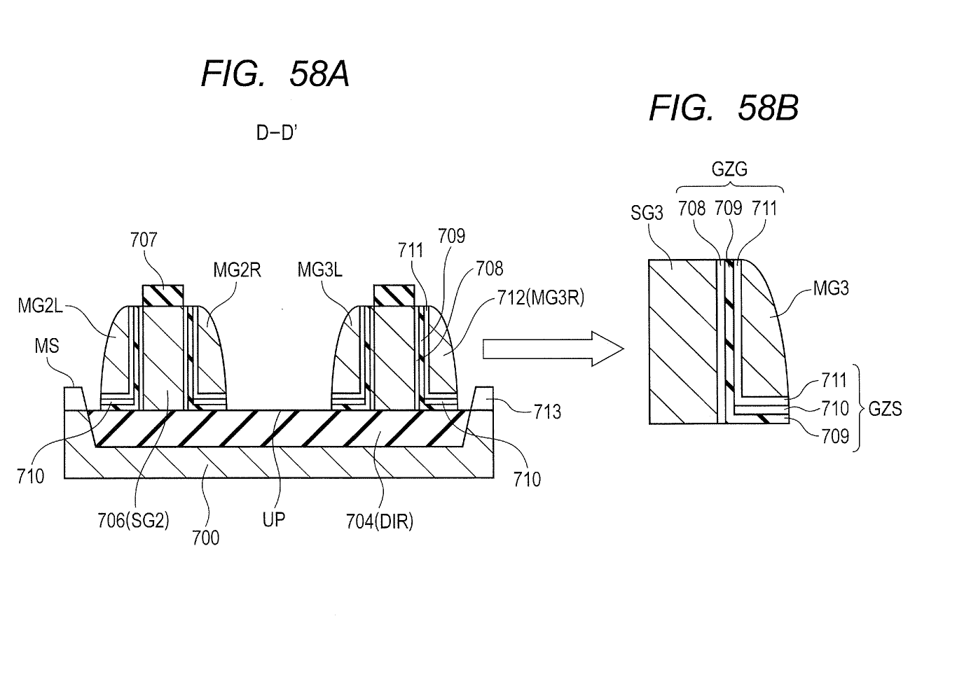

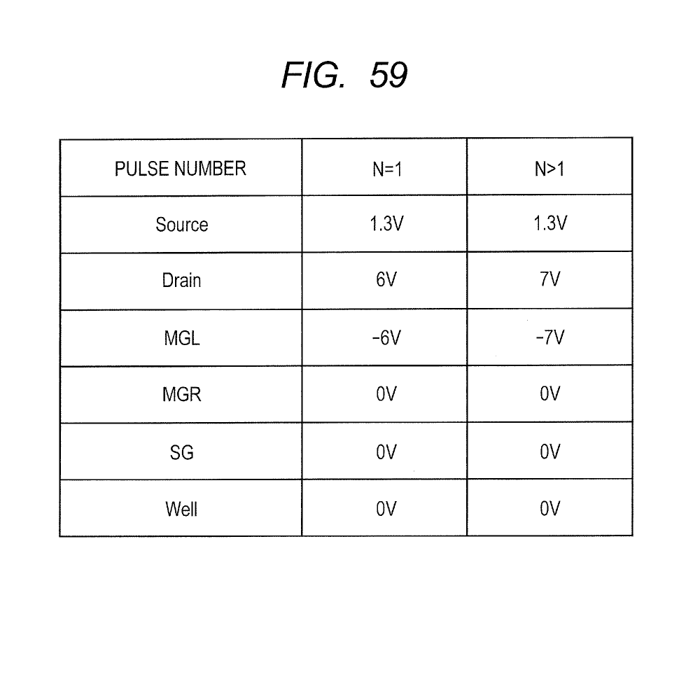

FIG. 54 is a plan view of a memory cell array in a semiconductor device according to Embodiment 7. FIG. 55A is a partial cross-sectional view of the memory cell array along the line A-A′ in FIG. 54. FIG. 55B is a partially enlarged view of FIG. 55A. FIG. 56 is a partial cross-sectional view of the memory cell array along the line B-B′ in FIG. 54. FIG. 57 is a partial cross-sectional view of the memory cell array along the line C-C′ in FIG. 54. FIG. 58A is a partial cross-sectional view of the memory cell array along the line D-D′ in FIG. 54. FIG. 58B is a partially enlarged view of FIG. 58A.

Embodiment 7 is different from Embodiments 1 and 6 only in memory cells. The structure of the semiconductor device is otherwise the same as that of Embodiment 6. Each of the memory cells of Embodiment 7 has a so-called twin MONOS structure in which two polysilicon films (memory gates) each having a sidewall shape are present on both sides of a selection gate (control gate) with the selection gate being interposed therebetween. That is, as shown in FIG. 54, the structure has memory gates MG1L, MG2L, MG3L, and MG4L on one side of the selection gates (control gates) SG1, SG2, SG3, and SG4, while having memory gates MG1R, MG2R, MG3R, and MG4R on the other side of the selection gates (control gates) SG1, SG2, SG3, and SG4. Each of the selection gates and the pair of memory gates on both sides thereof form one gate group. The dummy gates DG1, DG2, DG3, and DG4 of Embodiment 6 are respectively replaced with the memory gates MG1L, MG2R, MG3L, and MG4R of Embodiment 7. The memory gates MG1, MG2, MG3, and MG4 of Embodiment 6 respectively correspond to and are the same as the memory gates MG1R, MG2L, MG3R, and MG4L of Embodiment 7.

The reference numerals “7XX” and “7XX-X” in FIGS. 54 to 58 correspond to and are the same as the reference numerals “1XX” and “1XX-X” of Embodiment 1 and the reference numerals “6XX” and “6XX-X” of Embodiment 6. For example, the reference numeral “715-1” of Embodiment 7 corresponds to and is the same as the reference numeral “115-1” of Embodiment 1 and the reference numeral “615-1” of Embodiment 6. Therefore, the repeated description of the same parts as in Embodiment 1 or 6 is omitted. However, in the context of description, the description in Embodiment 7 has a part overlapping the description in Embodiment 1 or 6.

The shape of the source 713-S shown in FIG. 55A is different from the shape of the source 113-S in Embodiment 1 and the shape of the source 613-S in Embodiment 6. That is, the source 713-S does not extend to the selection gates SG2 and SG3. In addition, the memory gate MG2R is located on the right side of the selection gate SG2 and the memory gate MG3L is located on the left side of the selection gate SG3. FIGS. 55A and 55B are otherwise the same as FIGS. 50A and 50B of Embodiment 6 so that the description thereof is omitted. Since FIG. 56 is the same as FIG. 51 of Embodiment 6, the description thereof is omitted.

The cross-sectional view of FIG. 57 vertically extends through the two memory cells and along the memory gate MG1R.

As can be seen from the drawing, the upper surface UP of each of the isolation regions DIR is present at a position different from that of the main surface MS of a semiconductor substrate 700. That is, the upper surface UP is located blow the main surface MS. As a result, the upper surface UP of the isolation region DIR has a shape recessed from the main surface MS of the semiconductor substrate 700. Over the semiconductor substrate 700 and the isolation regions DIR, the memory gate MG1R and the gate insulating film GZ located thereunder and having the laminated structure extend. The memory gate MG1R has a shape selectively protruding toward the upper surface UP of the isolation region DIR.

Such structures of the memory gate and the gate insulating film located thereunder are substantially the same as in Embodiments 1 and 6.

That is, the gate insulating film GZ having the laminated structure has an insulating film 708, an insulating film 709 as a charge storage film, and an insulating film 711 over the main surface MS of the portion of the semiconductor substrate 700 which is not formed with the isolation regions.

On the other hand, the portion of the gate insulating film GZ having the laminated structure which is located over the isolation regions DIR further has an insulating film 710 besides the insulating film 708, the insulating film 709 as the charge storage film, and the insulating film 711.

As a result, the insulating film present between the memory gate MG1R and the insulating film 709 as the charge storage film located thereunder has a difference between the thicknesses thereof over the isolation region DIR and over the region of the semiconductor substrate 700 other than the isolation regions. Here, of the insulating film present between the memory gate MG1R and the insulating film 709 as the charge storage film located thereunder, the portion located over the portion of the semiconductor substrate 700 without the isolation regions and the portion located over each of the isolation regions DIR are respectively referred to also as a first insulating film and a second insulating film. Accordingly, due to the presence of the insulating film 710, the thickness of the second insulating film is larger than the thickness of the first insulating film. In other words, the thickness of the first insulating film is smaller than the thickness of the second insulating film.

Methods for the read, erase, and write operations to the memory cell described in Embodiment 7 described above are basically the same as in Embodiment 1. However, because of the presence of the two memory gates, the read, erase, and write operations in Embodiment 7 will be describe below in detail.

However, charges are injected into the charge storage films on the first memory gate (MGL) (memory gates denoted by the reference numerals MG1L, MG2L, MG3L, and MG4L) side. That is, it is assumed that a memory operation of reading, erasing, or writing is performed to the first memory gate (MGL) side. The second memory gate (MGR) faces the first memory gate (MGL) with the selection gate (SG) interposed therebetween.

(1) Read Operation

To the diffusion layer on the first memory gate (MGL) side, 0 V is applied and, to the diffusion layer on the second memory gate (MGR) side, a positive potential of about 1.0 V is applied. To the selection gate (SG), a positive potential of about 1.3 V is applied and, to the second memory gate (MGR), a voltage higher than the write threshold value of the memory cell is applied to turn ON the channels under the second memory gate (MGR) and the selection gate (SG).

Here, by giving a proper memory gate potential (i.e., a middle potential between the threshold value in a write state and the threshold value in an erase state) which allows the difference between the threshold values of the first memory gate (MGL) given by the write state and the erase state to be recognized, held charge information can be read as a current.

(2) Erase Operation

For example, a voltage of −6 V is applied to the first memory gate (MGL) and a voltage of 0 V is applied to each of the second memory gate (MGR) and the selection gate (SG). On the other hand, 6 V is applied to the diffusion layer (Drain) on the first memory gate (MGL) side and 1.3 V is applied to the diffusion layer (Source) on the second memory gate (MGR) side. However, the diffusion layer (Source) on the second memory gate (MGR) side may also be brought into an electrically open state. As a result, holes are generated in the semiconductor substrate and injected into the charge storage film.

When the erase operation is actually performed to the memory cell, the erase pulse is applied to inject holes into the charge storage film and thereby effect the erase operation. Then, by a verify operation, it is verified whether or not the memory cell has reached a desired threshold value. A sequence is repeated in which, when the memory cell has not reached the desired threshold value, the erase pulse is applied again.

Typical applied voltages are as shown above. However, erase conditions after the verification need not necessarily be the same as the conditions for the first application of the erase pulse. FIG. 59 shows an example of the erase pulse in that case.

(3) Write Operation

To the memory cell of Embodiment 7, writing is performed by injecting electrons therein from the silicon substrate side by the SSI injection method in the same manner as to the memory cell of Embodiment 1. As a method for injecting electrons from the silicon substrate side, a voltage of, e.g., 10 V is applied to the first memory gate (MGL), a voltage higher than the threshold value of the memory cell in the write state is applied to the second memory gate (MGR). On the other hand, a voltage of 0.9 V is applied to the selection gate (SG), a voltage of 4.5 V is applied to the drain (Drain) region on the first memory gate (MGL) side, and a voltage lower than the voltage applied to the drain region (Drain), e.g., 0.3 V is applied to the source (Source) region on the second memory gate (MGR) side. In this manner, the injection of charges (electrons) is performed locally into the end portion of the first memory gate (MGL) located on the selection gate (SG) side.

When writing is actually performed to the memory cell, it is verified by a verify operation whether or not the memory cell has reached a desired threshold value. A sequence is repeated in which, when the memory cell has not reached the desired threshold value, the SSI pulse is applied again.

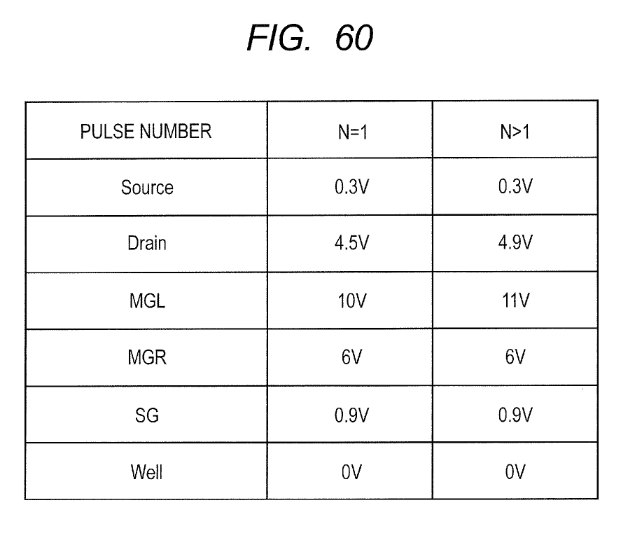

Typical applied voltages are as shown above. However, in the same manner as in the erasing after the verification, write conditions need not necessarily be the same as the conditions for the first application of the SSI pulse. FIG. 60 shows an example in that case.

The manufacturing method is also generally the same as in the manufacturing process of Embodiment 1. That is, the steps in the steps P-1 to P-4 shown in FIG. 16 are performed and, in the step P-5, the polysilicon film 112 is subjected to sidewall processing to form the first memory gate (MGL) and the second memory gate (MGR) on both sides of each of the selection gates (SG). Then, unlike in the first embodiment, the polysilicon film 112 of the second memory gate (MGR) and the insulating films 108, 109, and 111 are left without being removed. That is, by not performing steps for removal such as lithography and dry etching, the second memory gate (MGR) is formed. In the step P-5, the step of forming the second memory gate (MGR) first and then forming the first memory gate (MGL) may also be performed. In Embodiment 7, the polysilicon film 112 can also be referred to as a polysilicon film 712. Thereafter, the steps of forming the diffusion layers, the contacts, and the wires in the step P-6 (FIG. 26) are performed to form the memory cell array.

In Embodiment 7, the step of removing the sidewall gates on one side of the memory gates is unnecessary. This allows the manufacturing process to be further simplified than in Embodiment 1.

Embodiment 7 described above achieves the same function/effect as achieved by Embodiments 1 and 6.

### Embodiment 8

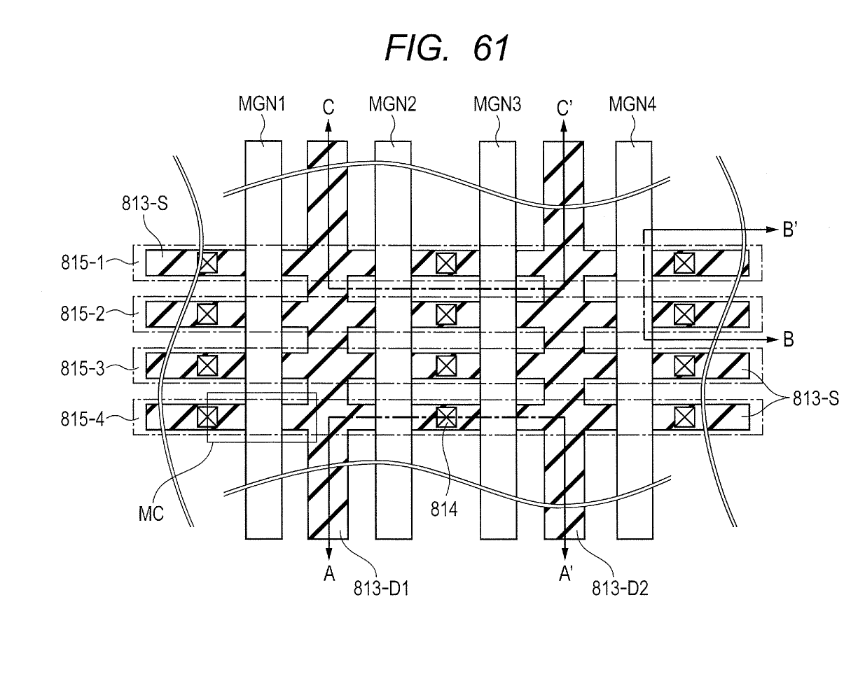

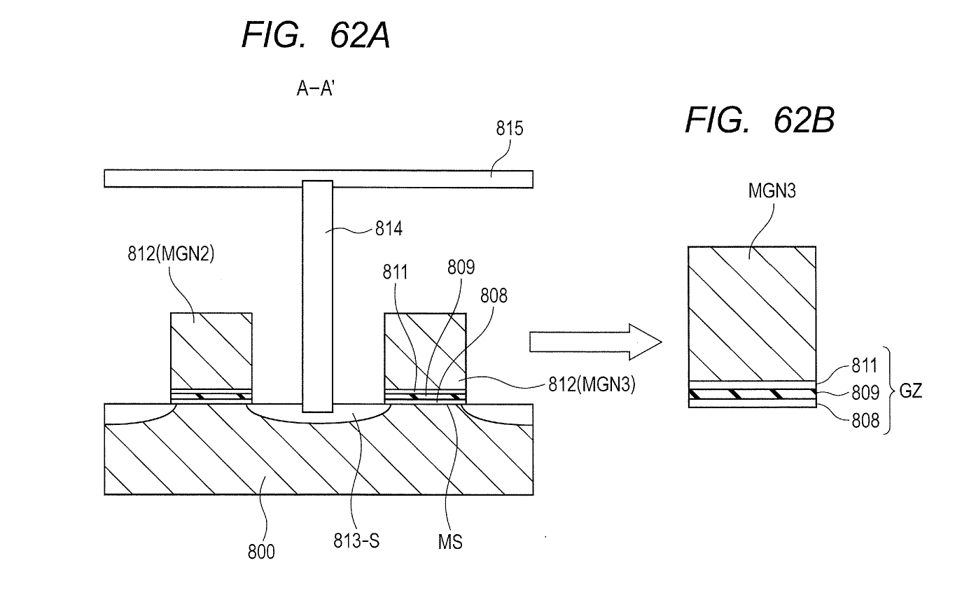

FIG. 61 is a top view of a memory cell array in Embodiment 8. FIGS. 62A and 62B, 63, and 64 are cross-sectional views along the respective lines A-A′, B-B′, and C-C′ in FIG. 61.

Embodiment 8 is different from Embodiment 1 in memory cell configuration. Each of the memory cells shown in Embodiment 8 is not of a split-gate type, but is formed of one transistor and does not have the selection gate SG. The memory cell of Embodiment 8 is a so-called NROM (Nitrided Read Only Memory). The memory cell of Embodiment 8 is also applicable to a mirror bit memory in which, in the silicon nitride film in the vicinity of the source region and the drain region, charges are locally stored to store 2-bit-per-cell data or, in the vicinity of the source or drain region, 2-bit information is recorded to store 4-bit-per-cell data.

The square region enclosed in the solid line in FIG. 61 corresponds to one memory cell. The memory cell array has a plurality of the memory cells MC arranged in rows and columns (as a matrix) and isolation regions adjacent to and located therebetween. Each of the memory gates MGN1, MGN2, MGN3, and MGN4 extends in the same direction (first direction). The memory cell array has diffusion regions 813 traversing (or orthogonal to) the plurality of memory gates MGN1, MGN2, MGN3, and MGN4 and extending in another direction (second direction) different from the first direction, while extending in the first direction between the memory gates. Drain regions 813-D are formed between the memory gates MGN1 and MGN2 and between the memory gates MGN3 and MGN4 and extend in the first direction similarly to the group of memory gates MGN1, MGN2, MGN3, and MGN4 to form a first drain line 813-D-1 and a second drain line 813-D-2.

FIGS. 62A and 62B show the respective cross sections of the memory gates MGN2 and MGN3. FIG. 62B is a partially enlarged view of FIG. 62A. In the portion of a semiconductor substrate 800 located between the memory gates MGN2 and MGN3, a source region 813-S formed of a diffusion layer is formed. In addition, in the portion of the semiconductor substrate 800 located outside the memory gates MGN2 and MGN3, drain regions 813-D-1 and 813-D-2 each formed of a diffusion layer are formed such that the memory gates MGN2 and MGN3 are interposed therebetween. Between the memory gates MGN2 and MGN3 and the main surface MS of the semiconductor substrate 800, the gate insulating film GZ having a laminated structure is located. The gate insulating film GZ having the laminated structure has an insulating film 808, an insulating film 809 serving as a charge storage film, and an insulating film 811 in order of increasing distance from the main surface MS side of the semiconductor substrate 800. Preferably, the insulating film 808 is formed of a silicon oxide film, the insulating film 809 is formed of a silicon nitride film, and the insulating film 811 is formed of a silicon oxide film.

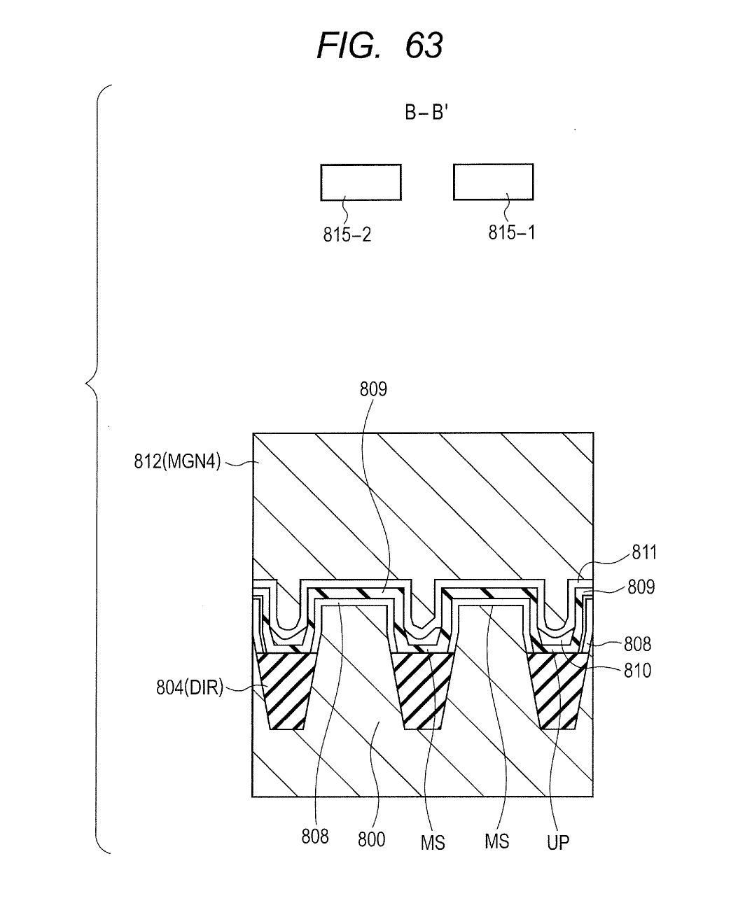

FIG. 63 is a cross section vertically extending through the two memory cells and along the memory gate MGN4. The insulating films between the first and second source lines 815-1 and 815-2 and the memory gate MG4 located thereunder are omitted without being illustrated. As can be seen from the drawings, the upper surface UP of each of the isolation regions DIR is present at the position different from that of the main surface MS of the semiconductor substrate 800. That is, the upper surface UP is located below the main surface MS. Accordingly, the upper surface UP of each of the isolation regions DIR has a shape recessed from the main surface MS of the semiconductor substrate 800. Over the semiconductor substrate 800 and over the isolation regions DIR, the memory gate MGN4 and the gate insulating film GZ having the laminated structure and located thereunder extend. A part of the memory gate MGN4 has a shape (protruding shape) protruding toward the upper surface UP of each of the isolation regions DIR. Such structures of the memory gate and the gate insulating film located thereunder shown in the cross-sectional view of FIG. 63 are substantially the same as in Embodiments 1, 6, and 7 described above.

As shown in FIG. 62, the gate insulating film GZ having the laminated structure has the insulating film 808, the insulating film 809 as the charge storage film, and the insulating film 811 over the main surface MS of the portion of the semiconductor substrate 800 which is not formed with the isolation regions.

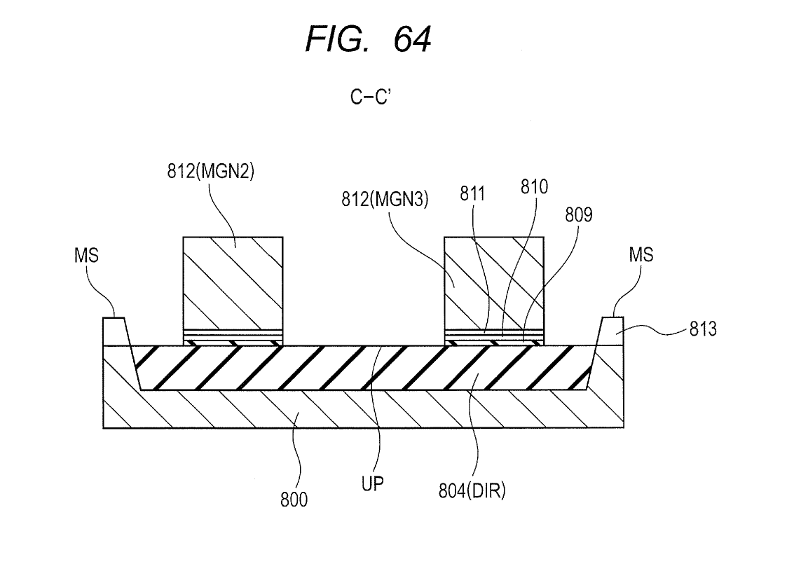

On the other hand, the portion of the gate insulating film. GZ having the laminated structure which is located over each of the isolation regions DIR has the insulating film 809 as the charge storage film, the insulating film 810, and the insulating film 811 which are laminated in this order, as shown in FIGS. 63 and 64. As a result, the insulating film present between the memory gate MGN4 and the insulating film 809 as the charge storage film located thereunder has the difference between the thicknesses thereof over the isolation regions DIR and over the region of the semiconductor substrate 800 other than the isolation regions. This is because, as described above, the insulating film present between the memory gate MGN4 and the insulating film 809 is the laminated film including the insulating films 810 and 811 over the isolation regions DIR, while the insulating film present between the memory gate MGN4 and the insulating film 809 is the insulating film 811 (does not have the insulating film 810) over the region of the semiconductor substrate 800 other than the isolation regions. Here, of the insulating film present between the memory gate MGN4 and the insulating film 809 as the charge storage film located thereunder, the portion located over the portion of the semiconductor substrate 800 without the isolation regions and the portion located over each of isolation regions 804 are respectively referred to also as a first insulating film and a second insulating film. In other words, the thickness of the first insulating film is smaller than the thickness of the second insulating film. In terms of this point also, Embodiment 8 is substantially the same as Embodiments 1, 6, and 7 described above.

Methods for the read, erase, and write operations to the memory cell shown in Embodiment 8 will be described.

(1) Read Operation

In the read operation, 0 V is applied to the source and a voltage of about 1.0 V is applied to the drain. Here, by applying a proper voltage (i.e., a middle potential between the threshold value in the write state and the threshold value in the erase state) which allows the difference between the threshold values of the memory gate given by the write state and the erase state to be recognized to the memory gate (MG), information in the memory cell can be read. Even when 2 or more bits of information is stored in the region on one side by controlling the quantity of charges locally injected into the source region (or drain region) also, by applying the voltage between the threshold values of each of the memory cells to the memory gate, data can be read.

(2) Erase Operation

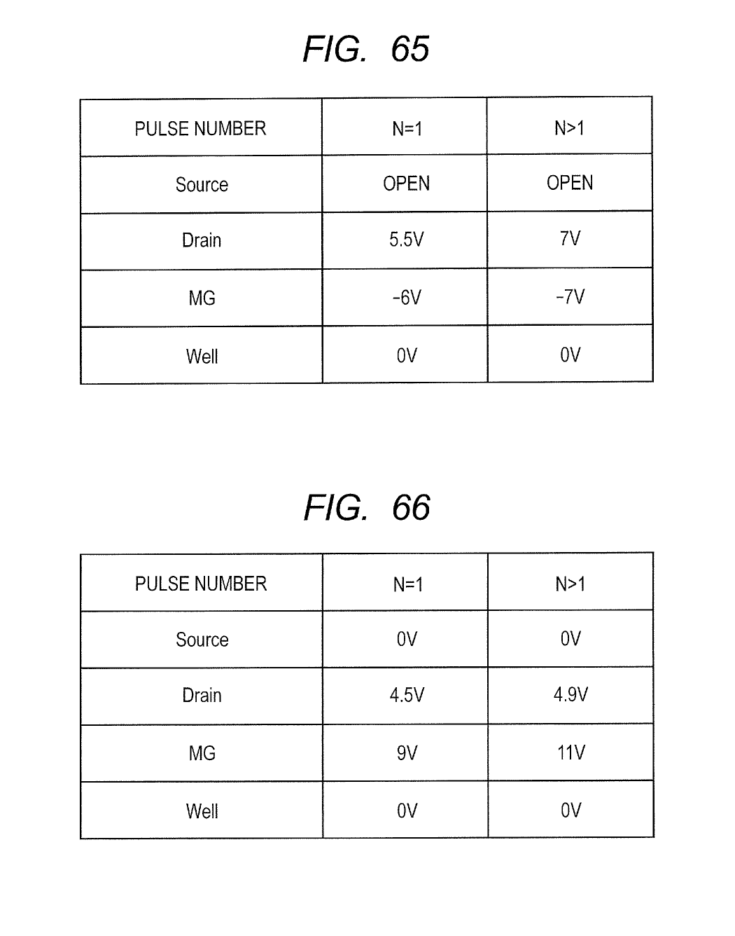

The erase operation is performed by generating holes in the silicon substrate and injecting the holes into the silicon nitride film, in the same manner as in Embodiment 1. As an example of the voltages applied to the respective electrodes when the data stored locally on the drain side is to be erased, 5.5 V is applied to the drain (Drain) and −6 V is applied to the gate (MG), while the source (Source) is brought into a floating state. When the erase operation is actually performed to the memory cell, an erase pulse is applied to inject holes into the charge storage film and thereby effect the erase operation. Then, by a verify operation, it is verified whether or not the memory cell has reached a desired threshold value. A sequence is repeated in which, when the memory cell has not reached the desired threshold value, the erase pulse is applied again. Typical applied voltages are as shown above. However, erase conditions after the verification need not necessarily be the same as the conditions for the first application of the erase pulse. FIG. 65 shows an example of the erase pulse in that case. In FIG. 65, N=1 shows the first application of the erase pulse, and N>1 shows the second or subsequent application of the erase pulse. Here, the “Well” shown in the drawing indicates the region of the semiconductor substrate 800 which supplies a substrate potential to the memory transistor MT.

(3) Write Operation

A typical write operation is a channel hot electron (CHE) injection method. In this example, for instance, 0 V is applied to the source (Source) of the memory cell, 4.5 V is supplied to the drain (Drain) thereof, and 9 V is applied to the gate (MG) thereof. In this manner, a horizontal electric field which accelerates electrons from the source to the drain is generated. When the electrons in the vicinity of the drain region obtains sufficiently high energy, due to a vertical electric field, the electrons pass through the insulating film 808 to be injected into the insulating film 809 as the charge storage film. When the write operation is actually performed to the memory cell, it is verified by a verify operation whether or not the memory cell has reached a desired threshold value. A sequence is repeated in which, when the memory cell has not reached the desired threshold value, the CHE pulse is applied again. Typical applied voltages are as shown above. However, in the same manner as in erasing after the verification, write conditions need not necessarily be the same as the conditions for the first application. FIG. 66 shows an example in that case. In FIG. 66, N=1 shows the first application of the CHE pulse, and N>1 shows the second or subsequent application of the CHE pulse.

Embodiment 8 achieves the same function/effect as achieved by Embodiment 1. That is, as shown in FIGS. 63 and 64, the upper surface UP of each of the isolation regions 804 is located below the main surface MS of the semiconductor substrate 800 to have a shape recessed from the main surface MS of the semiconductor substrate 800. This results in the structure (so-called Fin structure) in which a part of the memory gate MGN4 and the charge storage film 809 protrude toward the recess. As a result, during writing, charges are injected extensively into a part of the charge storage film 809 present in the foregoing recessed portion so that the gate width (channel width) of the memory gate extends to a position over the isolation region 804. This allows the active region of the memory cell to be larger in area than in the case without the foregoing recess. Consequently, a read current can be increased to be larger than in the case without the foregoing recess.

Additionally, as shown in FIG. 63, not only the part of the memory gate MGN4 and the charge storage film (silicon nitride film) 809 located thereunder protrude toward the upper surface UP of each of the isolation regions 804, but also the insulating film between the charge storage film 809 and the memory gate MGN4 over the upper surface UP of the isolation region 804 is formed of the silicon oxide films 810 and 811. This results in a structure in which the insulating film between the charge storage film 809 and the memory gate MGN4 over the upper surface UP of the isolation region 804 is thicker than the insulating film (silicon oxide film) 811 between the charge storage film (silicon nitride film) 809 and the memory gate MGN4 over the main surface MS of the semiconductor substrate 800. Therefore, as shown in FIG. 63, it is possible to limit the regions (data retention regions) of the charge storage film 809 in which charges are stored over the isolation regions 804 to elongate the regions of the silicon nitride film 809 in which charges are not stored between the adjacent cells (regions which do not retain data). As a result, charge diffusion between the adjacent cells is not easily performed to improve the data retention property (reduce the amount of degradation).

Also, in a multiple-value memory for storing 1 or more bits of data per cell, higher-precision control of the threshold values of the memory cells is required so that the present embodiment is used preferably therefor.

In the semiconductor device of Embodiment 8, even when the width of the isolation region is reduced through the scaling of the memory cells to reduce the distance between the adjacent memory cells, the effective length of the charge storage film over each of the isolation regions can be increased. This allows a reduction in mutual interference between the electrons or holes injected into the charge storage film of the memory cell and diffused into the portions of the charge storage film located over the isolation regions.

In the semiconductor device of Embodiment 8, even when the gate width in planar view is reduced through the scaling of the memory cells, the effective channel width (gate width) can be increased. Therefore, it is possible to ensure a read current corresponding to a high-speed operation.

Further, in the semiconductor device according to Embodiment 8, even under circumstances where an external environment is severe, such as when the semiconductor device is used as an in-vehicle product, high quality and reliability can be ensured.

In addition, through the scaling of a product chip size, it is possible to improve the number of products obtained from a single wafer and thereby achieve a cost reduction.

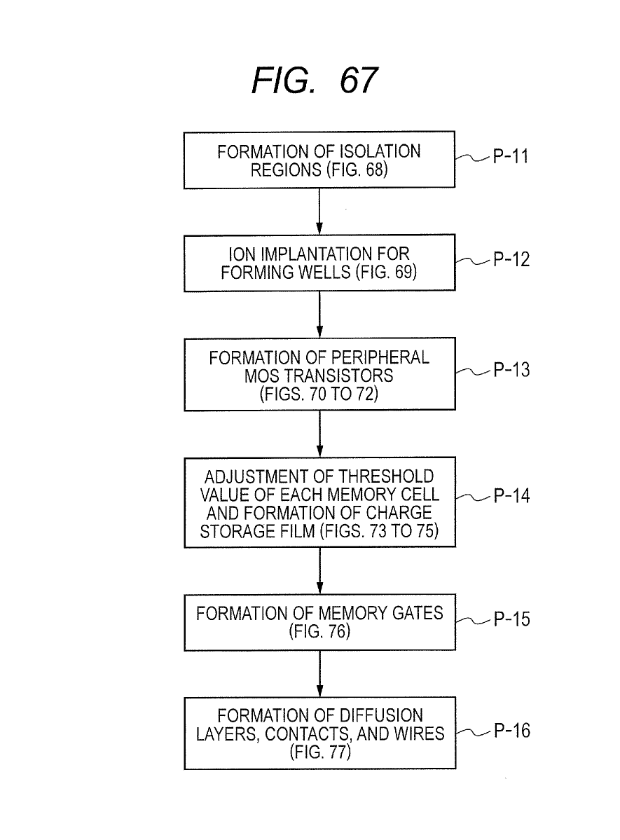

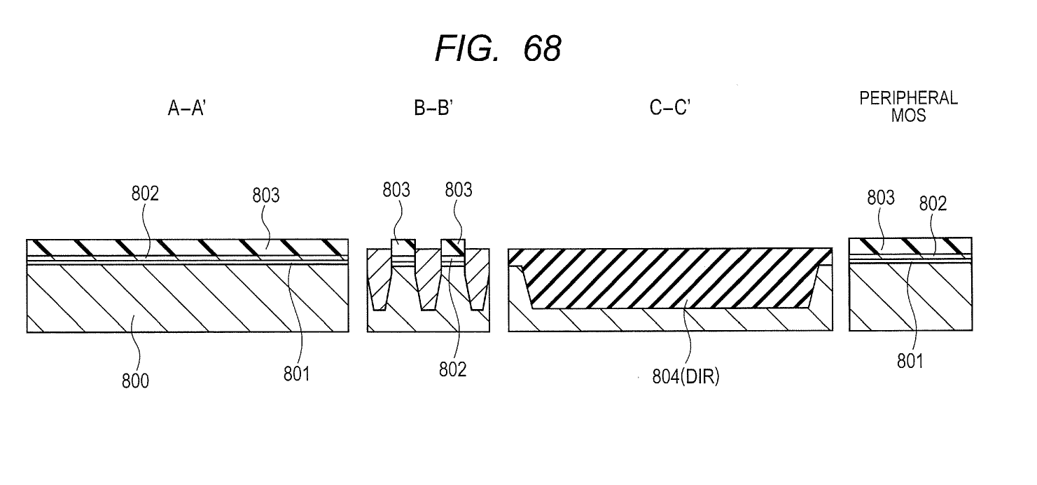

Next, using FIGS. 67 to 77, a description will be given of a manufacturing method of the semiconductor device of Embodiment 8. FIG. 67 is a flow chart showing the outline of the manufacturing method. FIGS. 68 to 77 are cross-sectional views in the individual process steps of Steps P-11 to P-16 shown in the flow chart. Note that, in the drawings, a memory cell array region and a peripheral circuit region are separately shown and the memory cell array region is shown in the cross sections along the lines A-A′, B-B′, and C-C′ in FIG. 61. As the peripheral circuit region, the peripheral MOS formation region is shown.

Here, the dimensions of the memory cell related to the present invention are such that the width of the active region of each of the memory cells in the memory cell array region and the width of each of the isolation regions DIR in the cross section along the line B-B′ are about 100 nm and 60 nm, respectively.

(a) Step P-11

The semiconductor substrate 800 made of silicon is thermally oxidized to form a silicon oxide film 801 of about 10 nm. Then, a polysilicon film 802 of about 10 nm and a silicon nitride film 803 of about 50 nm are deposited in this order (memory cell region and peripheral MOS formation region). By lithographic and etching techniques, trenches for isolation regions (STI) each at a depth of about 150 nm from the surface of the silicon substrate are formed. The silicon oxide film 804 is deposited and polished by a CMP method using the silicon nitride film 803 as a stopper to be left in the trenches and thereover (FIG. 68).

(b) Step P-12

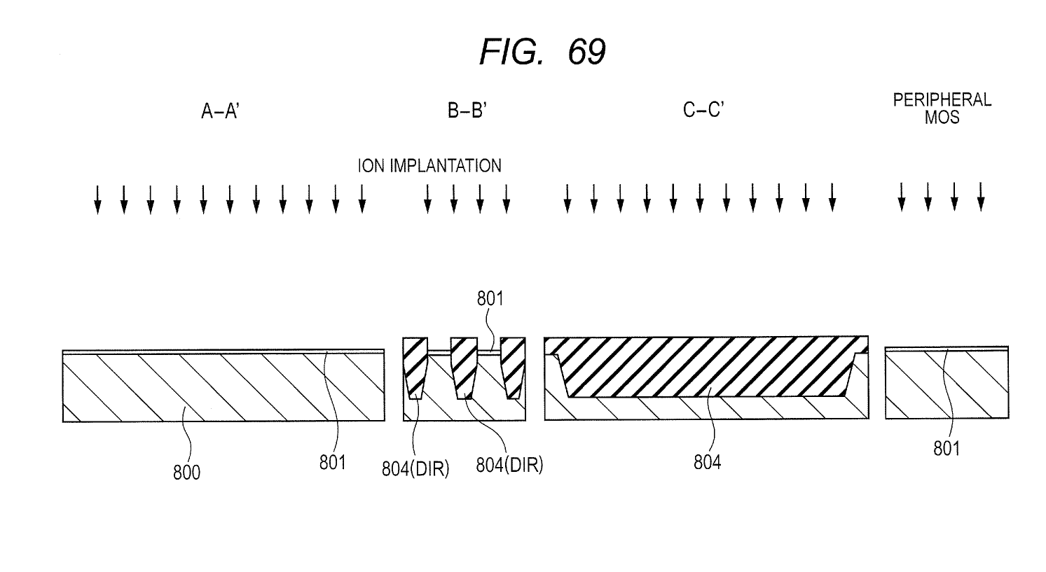

The silicon nitride film 803 and the polysilicon film 802 located thereunder are removed by wet etching and dry etching and, using the silicon oxide film 801 as a through film for ion implantation, p-type and n-type wells (not shown) are formed in the memory cell array formation region and the peripheral MOS formation region (FIG. 69).

(c) Step P-13

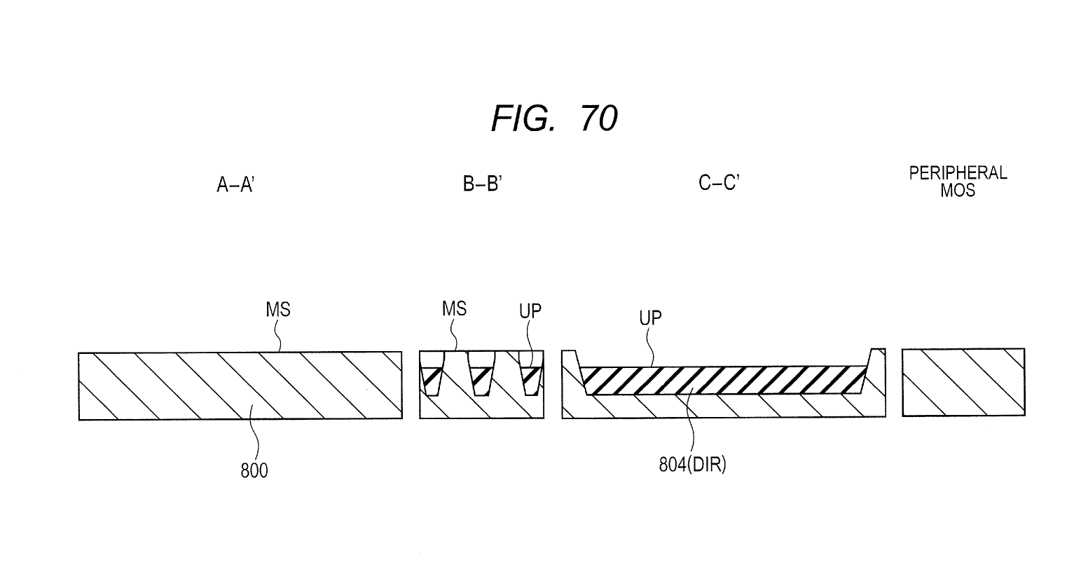

Next, the silicon oxide film 801 in the memory cell array formation region and the peripheral MOS formation region is removed by dry etching or wet etching. Further, a part of the silicon oxide film 804 in the isolation region DIR is removed. At this time, the part of the silicon oxide film 804 is removed such that, e.g., the depth of the silicon oxide film 804 from the surface of the silicon substrate 800 is about 50 nm. As a result, the main surface of the semiconductor substrate is newly exposed to form the main surface MS. On the other hand, the upper surface UP of the oxide film 804 in the isolation region DIR is at a depth of about 50 nm from the main surface MS of the semiconductor substrate and in a state recessed from the main surface MS of the semiconductor substrate (FIG. 70).

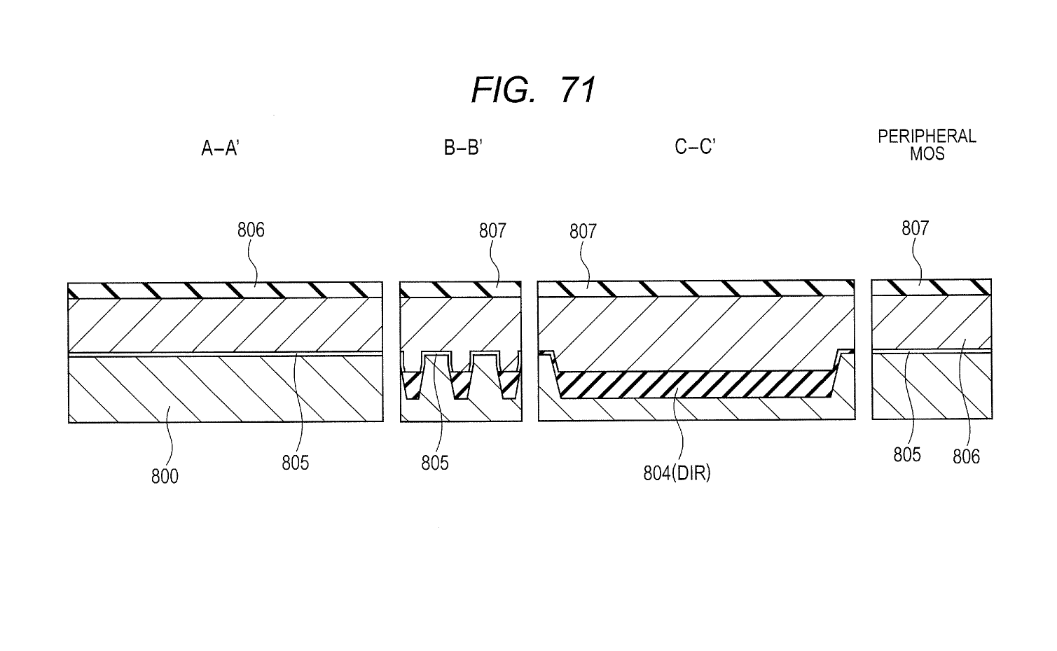

Subsequently, by a thermal oxidation method, a silicon oxide film 805 of about 1.4 nm serving as the gate insulating film of each of the peripheral MOS transistors is formed, and a polysilicon film 806 of about 80 nm serving as the gate electrode of the peripheral MOS transistor and a silicon nitride film 807 of about 20 nm are deposited (FIG. 71). Here, using lithographic and dry etching techniques, the silicon oxide film 805 may also be formed to have a plurality of levels of thicknesses.

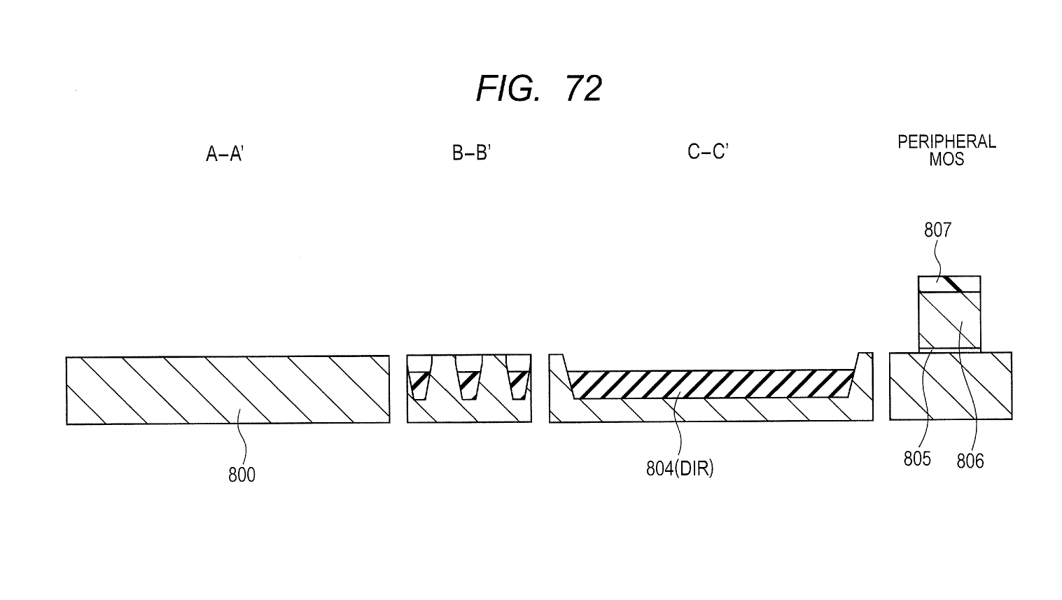

Next, using lithographic and etching techniques, the gates of the peripheral MOS transistors are formed (FIG. 72).

(d) Step P-14

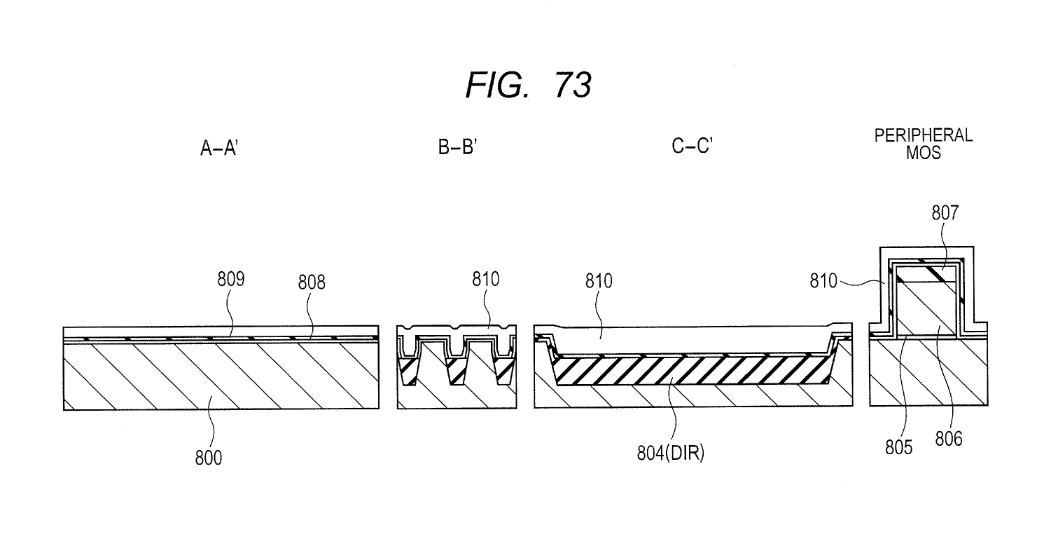

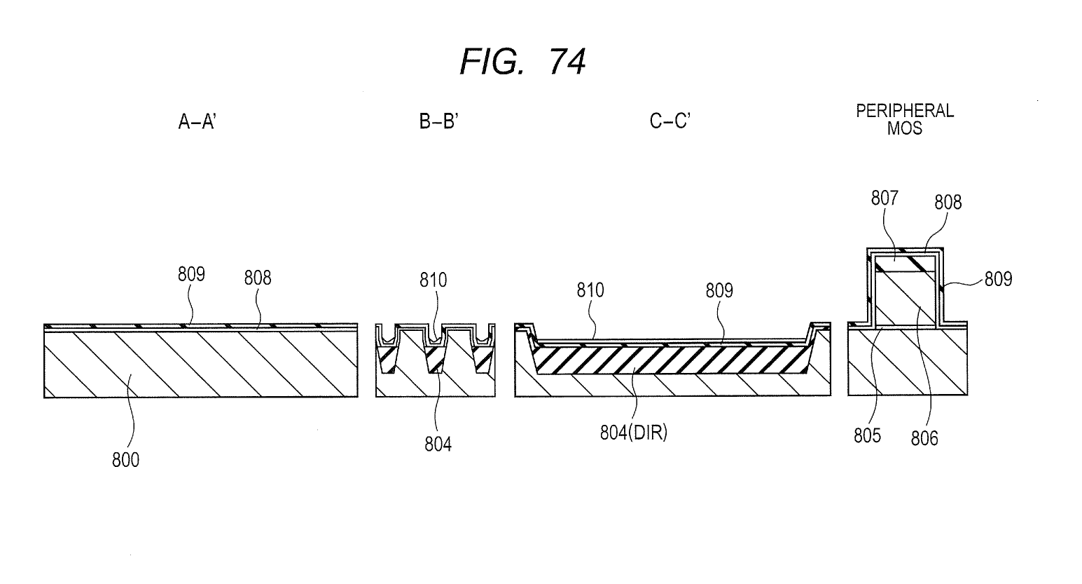

Subsequently, using lithographic and ion implantation techniques, ion implantation for adjusting the threshold values of the memory cells is performed. Next, in the memory cell region and the peripheral MOS formation region, a silicon oxide film (insulating film) 808 of about 4 nm is formed by a thermal oxidation method. Then, a silicon nitride film (charge storage film) 809 of about 9 nm serving as a charge storage film is deposited, and subsequently a silicon oxide film (insulating film) 810 is deposited. At this time, by depositing the silicon oxide film 810 of, e.g., about 20 nm such that the total of the physical thicknesses of the silicon oxide film 808, the silicon nitride film 809, and the silicon oxide film 810 is larger than the width of the isolation region DIR, the recess above the isolation region DIR can be filled with the insulating film (FIG. 73).

Next, the silicon oxide film 810 is removed by wet etching such that the silicon oxide film 810 of about 25 nm remains only over the silicon nitride film 809 located over the isolation region DIR (FIG. 74).

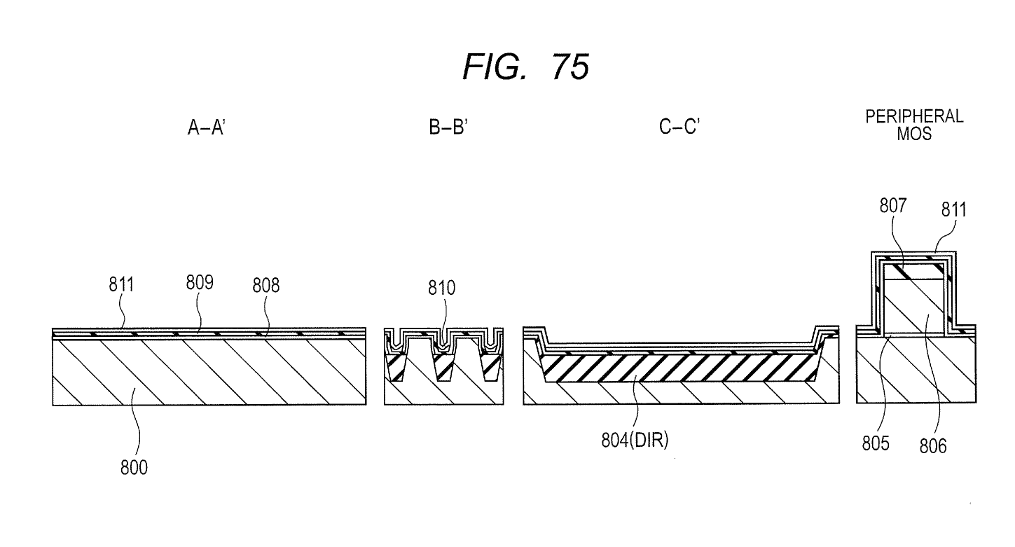

Then, in the memory cell region and the peripheral MOS formation region, the silicon oxide film 811 of about 7 nm is newly deposited. By this process, the thickness of the oxide film over the silicon nitride film 809 in the isolation region DIR can be increased to be larger than the thickness of the oxide film over the silicon nitride film 809 in the active region of the memory cell region (FIG. 75).

(e) Step P-15

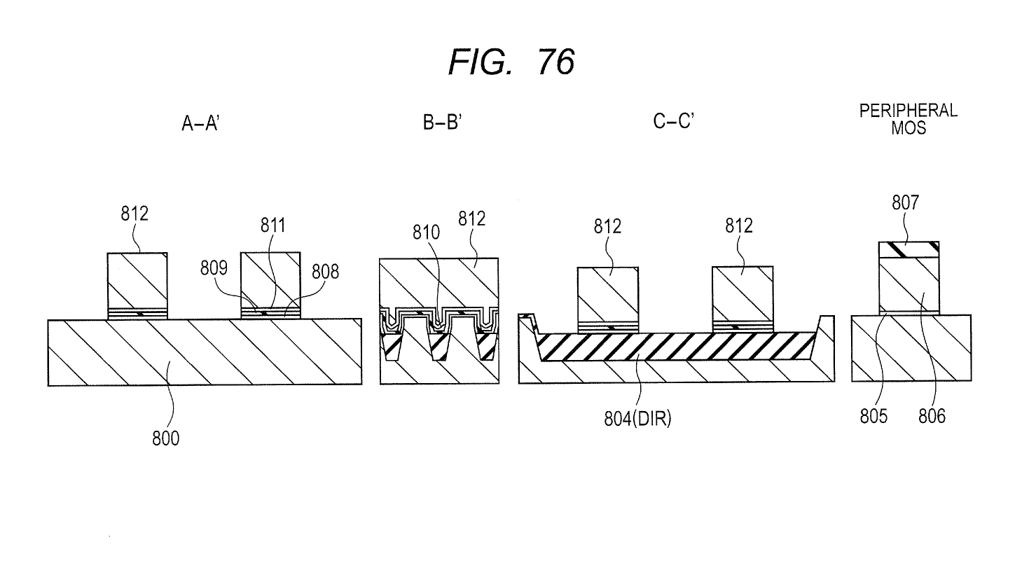

A polysilicon film 812 serving as the memory gate is deposited to a thickness of, e.g., 80 nm to form memory gates using lithographic and dry etching techniques (FIG. 76).

(f) Step P-16

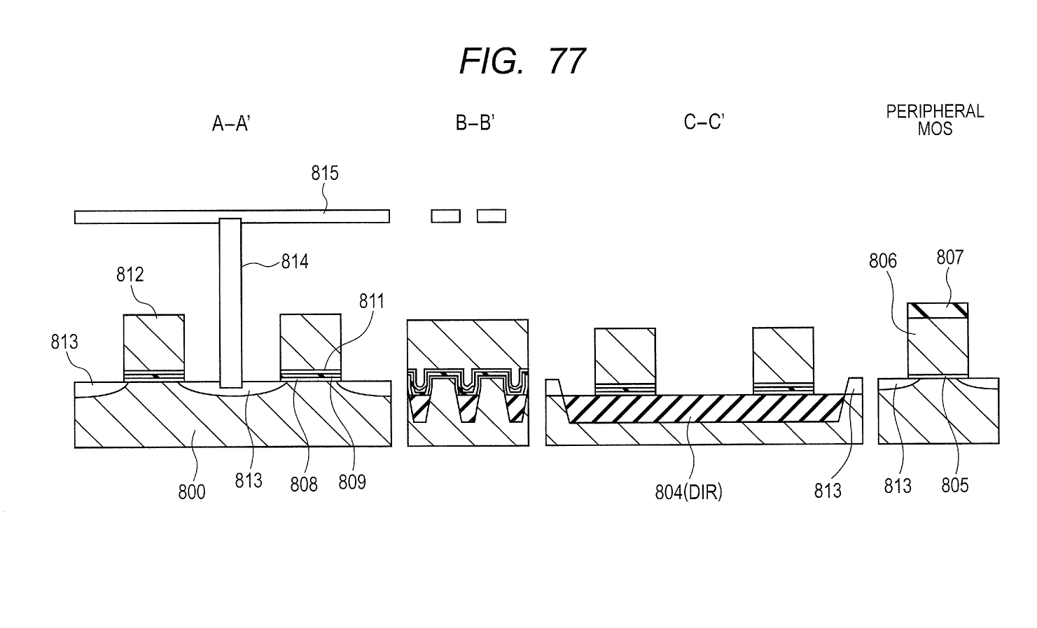

Then, ion implantation for the respective diffusion layers of p-MOS and n-MOS transistors is performed to form diffusion layers 813. Thereafter, a wiring interlayer film is deposited, and then contact holes for providing conduction to the memory transistors, the peripheral MOS transistors, and the diffusion layers are formed. A metal film is deposited in each of the contact holes to form contact portions 814. Subsequently, over the interlayer insulating film, a metal film is deposited and patterned to form wires 815 (FIG. 77).

It can also be considered to prevent the diffusion of the charges injected into the area between the adjacent cells by removing the silicon nitride film located over the isolation region. However, it is difficult to remove the portion (portion corresponding to L in FIG. 14) of the silicon nitride film located over the recessed and extremely narrow isolation region which does not form the gate insulating film of the memory gate, while leaving the portion of the silicon nitride film which forms the gate insulating film of the memory gate. Leaving the silicon nitride film over the isolation region allows further simplification of the manufacturing process.

### Embodiment 9

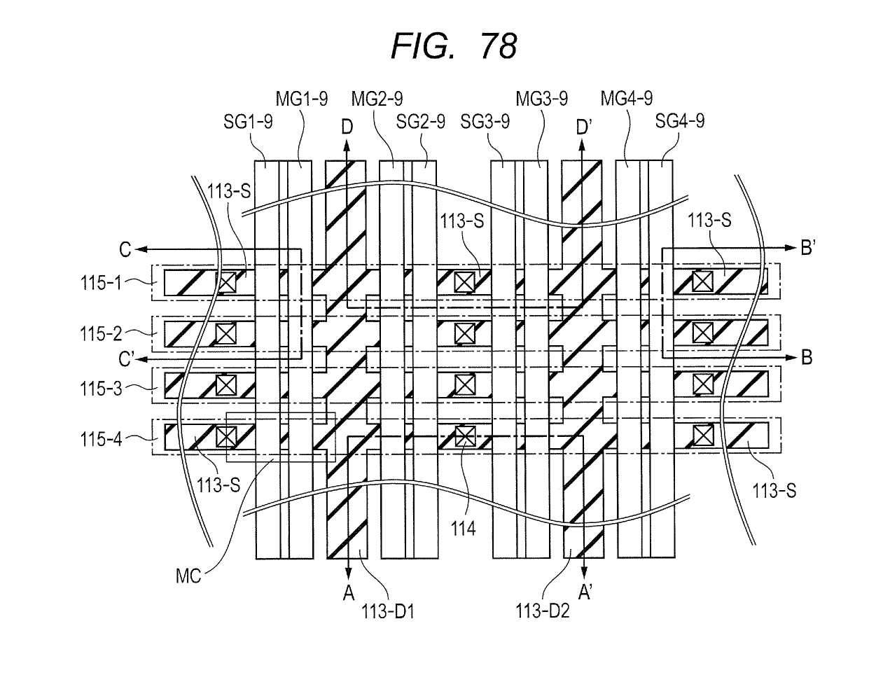

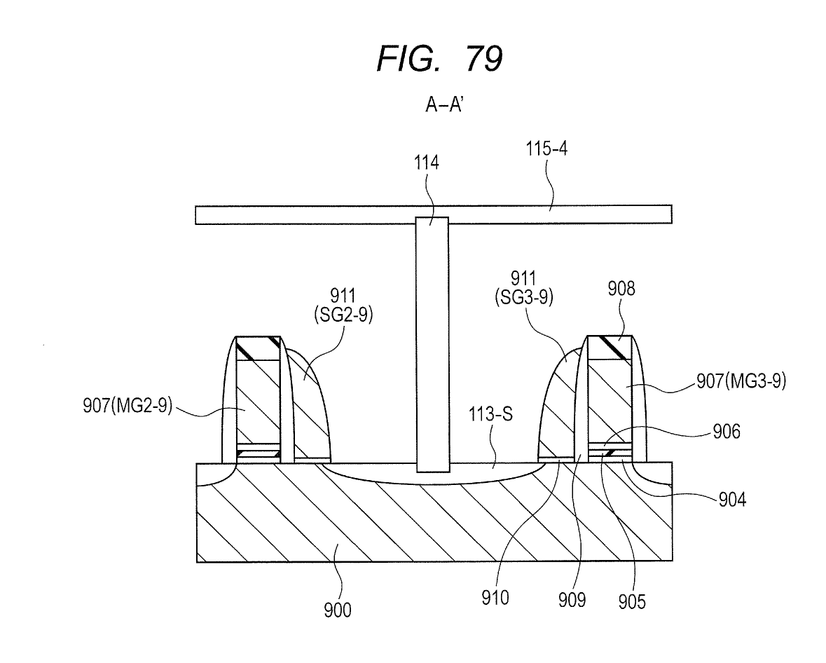

FIG. 78 is a plan view of a memory cell array in Embodiment 9. FIGS. 79, 80, 81, and 82 are cross-sectional views along the lines A-A′, B-B′, C-C′, and D-D′ shown in FIG. 78. Embodiment 9 is substantially the same as Embodiment 1 except in the points shown below.

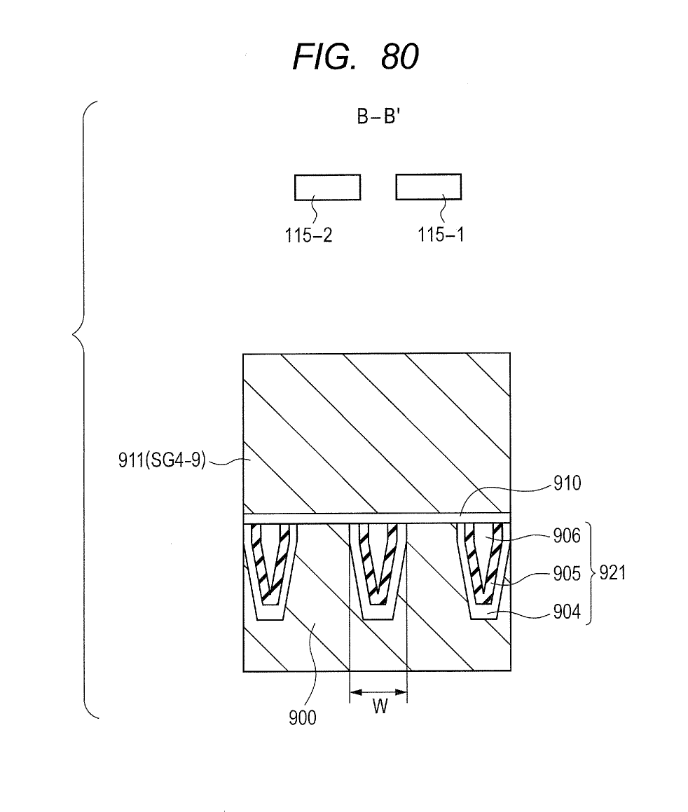

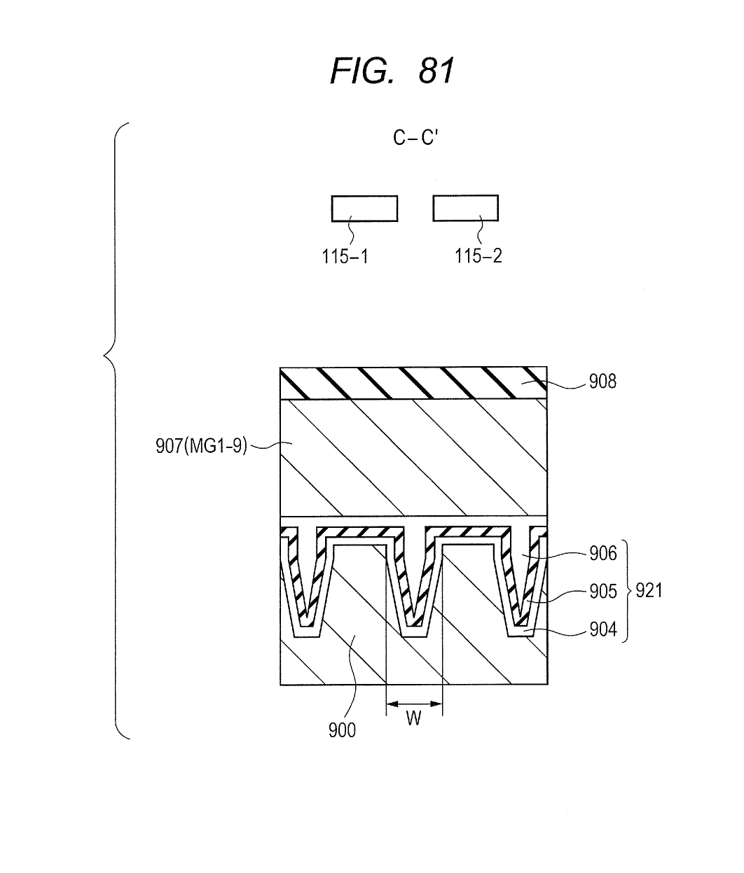

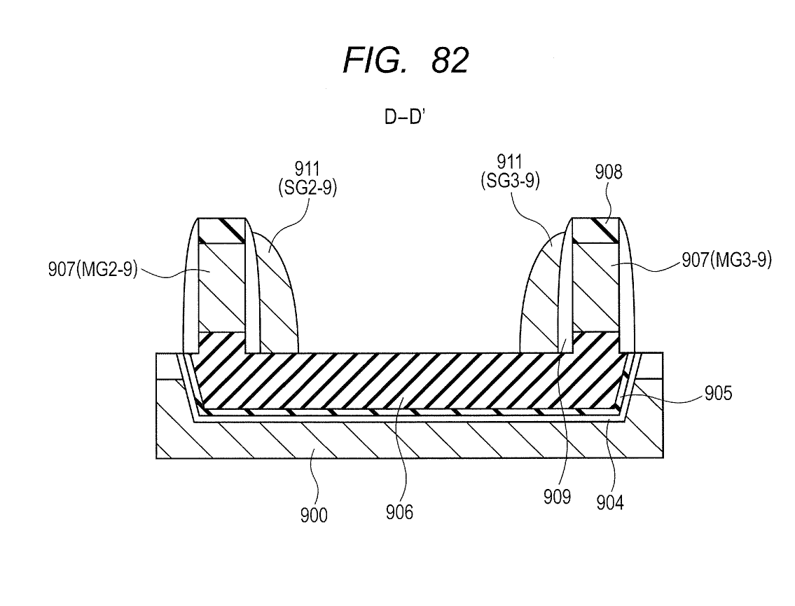

Embodiment 9 is different from Embodiment 1 in that: (1) each of the selection gates has a sidewall gate structure (in Embodiment 1, each of the memory gates has a sidewall gate structure); (2) the isolation regions are isolated by an ONO film structure; and (3) neither the memory gates nor the selection gates have a Fin structure. With regard to the point (1), as can be seen from FIGS. 79 and 82, the selection gate having the sidewall gate structure is formed on one side of the memory gate. With regard to the point (2), as can be seen from FIGS. 80, 81, and 82, an isolation region 921 is provided which has a structure (so-called ONO film structure) in which, in a trench 920 provided in a semiconductor substrate 900, a silicon oxide film 904, a silicon nitride film 905, and a silicon oxide film 906 are laminated in this order. With regard to (3), as shown in FIGS. 80 and 81, the selection gate and the memory gate do not protrude into the recessed portion of the isolation region 921. Here, of the insulating film present between a memory gate MG1-9 and an insulating film 905 as a charge storage film located thereunder, the portion located over the portion of the semiconductor substrate 900 without the isolation region and the portion located over the isolation trench region 921 are respectively referred to also as a first insulating film and a second insulating film. Accordingly, the thickness of the second insulating film is larger than the thickness of the first insulating film. In other words, the thickness of the first insulating film is smaller than the thickness of the second insulating film.

Preferably, the isolation region 921 shown in the cross-sectional views of FIGS. 80 and 81 has a width W of about 40 nm. That is, the width W is smaller than the width of the isolation region according to Embodiment 1. However, since the length of the silicon nitride film to the adjacent cell can be increased to the same level as in Embodiment 1 to allow a length of approximately 90 nm to be ensured, it is possible to reduce the degradation of the reliability of the memory cell resulting from the mutual interference between the electrons or holes injected in the charge storage film of the memory cell and diffused therein. That is, the diffusion of charges between the adjacent cells is not easily performed to improve the data retention property (reduce the amount of degradation).

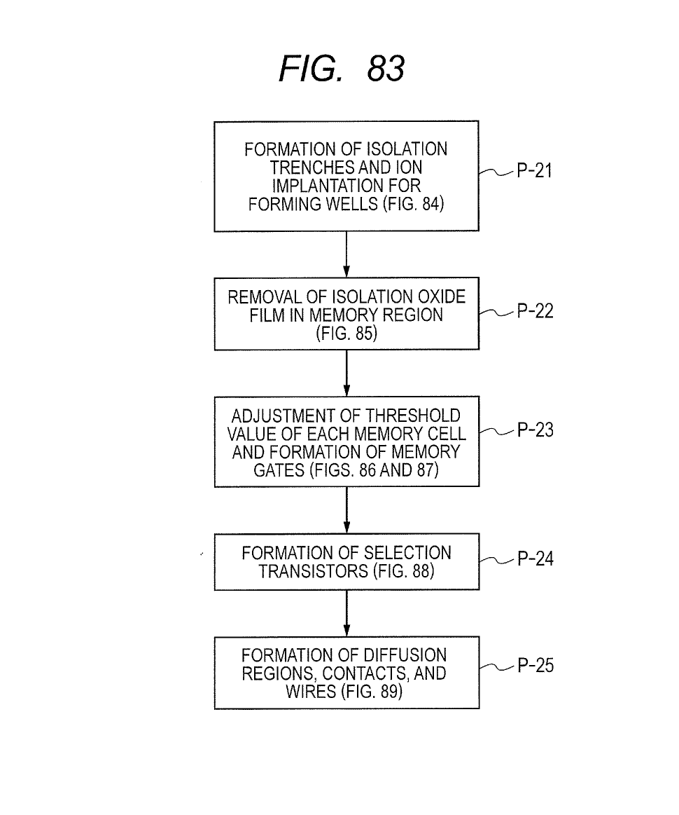

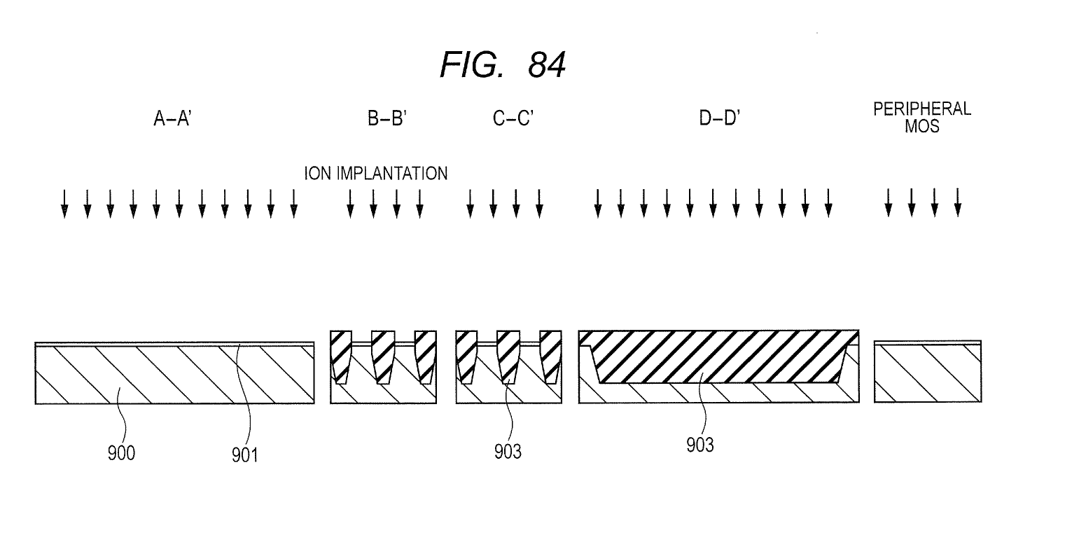

Next, using FIGS. 83 to 89, a description will be given of a manufacturing method of the semiconductor device according to Embodiment 9. Conceivably, this may more clearly show the difference with Embodiment 1. FIG. 83 is a flow chart showing the outline of the manufacturing method. FIGS. 84 to 89 are cross-sectional views in the individual process steps of Steps P-21 to P-25 shown in the flow chart. Note that, in the drawings, a memory cell formation region and a peripheral circuit formation region are separately shown and the memory cell formation region is further shown in the individual cross sections along the lines A-A′, B-B′, C-C′, and D-D′ in FIG. 78. As the peripheral circuit region, the peripheral MOS formation region is shown.

(a) Step P-21

The semiconductor substrate 900 made of silicon is provided. By thermally oxidizing the semiconductor substrate 900, over the memory cell formation region and the peripheral MOS transistor formation region, a silicon oxide film 901 of about 10 nm is formed, and a polysilicon film (not shown) of about 10 nm is formed thereover over the main surface of the semiconductor substrate 900. Then, a silicon nitride film of about 50 nm is deposited over the polysilicon film (not shown). Then, by lithographic and etching techniques, the main surface of the semiconductor substrate 900 is selectively etched to a depth of about 150 nm to be formed with the trench 920 for isolation. Over the silicon nitride film and in the trench 920, a silicon oxide film 903 is deposited and polished by a CMP method using the silicon nitride film as a stopper to be left in the trench 920 and thereover (FIG. 84). The silicon nitride film and the polysilicon film located thereunder are removed by wet etching and dry etching and, using the silicon oxide film 901 as a through film for ion implantation, P-type and N-type wells (not shown) are formed. At this time, the silicon oxide film 903 serves as a mask for ion implantation (FIG. 84).

(b) Step P-22

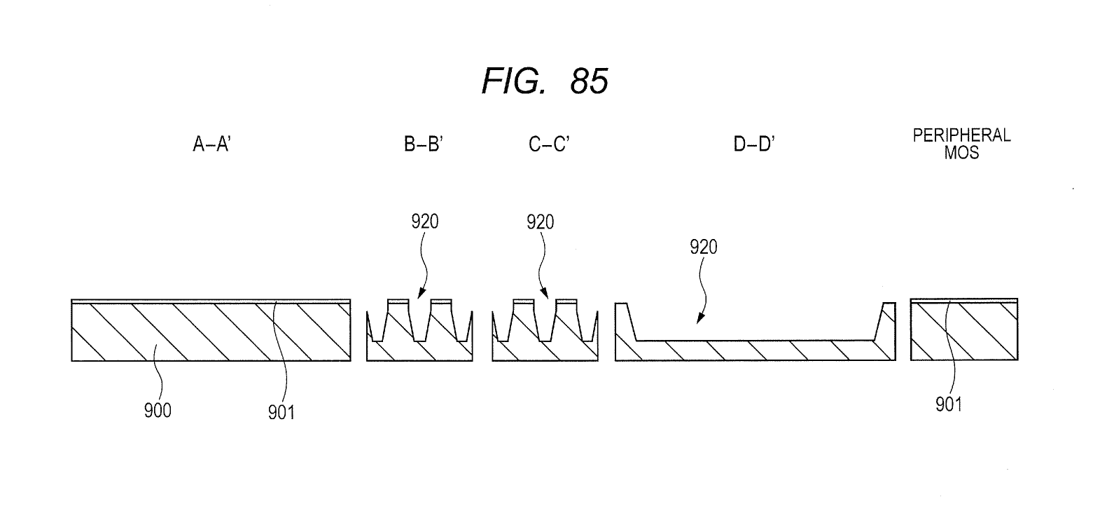

By dry etching or wet etching, the silicon oxide film 903 in the trench 920 is removed therefrom (FIG. 85).

(c) Step P-23

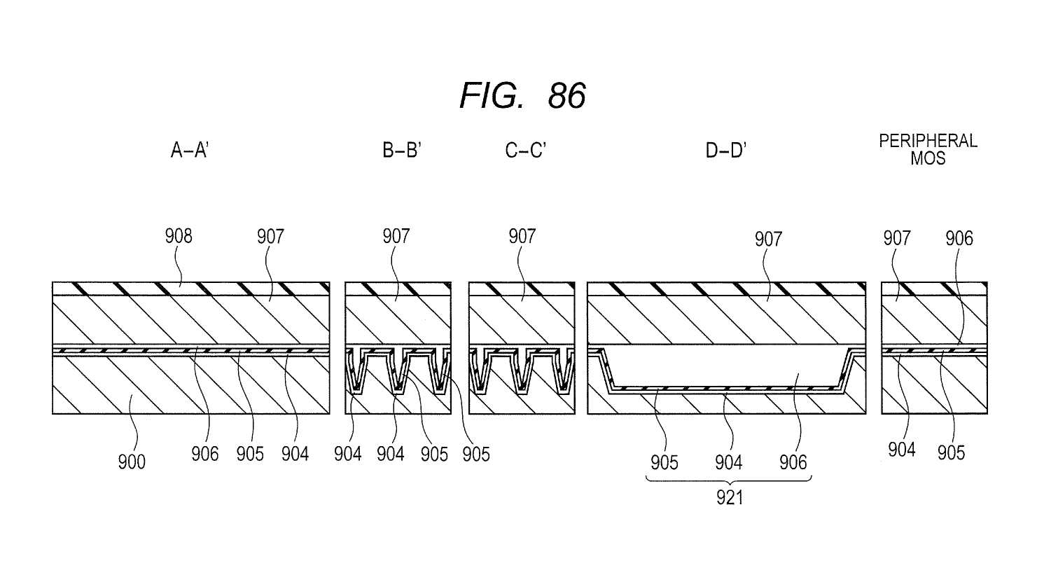

By dry etching or wet etching, the polysilicon film and the silicon oxide film 901 located thereunder in the memory cell formation region and the peripheral MOS formation region are removed. Subsequently, by a thermal oxidation method, the silicon oxide film 904 of about 4 nm serving as the gate oxide film of the memory gate is formed over the main surface MS of the semiconductor substrate 900 and in the trench 920. The silicon nitride film 905 of about 7 nm serving as the charge storage film and the silicon oxide film 906 of about 10 nm are deposited in this order over the silicon oxide film 904. In this manner, the trench 920 is filled with the insulating films. That is, in the memory cell formation region, a multilayer film serving as a gate insulating film under the memory gate is formed, while the trench portion 920 serves as the isolation region 921. Then, a polysilicon film (conductor film) 907 having a thickness of about 80 nm and serving as the memory gate is deposited, and a silicon nitride film 908 having a thickness of about 20 nm is deposited thereover (FIG. 86).

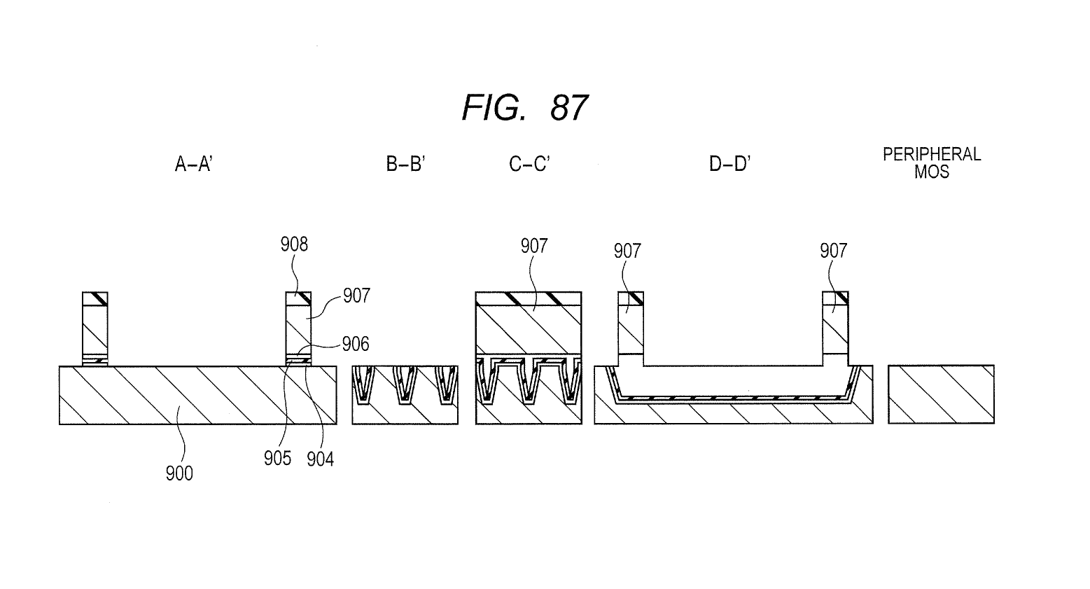

Next, by lithographic and etching techniques, the polysilicon film 907 and the silicon oxide film 904, the silicon nitride film 905, and the silicon oxide film 906 each located thereunder are selectively removed to form the memory gate formed of the polysilicon film 907 in the memory cell formation region. At this time, the polysilicon film 907 and the silicon oxide film 904, the silicon nitride film 905, and the silicon oxide film 906 each located thereunder in the peripheral MOS formation region are also removed (FIG. 87).

Then, by lithographic and ion implantation techniques, ion implantation for adjusting the threshold value of the memory cell is performed (not shown).

(d) Step P-24

Next, over each of the side walls of the memory gate, a sidewall film (sidewall) 909 made of a silicon oxide film of about 25 nm is formed to electrically isolate the memory gate from the selection gate afterwards. After a silicon oxide film 910 having a thickness of about 4 nm is formed by a thermal oxidation method in the memory cell formation region and the peripheral MOS transistor formation region, a polysilicon film 911 serving as the gate electrodes of the selection gate and a peripheral MOS transistor is deposited to, e.g., 40 nm. Here, using lithographic and etching techniques, the silicon oxide film 904 in, e.g., the peripheral MOS region may also be formed to have a plurality of levels of thicknesses.

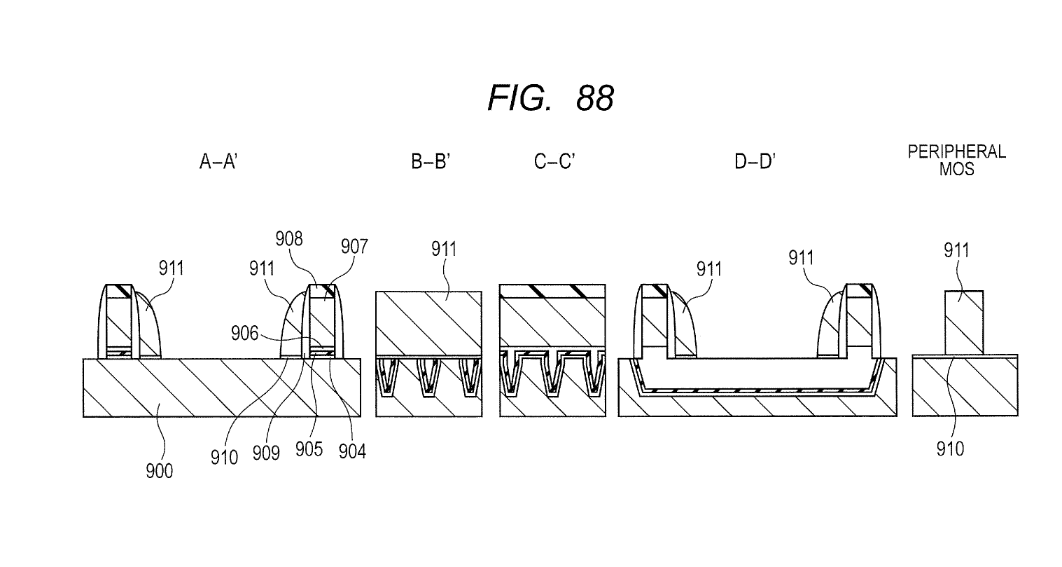

Then, the polysilicon film 911 in the memory cell formation region is etched back to form the selection gate having a sidewall shape. At this time, the sidewall electrodes are formed on both sides of the memory gate interposed therebetween but, by lithographic and etching techniques, the unneeded sidewall gate on one side of the memory gate is removed, while the sidewall gate is formed only on one side thereof (FIG. 88).

On the other hand, the polysilicon film 911 in the peripheral MOS transistor formation region is formed into the gate electrode having a predetermined shape by lithographic and etching techniques (FIG. 88).

(e) Step P-25

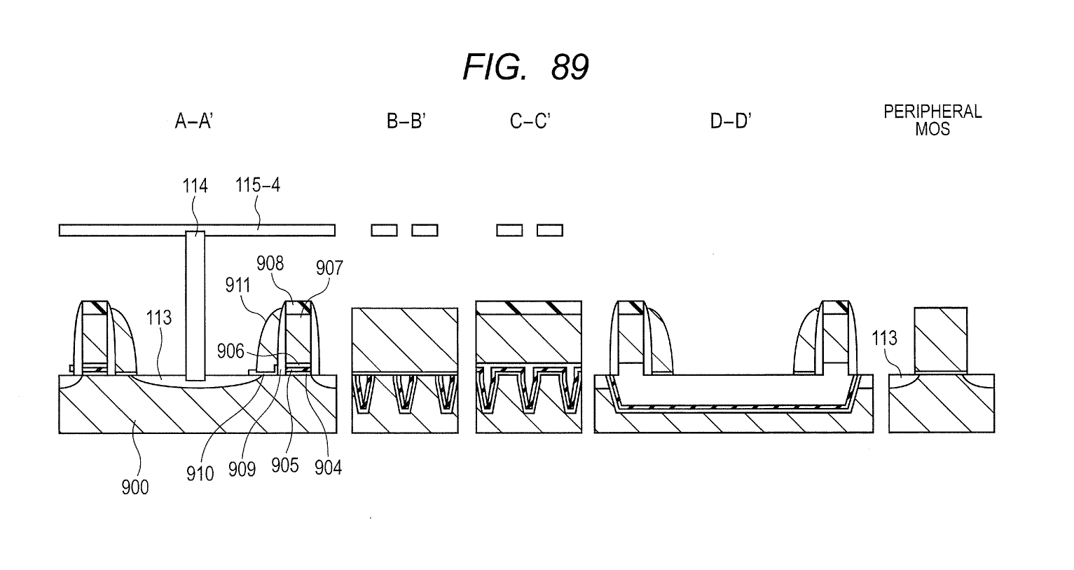

Thereafter, ion implantation for the diffusion layers of each of the p-MOS and n-MOS transistors is performed to form the diffusion layers 113. At this time, the gate electrode and diffusion layers of the selection transistor may also be silicidized for lower resistances. Thereafter, a wiring interlayer film is deposited, and then contact holes for providing conduction to the memory transistor, the selection transistor, the peripheral MOS transistor, and the diffusion layers are formed. In each of the contact holes, a metal film is deposited to form the contact portions 114. Subsequently, over the interlayer insulating film, a metal film is deposited and patterned to form wires 115 (FIG. 89).

Embodiment 9 described above achieves the same function/effect as achieved by Embodiment 2. That is, since the memory gate of Embodiment 9 does not have a Fin structure, a read current is smaller than in Embodiment 1. However, the length of the portion of the charge storage film which is located over the isolation region and in which charges are not injected can be increased to be larger than in Embodiment 1. Therefore, Embodiment 9 is preferred in the case where high-speed reading is less required than in Embodiment 1. In the semiconductor device of Embodiment 9, even when the width of the isolation region is reduced through the scaling of the memory cells to reduce the distance between the adjacent memory cells, the effective length of the charge storage film over the isolation region can be increased to be larger than in Embodiment 1. This allows a reduction in mutual interference between the electrons or holes injected into the charge storage film of the memory cell and diffused into the portion of the charge storage film located over the isolation region. In other words, if the length of the portion of the charge storage film which is located over the isolation region and in which charges are not injected is controlled to be the same as in Embodiment 1, the width of the isolation region can be reduced to be smaller than in Embodiment 1.

Also, even under the condition of a severe external environment, such as when the semiconductor device is used as an in-vehicle product, it is possible to ensure a high quality and high reliability therefor.

In addition, through the scaling of a product chip size, it is possible to improve the number of products obtained from a single wafer and thereby achieve a cost reduction.

While the invention achieved by the present inventors has been specifically described heretofore based on the embodiments thereof, the present invention is not limited thereto. It will be appreciated that various changes and modifications can be made in the invention within the scope not departing from the gist thereof.

What is claimed is:

1. A semiconductor device, comprising:
a semiconductor substrate having a main surface;
a plurality of memory cells each present in a selected region of the semiconductor substrate; and
an isolation region located between the memory cells in adjacent relation thereto to provide isolation between the memory cells,
wherein each of the memory cells has a charge storage film located over the main surface of the semiconductor substrate, and a memory gate located over the charge storage film,
wherein an upper surface of the isolation region is present at a position below the main surface of the semiconductor substrate,
wherein the charge storage film and the memory gate of the memory cell extend over the isolation region to an adjacent memory cell, and
wherein a length of a region of the charge storage film which is located over the isolation region and in which charges are not stored is larger than a width of the isolation region.

2. A semiconductor device according to claim 1,
wherein a part of the charge storage film located over the isolation region has a structure protruding toward the upper surface of the isolation region.

3. A semiconductor device according to claim 1,
wherein a portion of the memory gate located over the isolation region has a structure protruding toward the upper surface of the isolation region.

4. A semiconductor device according to claim 1,
wherein each of the memory cells has a selection gate.

5. A semiconductor device according to claim 4,
wherein the selection gate also extends over the isolation region.

6. A semiconductor device according to claim 4,
wherein the memory gate is present so as to face the selection gate.

7. A semiconductor device according to claim 6,
wherein, over a side portion of the memory gate facing the selection gate also, the charge storage film extends.

8. A semiconductor device according to claim 4,
wherein the memory gate and the selection gate are each made of polysilicon.

9. A semiconductor device according to claim 4,
wherein the memory cells are arranged in rows and columns in the semiconductor substrate, and
wherein the memory gates and the selection gates extend in the same direction to form a memory cell array.

10. A semiconductor device according to claim 9, further comprising:
a diffusion region extending in a direction crossing the direction in which the memory gates and the selection gates extend.

11. A semiconductor device according to claim 4,
wherein each of the memory cells has a dummy gate.

12. A semiconductor device according to claim 4,
wherein each of the memory cells has a plurality of memory gates between which the selection gate is interposed.

13. A semiconductor device according to claim 1,
wherein each of the memory cells is of a MONOS type.

14. A semiconductor device according to claim 1,
wherein each of the memory cells is an NROM.

15. A semiconductor device, comprising:
a semiconductor substrate having a main surface;
a plurality of memory cells each present in a selected region of the semiconductor substrate; and
an isolation region located between the memory cells in adjacent relation thereto to provide isolation between the memory cells,
wherein each of the memory cells has a charge storage film located over the main surface of the semiconductor substrate, and a memory gate located over the charge storage film,
wherein an upper surface of the isolation region is present at a position below the main surface of the semiconductor substrate,
wherein the charge storage film and the memory gate of the memory cell extend over the isolation region to an adjacent memory cell, and
wherein a part of the charge storage film located over the isolation region protrudes toward the upper surface of the isolation region,
the semiconductor device further comprising:
a first insulating film located between the memory gate and the charge storage film of each of the memory cells; and
a second insulating film located between the memory gate and the charge storage film over the isolation region,
wherein a thickness of the second insulating film is larger than a thickness of the first insulating film.

16. A semiconductor device, comprising:
a semiconductor substrate having a main surface;
a plurality of memory cells present in a selected region of the semiconductor substrate; and
an isolation region located between the memory cells in adjacent relation thereto to provide isolation between the memory cells,
wherein each of the memory cells has a charge storage film located over the main surface of the semiconductor substrate, and a memory gate located over the charge storage film,
wherein an upper surface of the isolation region is present below the main surface of the semiconductor substrate,
wherein the charge storage film and the memory gate of the memory cell extend over the isolation region to an adjacent memory cell, and
wherein a part of the memory gate protrudes toward the upper surface of the isolation region,
the semiconductor device further comprising:
an air gap in the protruding portion of the memory gate.

17. A semiconductor device according to claim 16, further comprising:
a first insulating film between the charge storage film located over the main surface of the substrate and the memory gate located over the charge storage film; and
a second insulating film between a portion of the charge storage film located over the isolation region and the memory gate located over the portion of the charge storage film,
wherein a thickness of the first insulating film is smaller than a thickness of the second insulating film.

18. A semiconductor device according to claim 16,
wherein each of the memory cells is of a MONOS type.

19. A semiconductor device, comprising:
a semiconductor substrate having a main surface;
a plurality of memory cells each present in a selected region of the semiconductor substrate; and
an isolation region located between the memory cells in adjacent relation thereto to provide isolation between the memory cells,
wherein each of the memory cells has a charge storage film located over the main surface of the semiconductor substrate, and a memory gate located over the charge storage film,
wherein an upper surface of the isolation region is present above the main surface of the semiconductor substrate, and
wherein the charge storage film and the memory gate of the memory cell extend over the isolation region to an adjacent memory cell.

20. A semiconductor device, comprising:
a semiconductor substrate having a main surface;
a plurality of memory cells each present in a selected region of the semiconductor substrate; and
an isolation region located between the memory cells in adjacent relation thereto to provide isolation between the memory cells,
wherein each of the memory cells has a charge storage film located over the main surface of the semiconductor substrate, a memory gate located over the charge storage film, and an insulating film located between the memory gate and the charge storage film,
wherein the memory gate of the memory cell extends over the isolation region to an adjacent memory cell,
wherein the isolation region has the charge storage film extending from the memory cell to the adjacent memory cell, and the insulating film located over the charge storage film, and
wherein the charge storage film in the isolation region protrudes toward a lower surface of the isolation region.

21. A semiconductor device according to claim 20,
wherein the insulating film located over the charge storage film includes a first insulating film in the memory cell and a second insulating film in the isolation region, and
wherein a thickness of the second insulating film is larger than a thickness of the first insulating film.

22. A semiconductor device according to claim 20,
wherein the memory gate provides coupling between the memory cells to extend in a direction.

23. A semiconductor device according to claim 21,
wherein a width of the isolation trench region along the direction in which the memory gate extends is 40 nm.

24. A method of manufacturing a semiconductor device, comprising the steps of:
providing a semiconductor substrate having a main surface;
selectively removing a portion of the main surface serving as an isolation region adjacent to a memory cell formation region of the main surface;
depositing an insulating film over a portion resulting from the removal;
removing a part of the insulating film in the isolation region such that the insulating film is recessed from the main surface;
forming a charge storage film extending from over the memory cell formation region of the main surface to over the isolation region;
forming an insulating film over the charge storage film;
selectively removing the insulating film so as to leave the insulating film over the charge storage film located over the isolation region;
forming a conductor film over the memory cell formation region of the main surface and over the isolation region; and
selectively removing the conductor film to form a memory gate extending from over the memory cell formation region to over the isolation region.

25. A method of manufacturing a semiconductor device, comprising the steps of:
providing a semiconductor substrate having a main surface;
selectively removing a portion of the main surface serving as an isolation region adjacent to a memory cell formation region of the main surface to form a trench for isolation;
forming a charge storage film and an insulating film in this order over the memory cell formation region of the main surface and in the trench;
forming a conductor film over the memory cell formation region and over the trench region; and
selectively removing the conductor film to form a memory gate extending from over the memory cell formation region to over the trench for isolation.
